(19) United States
(12) Patent Application Publication
(10) Pub. No.: US 2026/0344024 A1
(43) Pub. Date: Oct. 29, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 19/190,127

(22) Filed: Apr. 25, 2025

(51) Int. Cl. H10D 84/83; H10D 64/23; H10D 64/62; H10D 84/01

(52) U.S. Cl. CPC H10D 84/8312; H10D 64/256; H10D 84/0149; H10D 84/832; H10D 64/62

(57) ABSTRACT

A method for forming a semiconductor structure is provided. The method includes forming a first circuit and a second circuit. The first circuit includes a first fin element, a first source/drain feature on the first fin element, a plurality of first gate stacks extending across the first fin element and having a first gate pitch. The second circuit includes a second fin element, a second source/drain feature on the second fin element, a plurality of second gate stacks extending across the second fin element and having a second gate pitch that is different from the first gate pitch. The method further includes forming a first opening through the first fin element to expose a backside surface of the first source/drain feature while a backside surface of the second source/drain feature remains covered by the second fin element, and forming a first contact structure in the first opening.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A and 2B show the frontside layout and the backside layout of a semiconductor structure, in accordance with some embodiments.

FIGS. 3A-1, 3B-1, 3C-1, 3D-1, 3E-1, 3F-1, 3G-1, 3H-1, 3I-1, 3J-1, 3K-1, 3L-1, 3M-1, 3N-1, 3O-1, 3P-1 and 3Q-1 are cross-sectional views of the semiconductor structure at an intermediate stage corresponding to line X1-X1 and line X2-X2 of FIGS. 2A and 2B, in accordance with some embodiments of the disclosure.

FIGS. 3A-2, 3B-2, 3C-2, 3D-2, 3E-2, 3F-2, 3G-2, 3H-2, 3I-2, 3J-2, 3K-2, 3L-2, 3M-2, 3N-2, 3O-2, 3P-2 and 3Q-2 are cross-sectional views of the semiconductor structure at an intermediate stage corresponding to line Y1-Y1 and line Y2-Y2 of FIGS. 2A and 2B, in accordance with some embodiments of the disclosure.

FIG. 3Q-3 is a cross-sectional view of the semiconductor structure corresponding to line X3-X3 and line X4-X4 of FIGS. 2A and 2B, in accordance with some embodiments of the disclosure.

FIGS. 4-1, 4-2 and 4-3 are a modification of the semiconductor structure of FIGS. 3Q-1, 3Q-2 and 3Q-3, in accordance with some embodiments of the disclosure.

FIGS. 5A and 5B show the frontside layout and the backside layout of a semiconductor structure, in accordance with some embodiments.

FIG. 6-1 is a cross-sectional view of the semiconductor structure corresponding to line X1-X1 and line X2-X2 of FIGS. 5A and 5B, in accordance with some embodiments of the disclosure.

FIG. 6-2 is a cross-sectional view of the semiconductor structure corresponding to line Y1-Y1 and line Y2-Y2 of FIGS. 5A and 5B, in accordance with some embodiments of the disclosure.

FIG. 6-3 is a cross-sectional view of the semiconductor structure corresponding to line X3-X3 and line X4-X4 of FIGS. 5A and 5B, in accordance with some embodiments of the disclosure.

FIG. 6-4 is a cross-sectional view of the semiconductor structure corresponding to line X5-X5 of FIGS. 5A and 5B, in accordance with some embodiments of the disclosure.

FIGS. 7-1, 7-2 and 7-3 are a modification of the semiconductor structure of FIGS. 6-1, 6-2 and 6-3, in accordance with some embodiments of the disclosure.

FIGS. 8A and 8B show the frontside layout and the backside layout of a semiconductor structure, in accordance with some embodiments.

FIG. 9-1 is a cross-sectional view of the semiconductor structure corresponding to line X1-X1 and line X2-X2 of FIGS. 8A and 8B, in accordance with some embodiments of the disclosure.

FIG. 9-2 is a cross-sectional view of the semiconductor structure corresponding to line Y1-Y1 and line Y2-Y2 of FIGS. 8A and 8B, in accordance with some embodiments of the disclosure.

FIG. 9-3 is a cross-sectional view of the semiconductor structure corresponding to line X3-X3 and line X4-X4 of FIGS. 8A and 8B, in accordance with some embodiments of the disclosure.

FIGS. 10-1, 10-2 and 10-3 are a modification of the semiconductor structure of FIGS. 9-1, 9-2 and 9-3, in accordance with some embodiments of the disclosure.

FIGS. 11A and 11B show the frontside layout and the backside layout of a semiconductor structure, in accordance with some embodiments.

FIG. 12-1 is a cross-sectional view of the semiconductor structure corresponding to line X1-X1 and line X2-X2 of FIGS. 11A and 11B, in accordance with some embodiments of the disclosure.

FIG. 12-2 is a cross-sectional view of the semiconductor structure corresponding to line Y1-Y1 and line Y2-Y2 of FIGS. 11A and 11B, in accordance with some embodiments of the disclosure.

FIG. 12-3 is a cross-sectional view of the semiconductor structure corresponding to line X3-X3 and line X4-X4 of FIGS. 11A and 111B, in accordance with some embodiments of the disclosure.

FIGS. 13-1, 13-2 and 13-3 are a modification of the semiconductor structure of FIGS. 12-1, 12-2 and 12-3, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The aspect of the present disclosure is directed to a semiconductor structure with a backside power rail architecture. The semiconductor structure includes two cell regions with different gate pitches. One of the cell regions includes backside contact structures, and thus the current crowding may be alleviated. The other one of the cell regions has no backside contact structures, and thus the difficulty of the patterning process for forming the backside contact opening may be reduced. Therefore, the performance and manufacturing yield of the resulting semiconductor structure may improve.

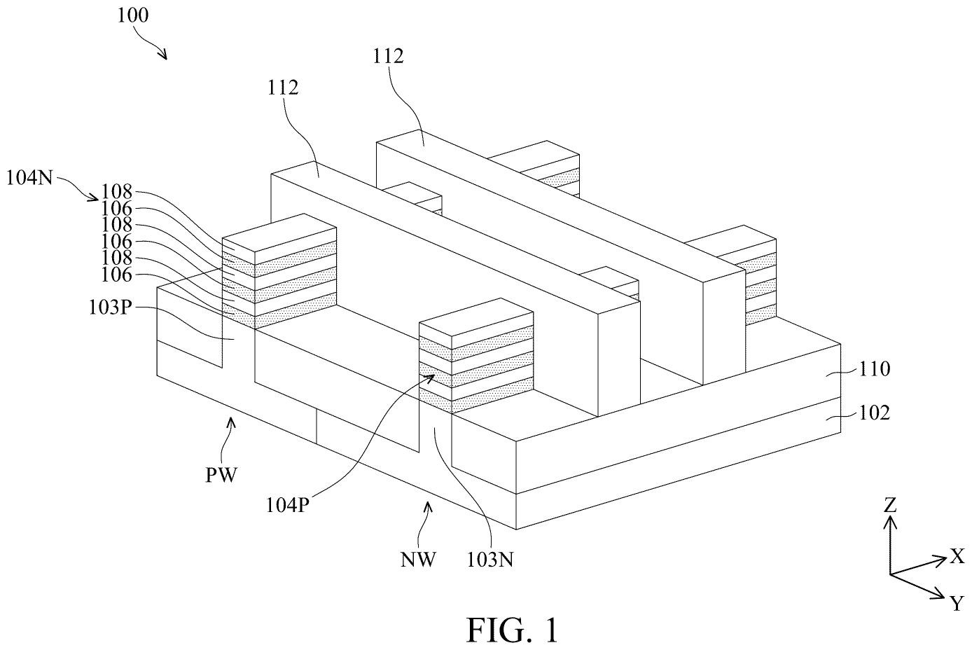

FIG. 1 is a perspective view of a semiconductor structure 100, in accordance with some embodiments of the disclosure. The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW of the substrate 102, and the fin structure 104P is formed in the n-type well NW of the substrate 102, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction. The vertical direction is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments. Each of the fin structures 104N and 104P further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

The fin structures 104N and 104P extend in the X direction, in accordance with some embodiments. That is, the fin structures 104N and 104P have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. It is noted that in the present disclosure, source/drain region(s) or source/drain feature(s) may refer to a source or a drain, individually or collectively dependent upon the context.

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-routing direction.

Although two fin structures 104 are illustrated in FIG. 1, the semiconductor structure 100 may include more than two fin structures 104. In addition, FIG. 1 shows two gate structures 112 (or channel regions) for illustrative purposes and is not intended to be limiting. The number of fin structures and the gate structures may be dependent on the design demand of an integrated circuit and/or performance consideration of semiconductor devices.

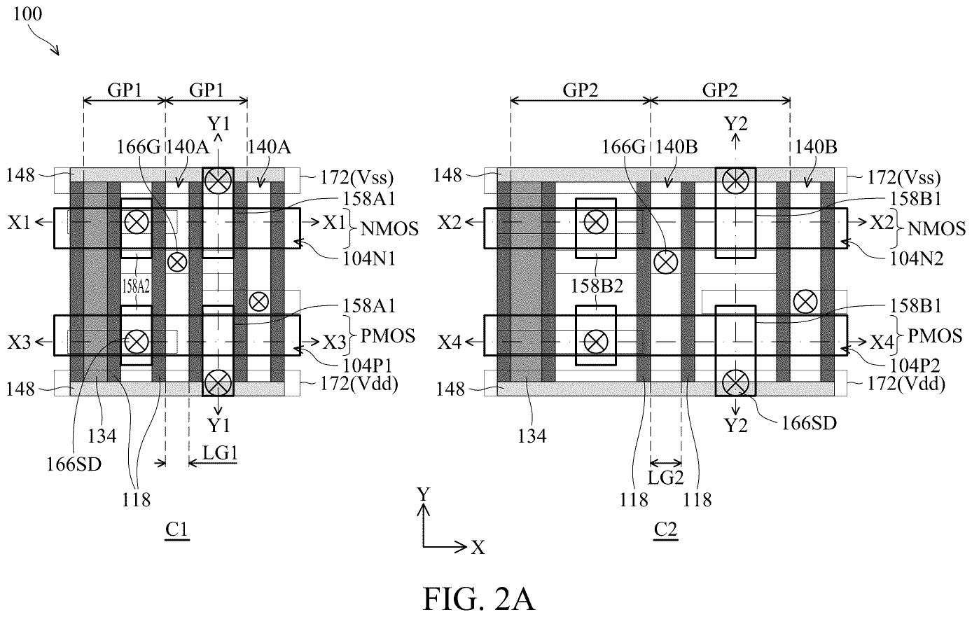

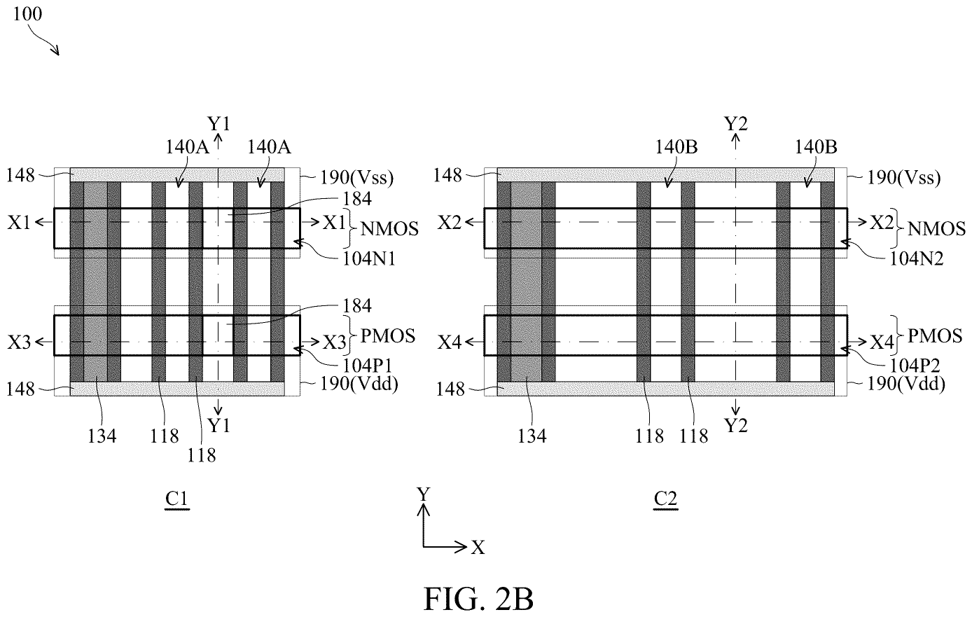

FIGS. 2A and 2B respectively illustrate the frontside layout and the backside layout of a semiconductor structure 100 with a backside power rail architecture, in accordance with some embodiments.

The semiconductor structure 100 is or includes nanostructure devices (e.g., GAA FETs), in accordance with some embodiments. The semiconductor structure 100 (or the substrate) is defined as or includes several cell regions, e.g., a first cell region C1 and a second cell region C2, in accordance with some embodiments. Circuits are formed in the respective cell regions and interconnected with each other to form integrated circuits, in accordance with some embodiments.

In some embodiments, the circuit in the first cell region C1 includes active regions 104N1 and 104P1 over a substrate (as shown in FIG. 1), final gate stacks 140A across the active regions 104N1 and 104P1, and frontside contact structures 158A (including 158A1 and 158A2), as shown in FIGS. 2A and 2B. In some embodiments, the circuit in the first cell region C1 further includes backside contact structures 184, as shown in FIG. 2B.

In some embodiments, the circuit in the second cell region C2 includes active regions 104N2 and 104P2 over the substrate, final gate stacks 140B across the active regions 104N2 and 104P2, and frontside contact structures 158B (including 158B1 and 158B2), as shown in FIGS. 2A and 2B. There is no backside contact structure disposed in the second cell region C2, as shown in FIG. 2B, in accordance with some embodiments.

In some embodiments, the functional circuit in the first cell region C1 may focus more on higher performance (i.e., on-state current), and the functional circuit in the second cell region C2 may focus more on higher device energy efficiency. In some embodiments, the first cell region C1 has a smaller gate pitch GP1 while the second cell region C2 has a greater gate pitch GP2 than the gate pitch GP1. The gate pitch is the pitch of the final gate stacks, and may be defined as the sum of a dimension (i.e., channel length) of the final gate stacks in the X direction and the spacing between the final gate stacks. In some embodiments, the gate pitch may be also referred to as critical poly-gate pitch (CPP). In some embodiments, the ratio (GP2/GP1) of the gate pitch GP2 to the gate pitch GP1 is greater than about 1.1, for example, in a range from about 1.2 to about 3.

In some embodiment, the dimension LG1 of the final gate stacks 140A in the X direction is less than the dimension LG2 of the final gate stacks 140B in the X direction. In some embodiments, the ratio (LG1/LG2) of the dimension LG2 to the dimension LG1 is in a range from about 1.2 to 5. In some embodiment, the spacing between the final gate stacks 140A is less than the spacing between the final gate stacks 140B. In some embodiments, the spacing between the final gate stacks 140A to the spacing between the final gate stacks 140B is in a range from about 1.2 to 5.

In some embodiments, the first cell region C1 is separate from the second cell region C2 by other cell regions. In some other embodiments, the first cell region C1 is immediately adjacent to the second cell region C2. In some embodiments, the first cell region C1 and the second cell region C2 are STD cell regions (e.g., NAND, the inverter cell, NOR, AND, OR, Flip-Flop, and/or SCAN cell regions) or memory cell regions such as SRAM cell region. In some embodiments, the first cell region C1 and the second cell region C2 include a passive circuit, e.g., e-fuse device, capacitor device, resistor device, and/or another suitable passive device. In some other embodiments, the cell height (the dimension in the Y direction) of the first cell region C1 is substantially equal to the cell height of the second cell region C2, as shown in FIGS. 2A and 2B. In some embodiments, the first cell region C1 has a smaller cell height than the second cell region C2.

The active regions 104N (including 104N1 and 104N) Are Located in the p-type wells (PW as shown in FIG. 1), and the active regions 104P (including 104P1 and 104P2) are located in the n-type wells (NW as shown in FIG. 1), in accordance with some embodiments. Each of the active regions 104N and 104P includes a lower fin element (103N or 103P as shown in FIG. 1) longitudinally oriented along the X direction and nanostructures (not shown in FIG. 2) formed over the lower elements, in accordance with some embodiments.

The final gate stacks 140A and 140B are longitudinally oriented along the Y direction and across the lower fin elements, and wrap around the nanostructures of the active regions 104N1, 104P1, 104N2 and 104P2, in accordance with some embodiments. Gate spacer layers 118 are formed along the opposite sides of the final gate stacks 140A and 140B, in accordance with some embodiments.

The final gate stacks 140A and 140B are combined with the nanostructures of the active regions 104N and 104P to form nanostructure transistors, in accordance with some embodiments. The nanostructure transistors are formed at the cross points between the active regions 104N and 104P and the final gate stacks 140A and 140B, in accordance with some embodiments. The nanostructure transistors which are formed on the active regions 104N1 and 104N2 (in the p-type wells) are n-channel nanostructure transistors NMOS, and the nanostructure transistors which are formed on the active regions 104P1 and 104P2 (in the n-type wells) are p-channel nanostructure transistors PMOS, in accordance with some embodiments.

Fin isolation structures 134 are longitudinally oriented along the Y direction and cut through the active regions 104N and 104P, as shown in FIGS. 2A and 2B, in accordance with some embodiments. In some embodiments, the fin isolation structures 134 are formed by replacing gate structures with dielectric material. Gate spacer layers 118 are also formed along the opposite sides of the fin isolation structures 134, in accordance with some embodiments. The fin isolation structures 134 are located on and arranged along the boundaries of the cell regions C1 and C2 extending in the Y direction, in accordance with some embodiments.

Gate isolation structures 148 are longitudinally oriented along the X direction, and cut through the final gate stacks 140A and 140B, the fin isolation structures 134 and the gate spacer layers 118, as shown in FIGS. 2A and 2B, in accordance with some embodiments. The gate isolation structures 148 are located on and arranged along the boundaries of the cell regions C1 and C2 extending in the X direction, in accordance with some embodiments.

The frontside contact structures 158A and 158B (including 158A1, 158A2, 158B1 and 158B2) are disposed on the source/drain regions of the active regions 104N and 104P, and electrically connected to the source or drain terminals of the nanostructure transistors, in accordance with some embodiments. The frontside contact structures 158A1 and 158B1 are electrically connected to frontside power rails (or power supply lines) and may also serve as Vdd/Vss nodes of the circuits in the cell regions C1 and C2, in accordance with some embodiments. The contact structures 158A2 and 158B2 are electrically connected to signal lines and may also serve as non-Vdd/Vss nodes of the circuits in the cell regions C1 and C2.

Vias 166SD are disposed on and electrically connected to the frontside contact structure 158A and 158B and may also be referred to as source/drain vias, as shown in FIG. 2A, in accordance with some embodiments. gate vias 166G are disposed on the final gate stacks 140A and 140B and may also be referred to as gate vias, as shown in FIG. 2A, in accordance with some embodiments.

A frontside metal layer (e.g., frontside first-level metal layer (F_M1)) is disposed on and electrically connected to the vias 166SD and the gate vias 166G, in accordance with some embodiments. The frontside metal layer includes several metal lines (tracks) 172, e.g., power rails and signal lines (not shown), as shown in FIG. 2A, in accordance with some embodiments. The power rails 172 include Vdd frontside power rails providing positive voltage and Vss frontside power rails which may be an electrical ground, in accordance with some embodiments. The signal lines are configured for signal transmission and are electrically isolated from the power rails, in accordance with some embodiments. The lines 172 of the frontside metal layer are longitudinally oriented along the X direction, in accordance with some embodiments.

The Vss frontside power rails 172 are electrically connected to the Vss node (e.g., source terminals) of the n-channel nanostructure transistors NMOS through the vias 166SD and the frontside contact structures 158A1 and 158B1, in accordance with some embodiments. The Vdd frontside power rail 172 is electrically connected to the Vdd node (e.g., source terminals) of the p-channel nanostructure transistors PMOS through the vias 166SD and the frontside contact structures 158A1 and 158B1, in accordance with some embodiments.

The signal lines 172 are electrically connected to the final gate stacks 140A and 140B through the gate vias 166G, and to the non-Vdd/Vss nodes (e.g., drain terminals) of the nanostructure transistors NMOS and PMOS through the vias 166SD and the contact structures 158A2 and 158B2, in accordance with some embodiments.

Backside contact structures 184 are disposed on the source/drain regions of the active regions 104N1 and 104P1 in the first cell region C1, as shown in FIG. 2B, in accordance with some embodiments. The contact structures 184 are electrically connected to the source terminals of the nanostructure transistors, in accordance with some embodiments. The backside contact structures 184 are electrically connected to backside power rails and may also serve as Vdd/Vss nodes of the circuit in the first cell region C1, in accordance with some embodiments.

A backside metal layer (e.g., backside first-level metal layer (B_M1)) is formed under and electrically connected to the backside contact structures 184, in accordance with some embodiments. The backside metal layer includes several metal lines (tracks) e.g., power rails 190, in accordance with some embodiments. In some embodiments, the backside metal layer includes no signal lines. The metal lines 190 of the backside metal layer are longitudinally oriented along the X direction, in accordance with some embodiments. In some embodiments, the routing density (e.g., the number of tracks per unit area) of the backside metal layer (B_M1) is less than the routing density of the frontside metal layer (F_M1).

In the first cell region C1, the Vss backside power rail 190 is electrically connected to the Vss node (e.g., source terminals) of the n-channel nanostructure transistors NMOS through the backside contact structures 184, and the Vdd backside power rail 190 is electrically connected to the Vdd node (e.g., source terminals) of the p-channel nanostructure transistors PMOS through the backside contact structures 184, in accordance with some embodiments.

Although the backside power rails 190 extend across the second cell region C2, the backside power rails 190 are not electrically connected to the source terminals of the nanostructures in the second cell region C2. In some other embodiments, no backside power rails 190 extend across the second cell region C2. The circuit in the first cell region C1 is powered from both the frontside and backside of the semiconductor structure 100, while the circuit in the second cell region C2 is powered only from the frontside of the semiconductor structure 100, in accordance with some embodiments.

FIGS. 2A and 2B further illustrate reference cross-sections that are used in later figures. Cross-section X1-X1 is in a plane parallel to the longitudinal axis (X direction) of the active region 104N1 and through the active region 104N1 of the first cell region C1, and cross-section X2-X2 is in a plane parallel to the longitudinal axis (X direction) of the active region 104N2 and through the active region 104N2 of the second cell region C2.

Cross-section X3-X3 is in a plane parallel to the longitudinal axis (X direction) o the active region 104P1 and through the active region 104P1 of the first cell region C1, and cross-section X4-X4 is in a plane parallel to the longitudinal axis (X direction) of the active region 104P2 and through the active region 104P2 of the second cell region C2.

Cross-section Y1-Y1 is in a plane parallel to the longitudinal axis (Y direction) of the final gate stack 140A and across two Vdd/Vss nodes of the circuit in the first cell region C1, and cross-section Y2-Y2 is in a plane parallel to the longitudinal axis (Y direction) of the final gate stack 140B and across two Vdd/Vss nodes of the circuit in the second cell region C2.

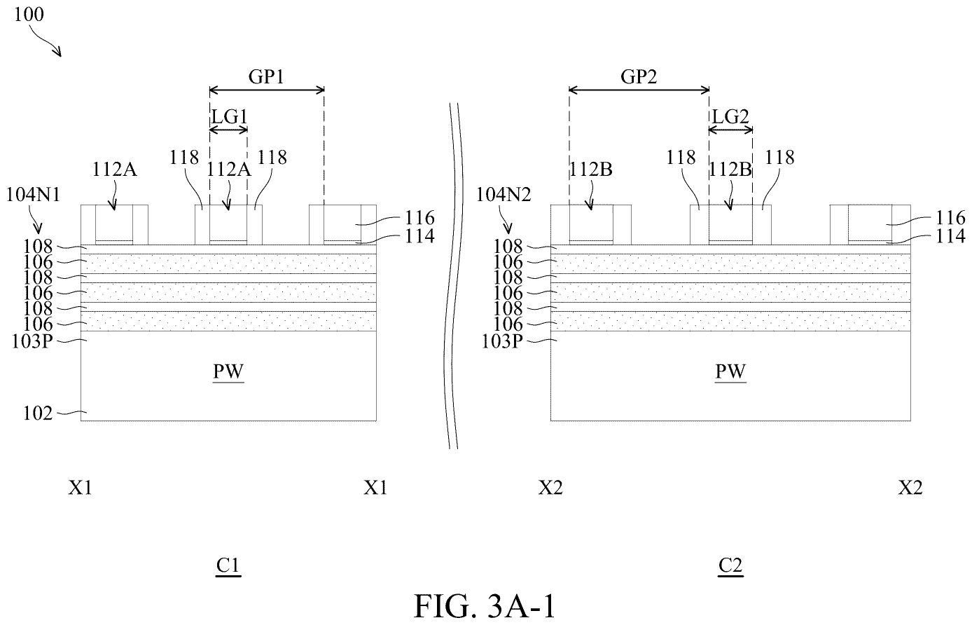

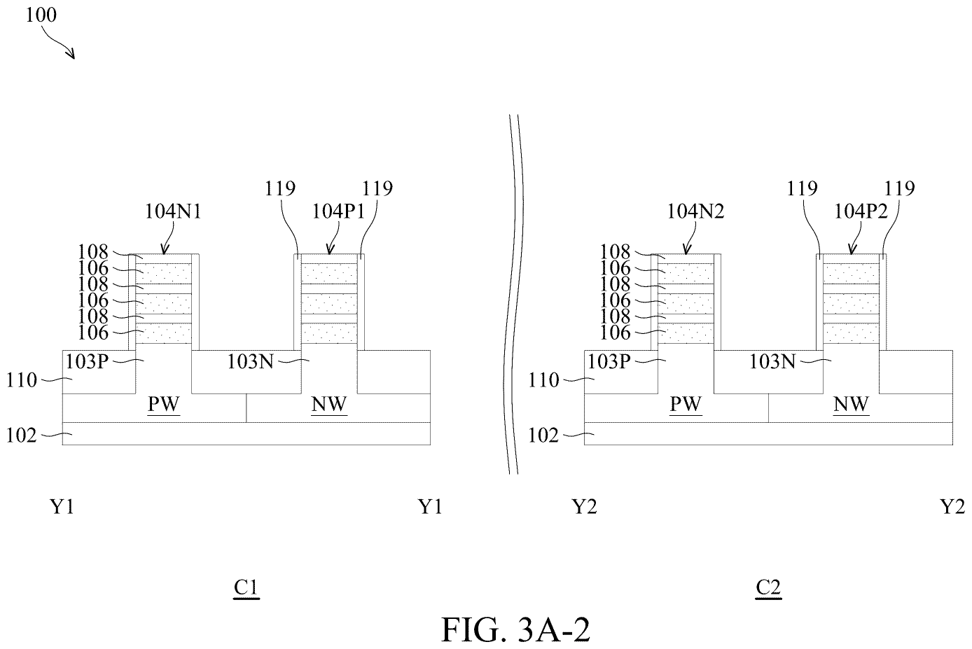

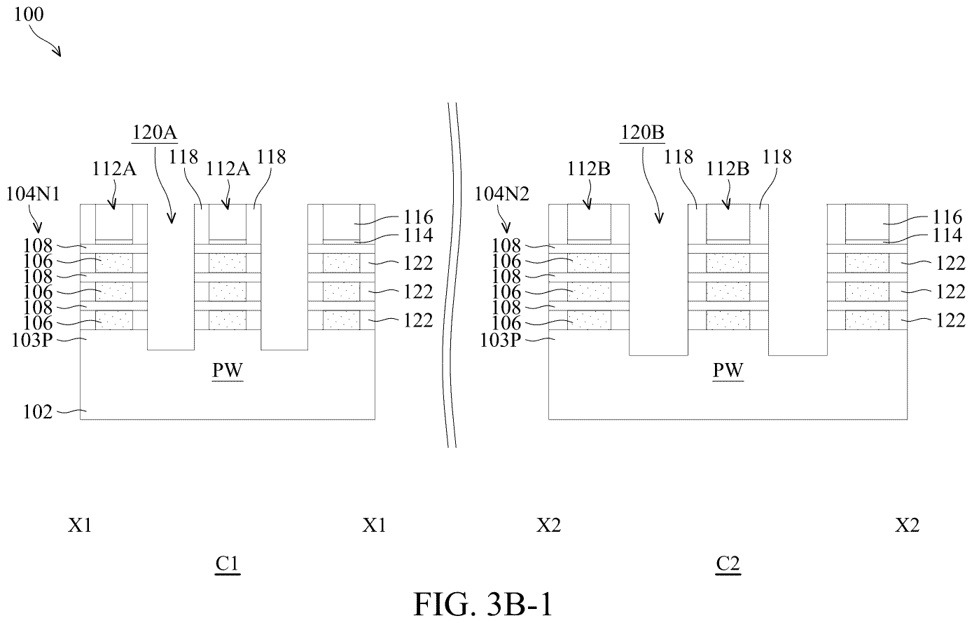

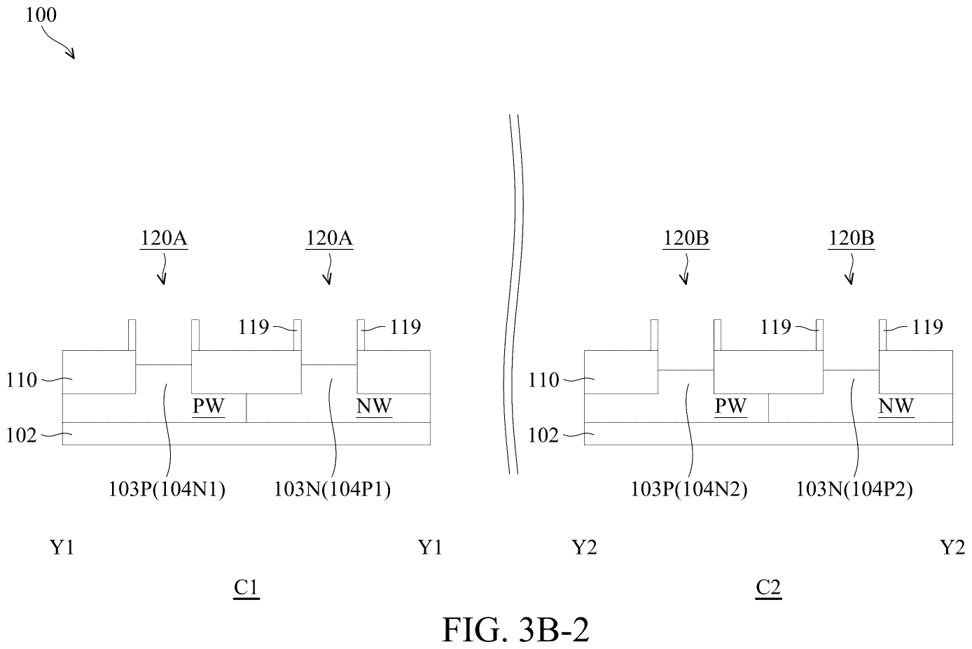

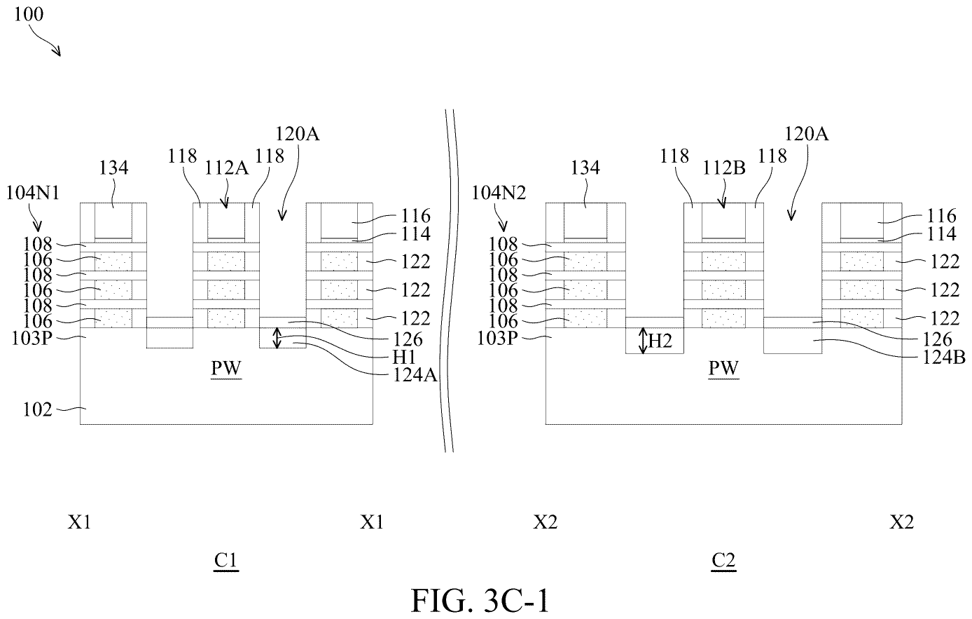

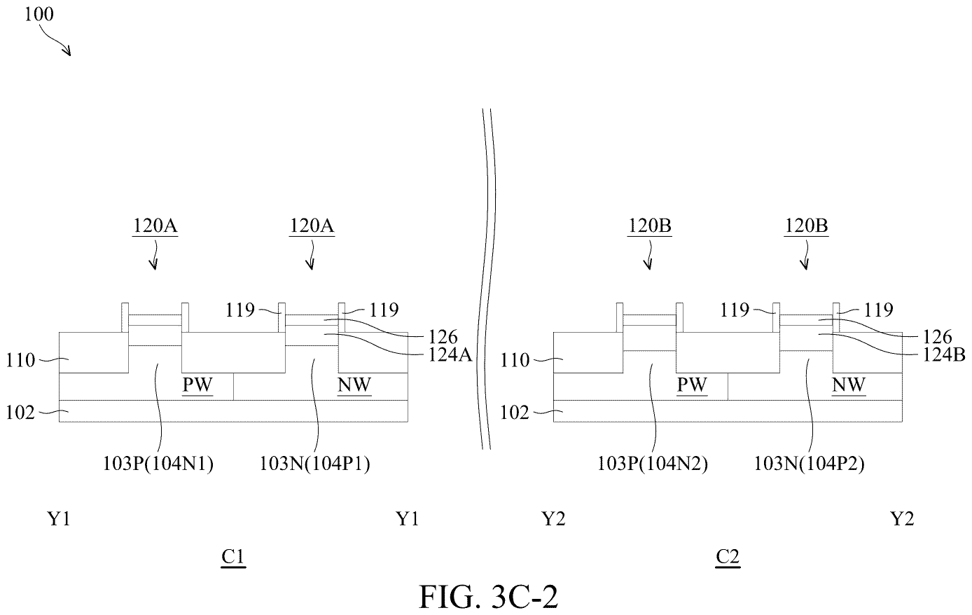

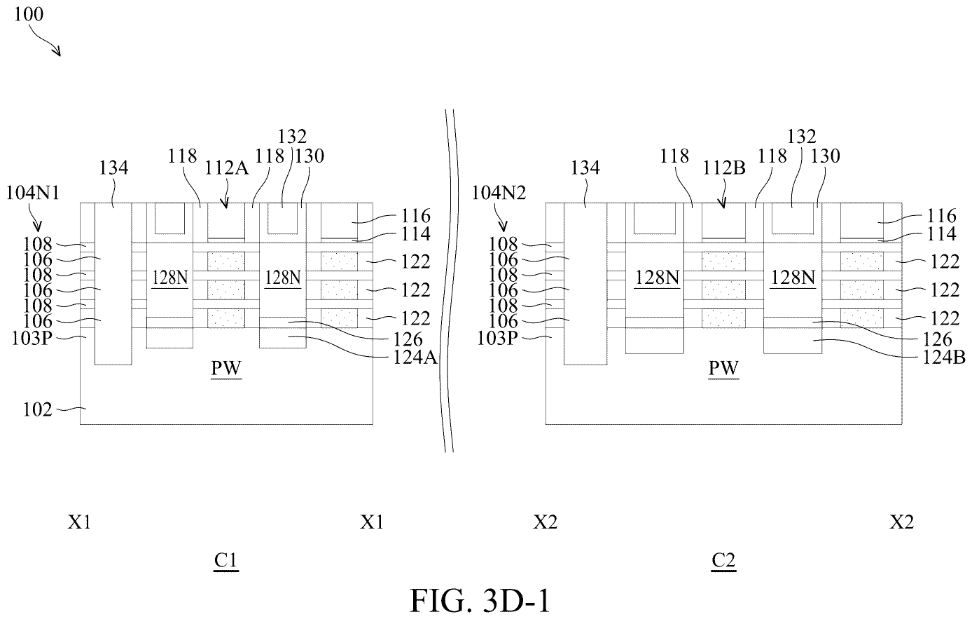

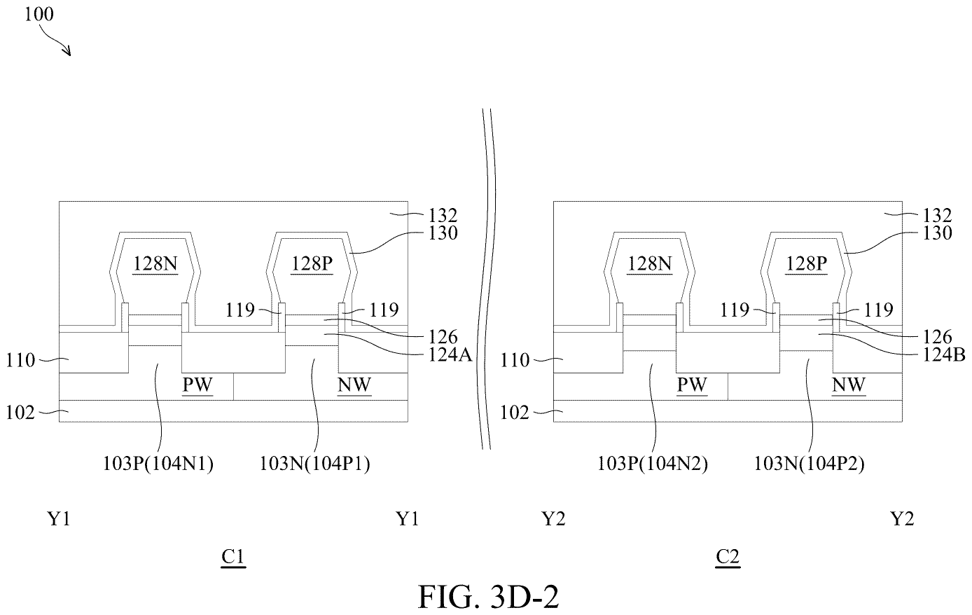

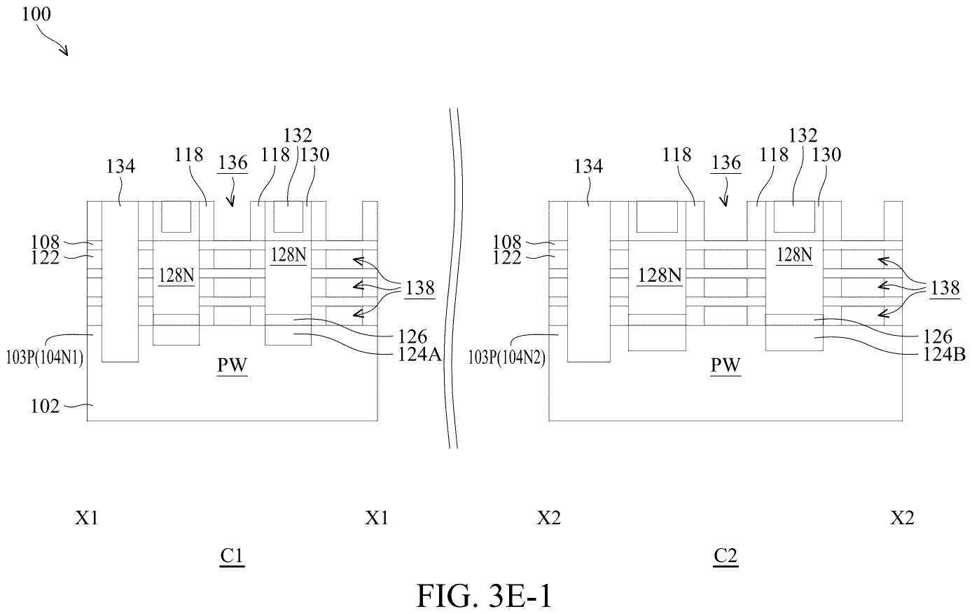

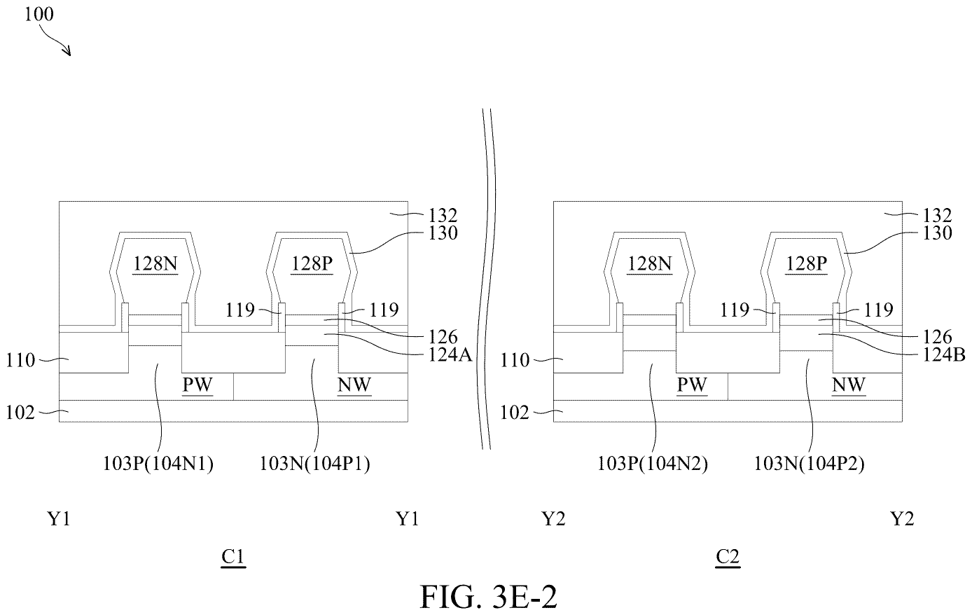

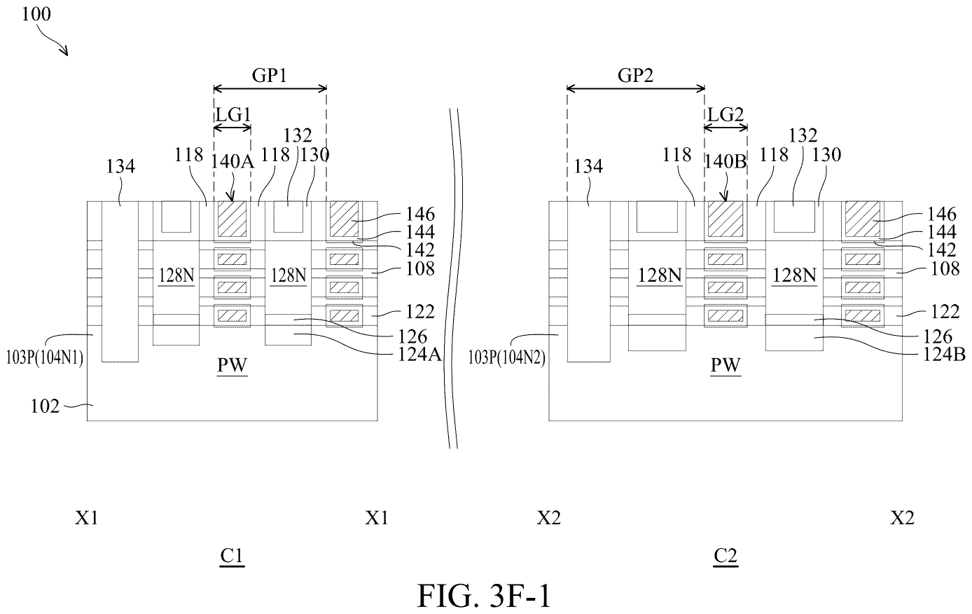

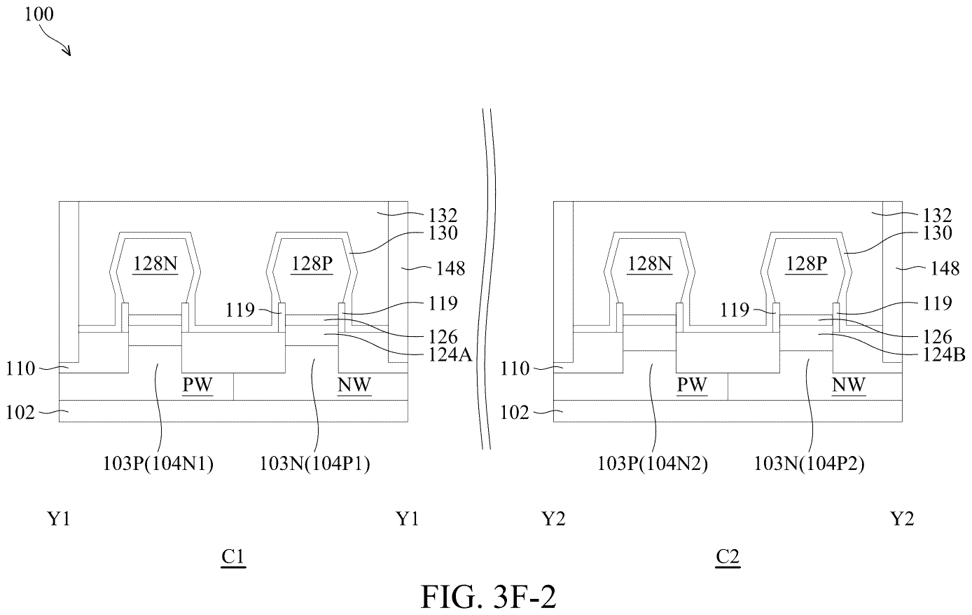

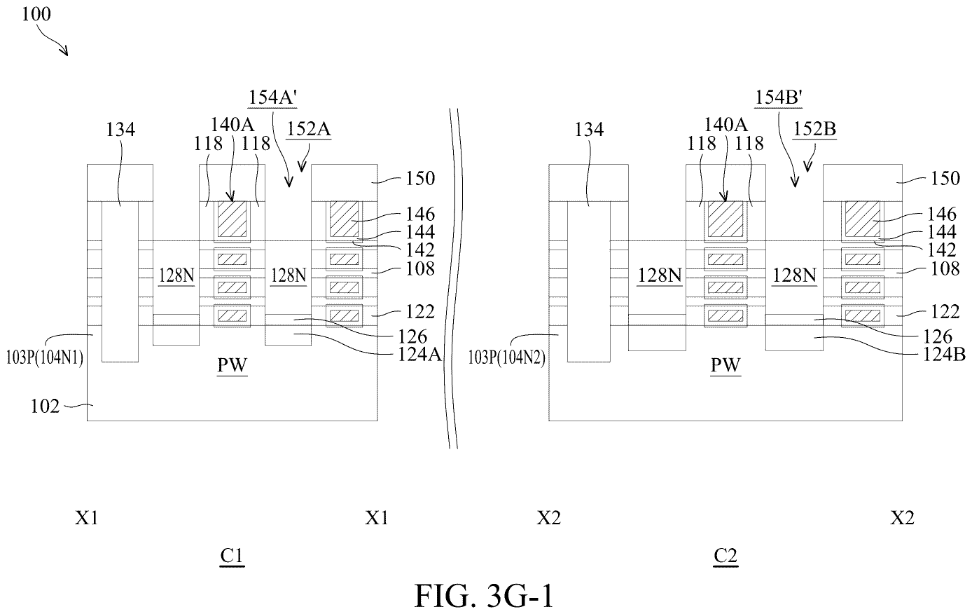

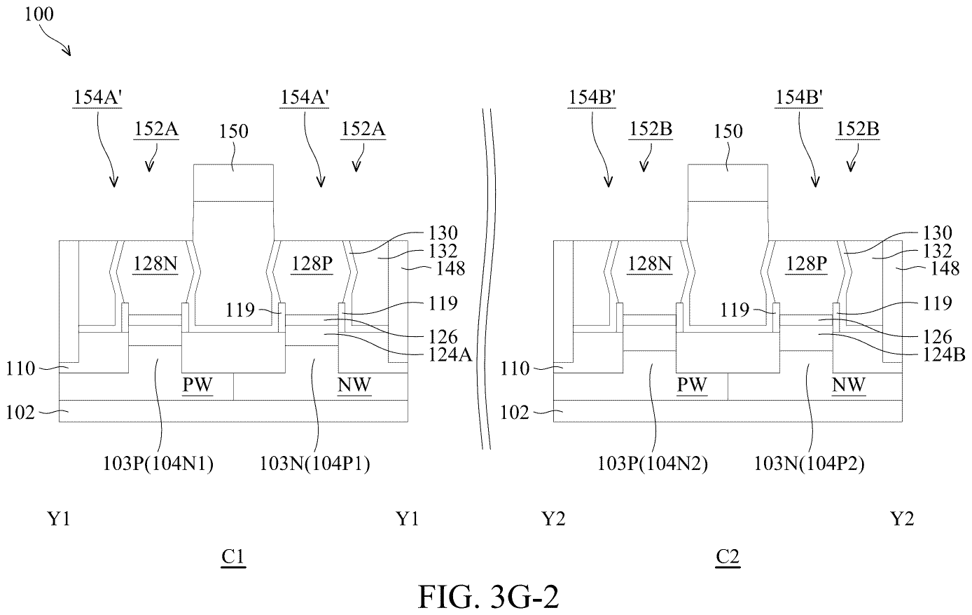

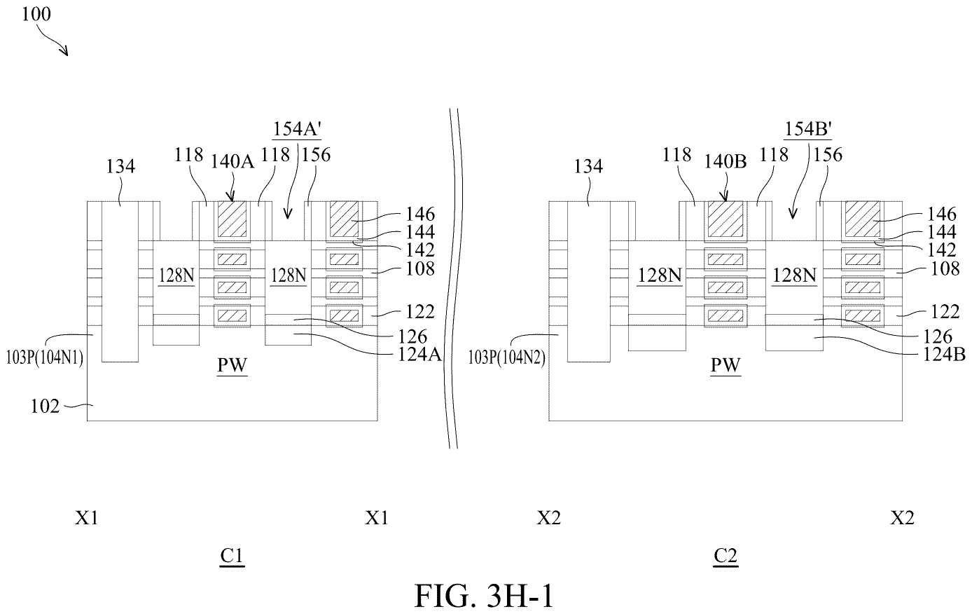

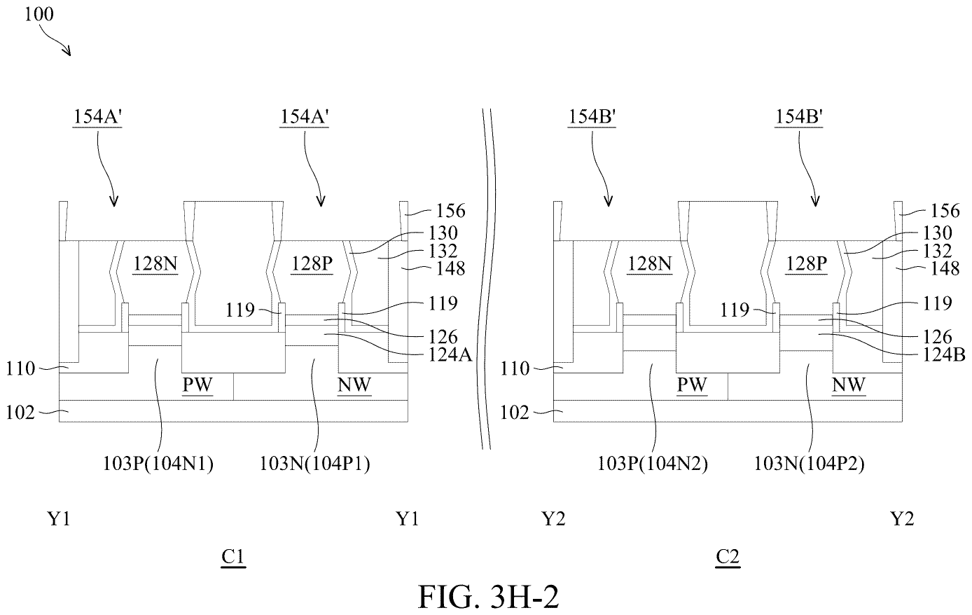

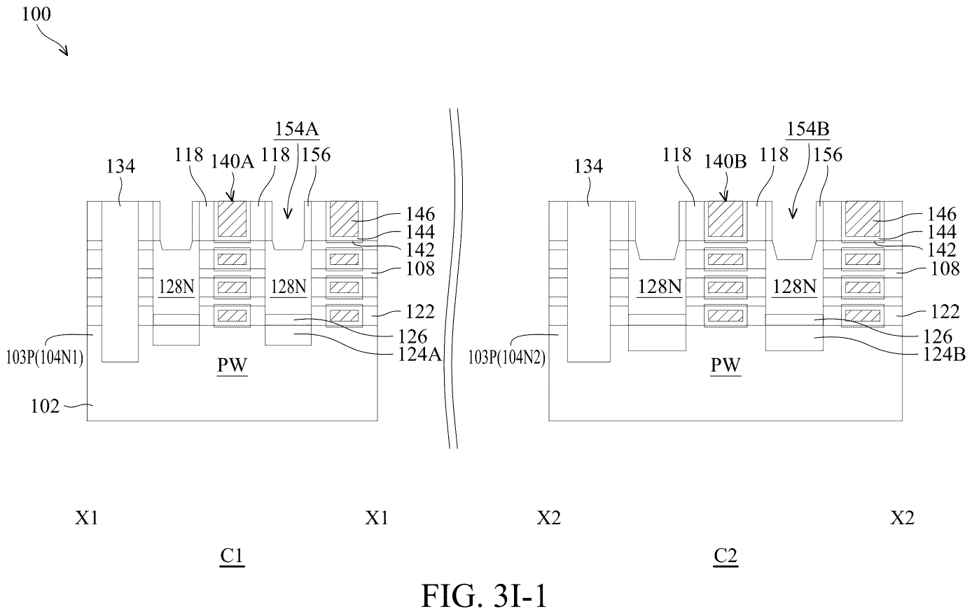

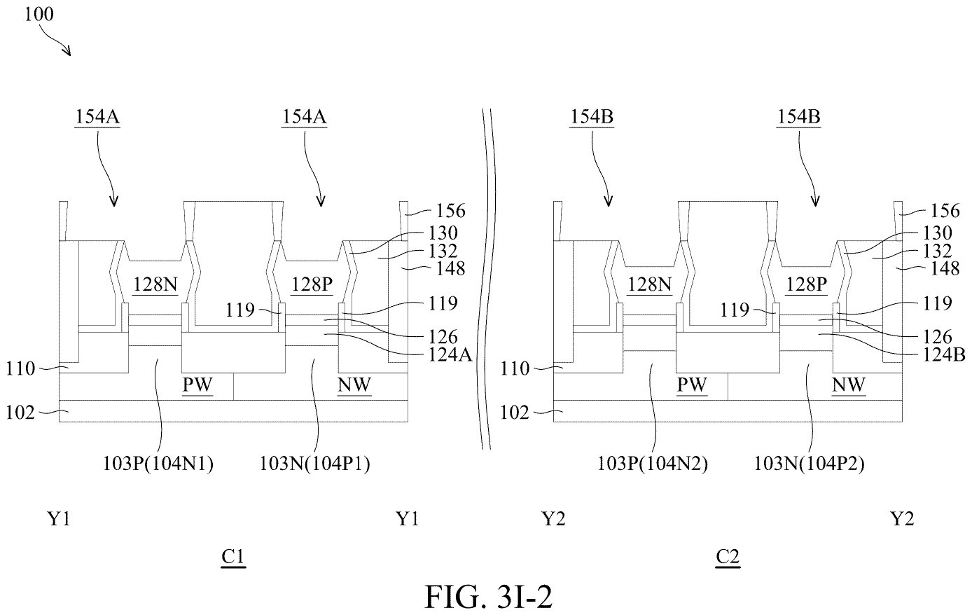

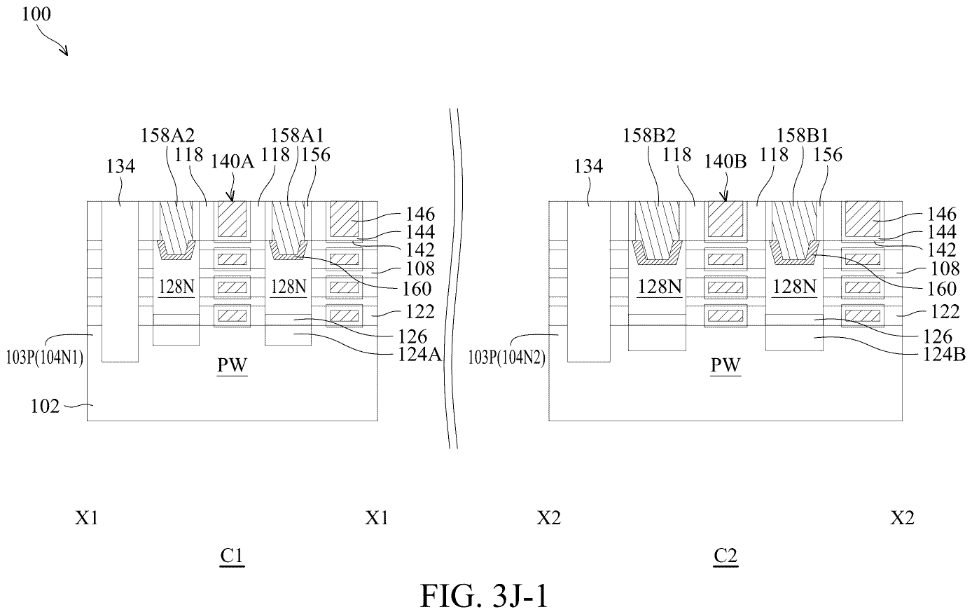

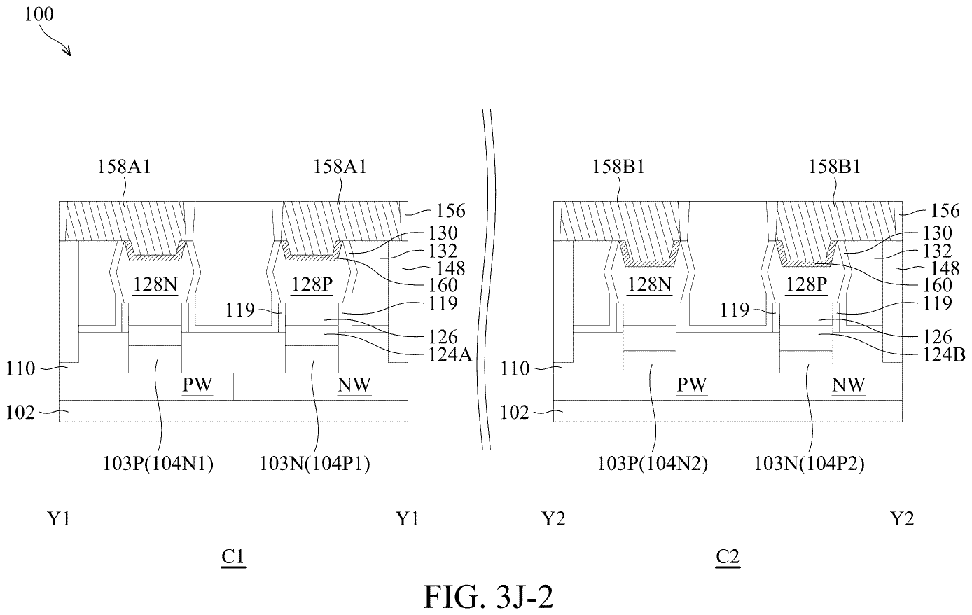

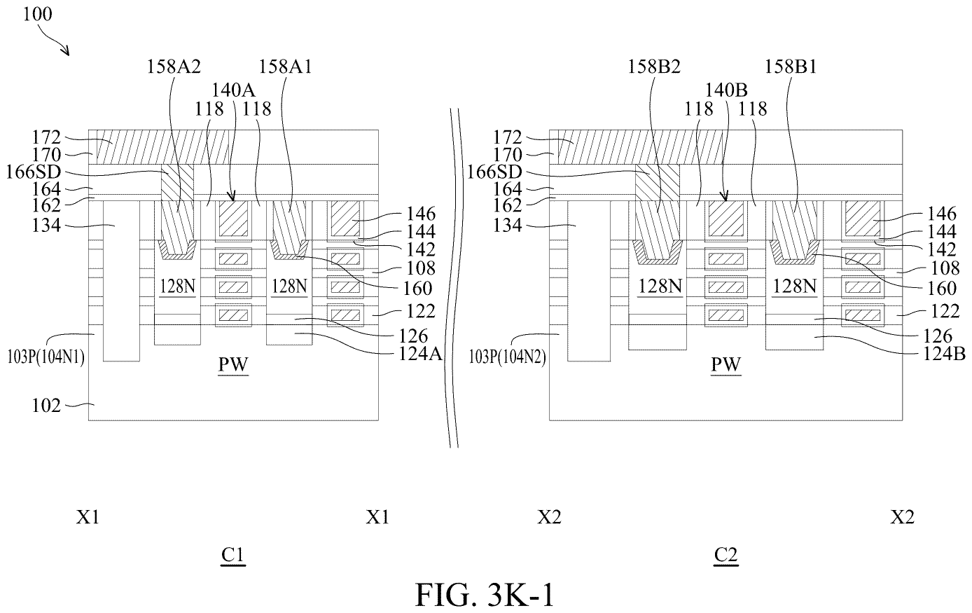

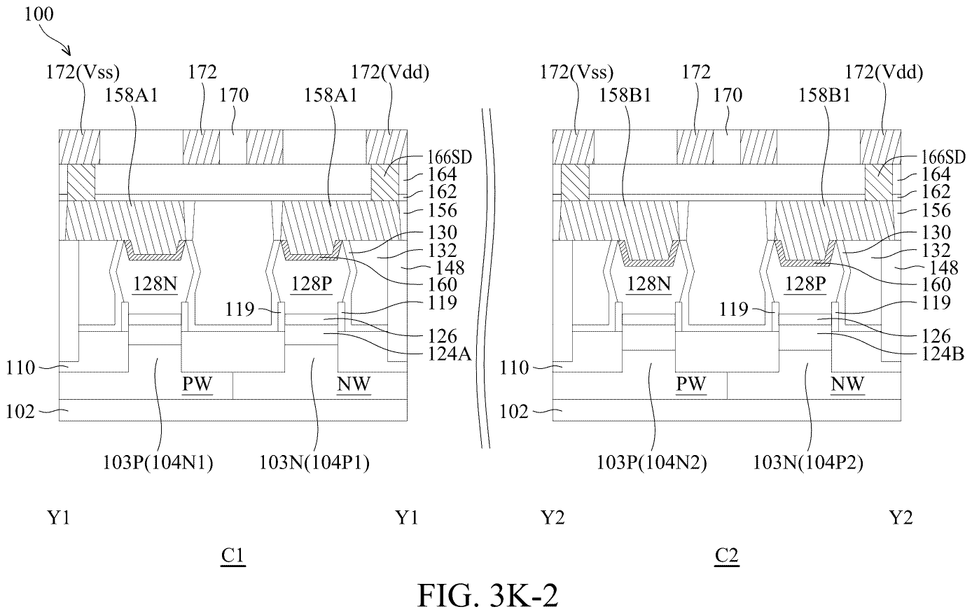

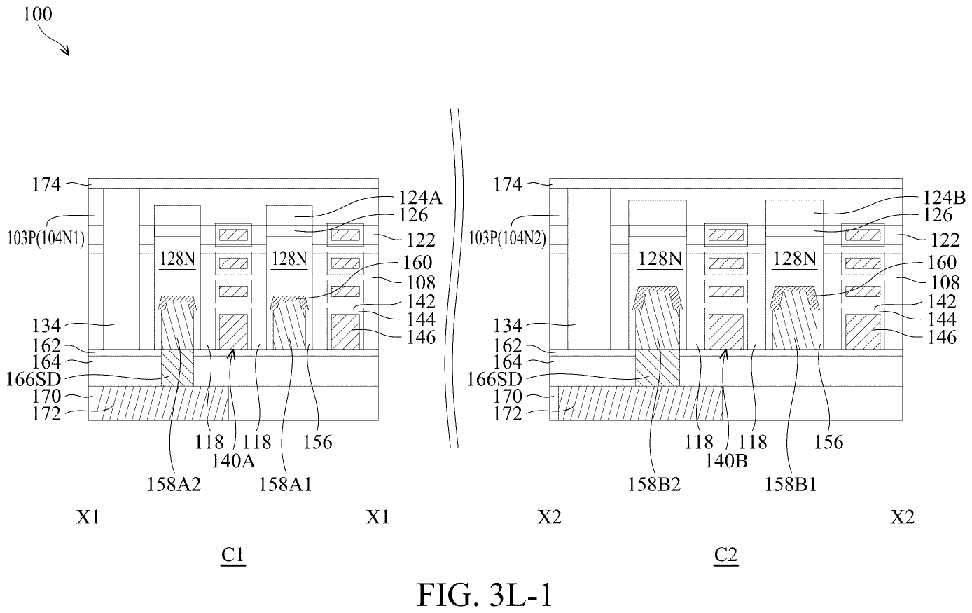

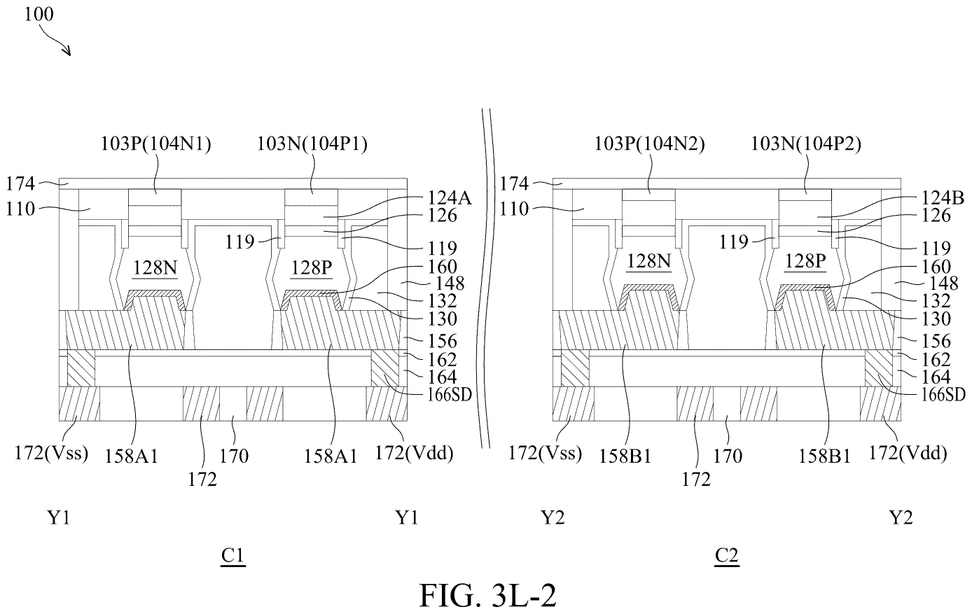

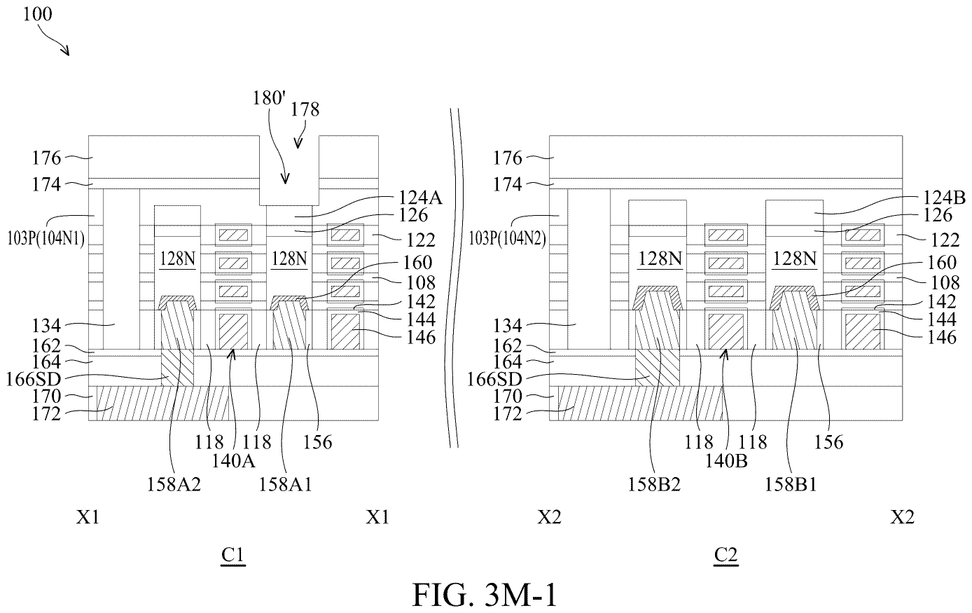

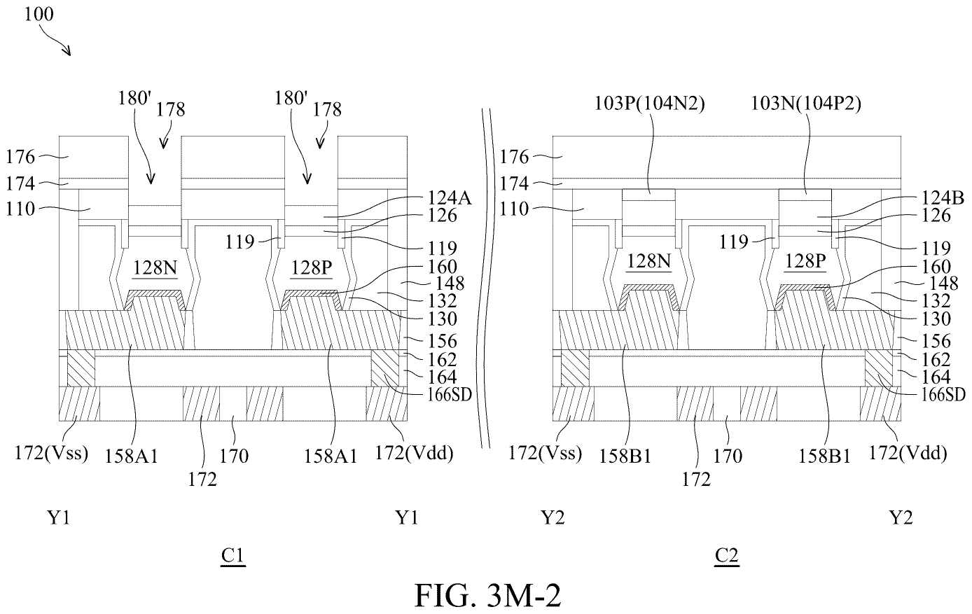

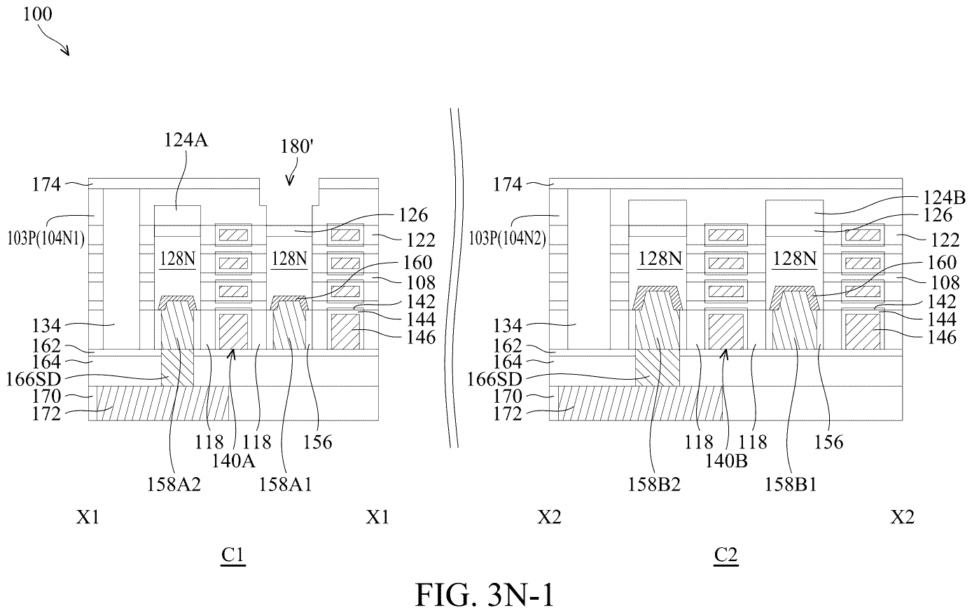

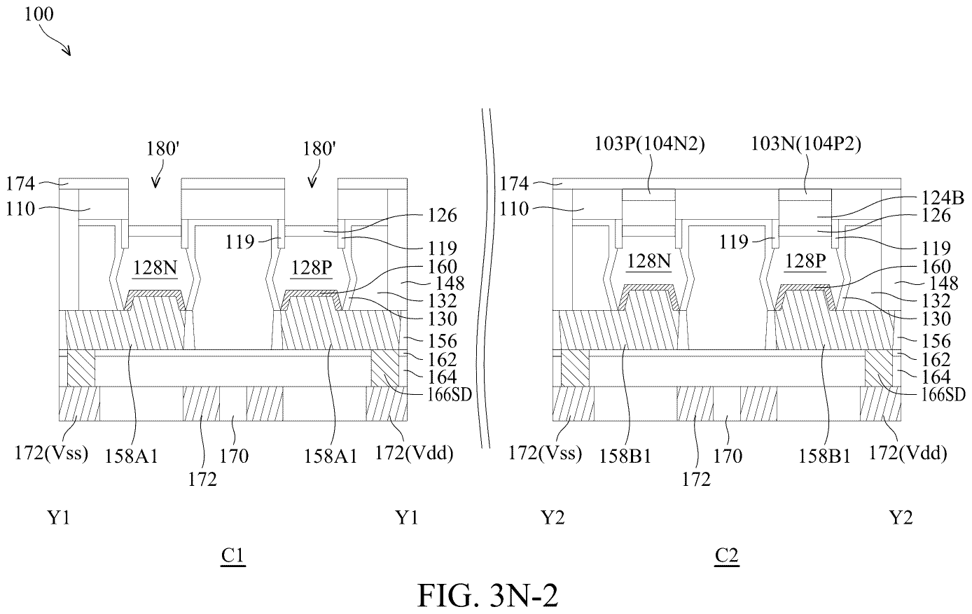

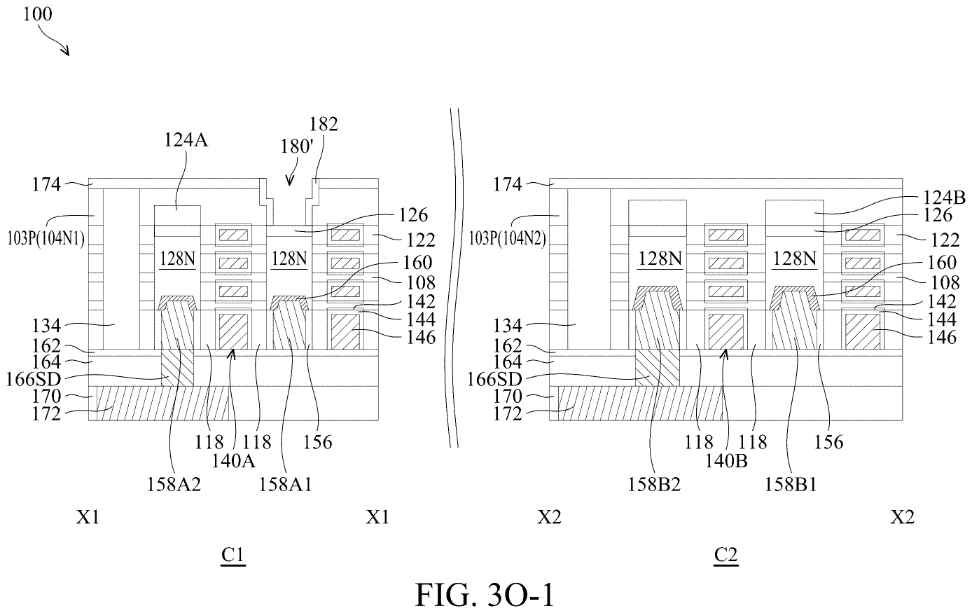

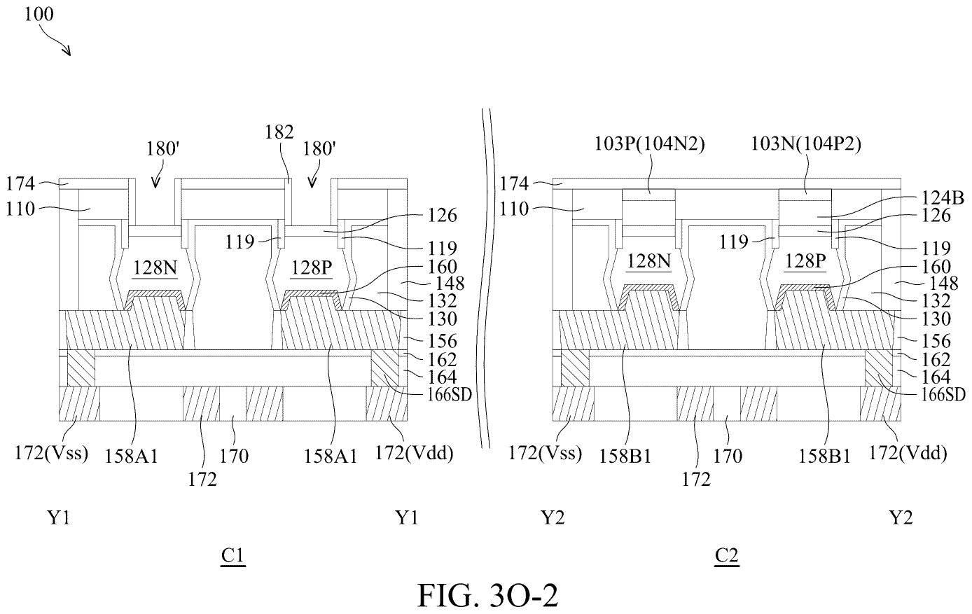

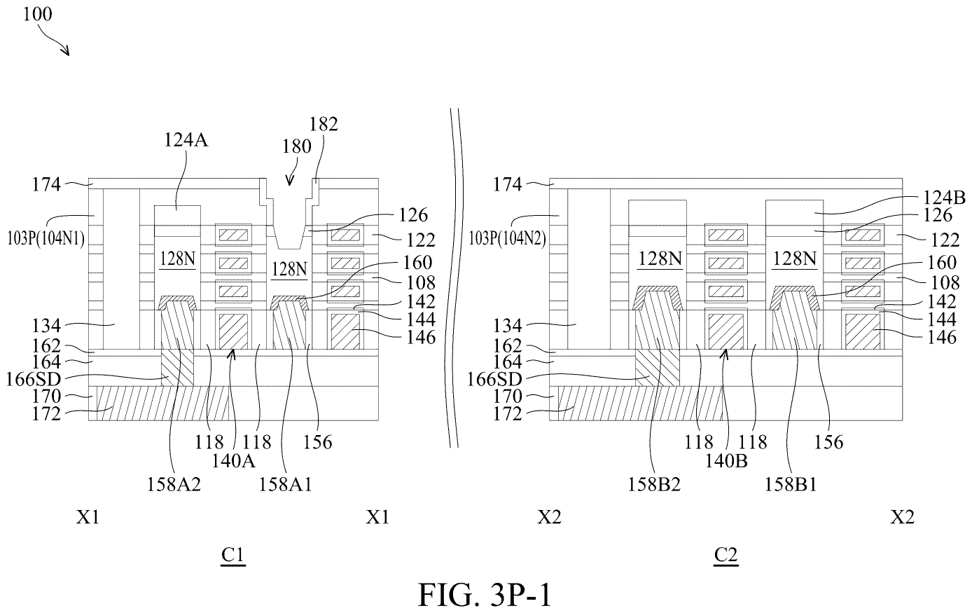

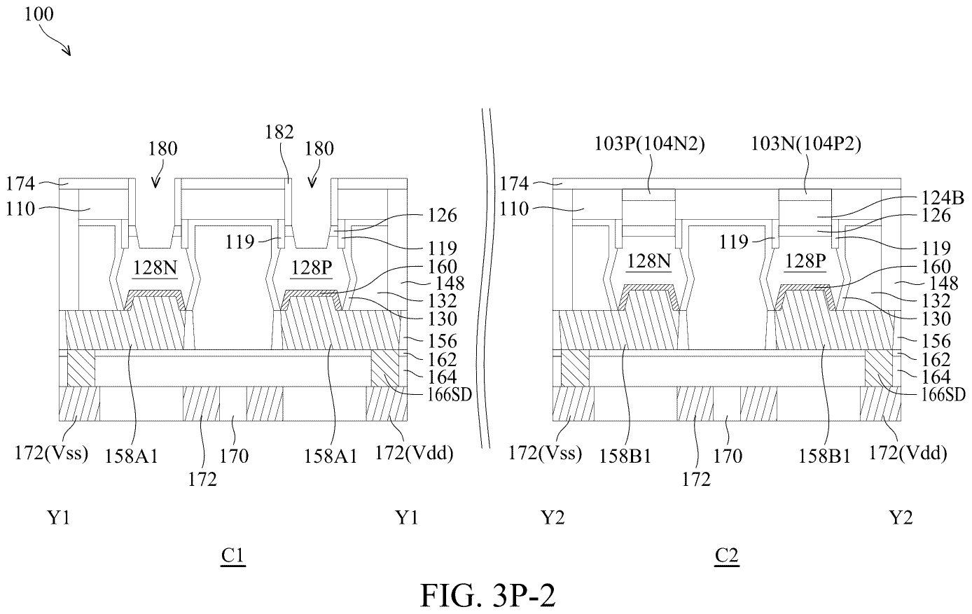

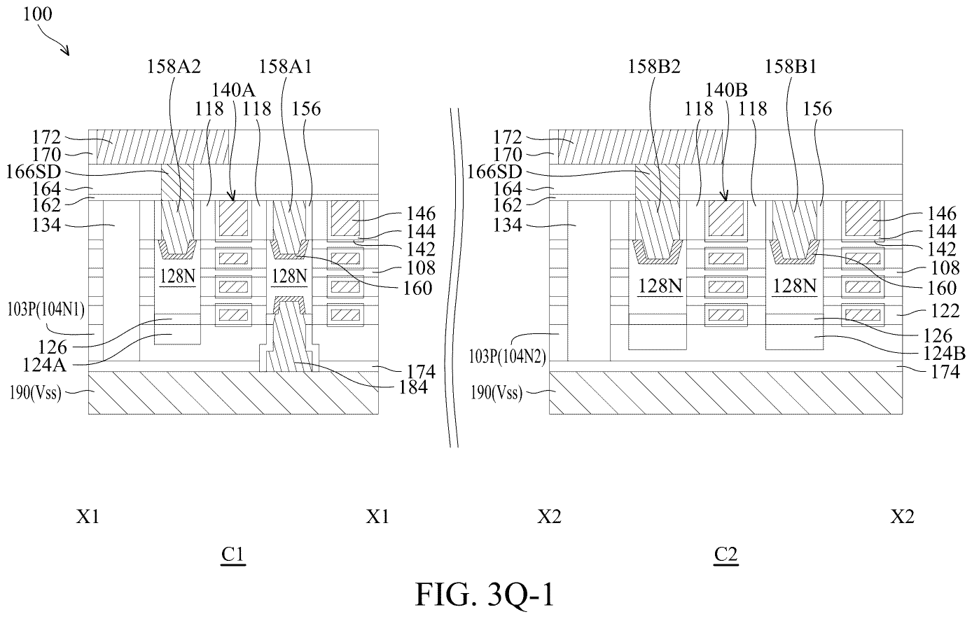

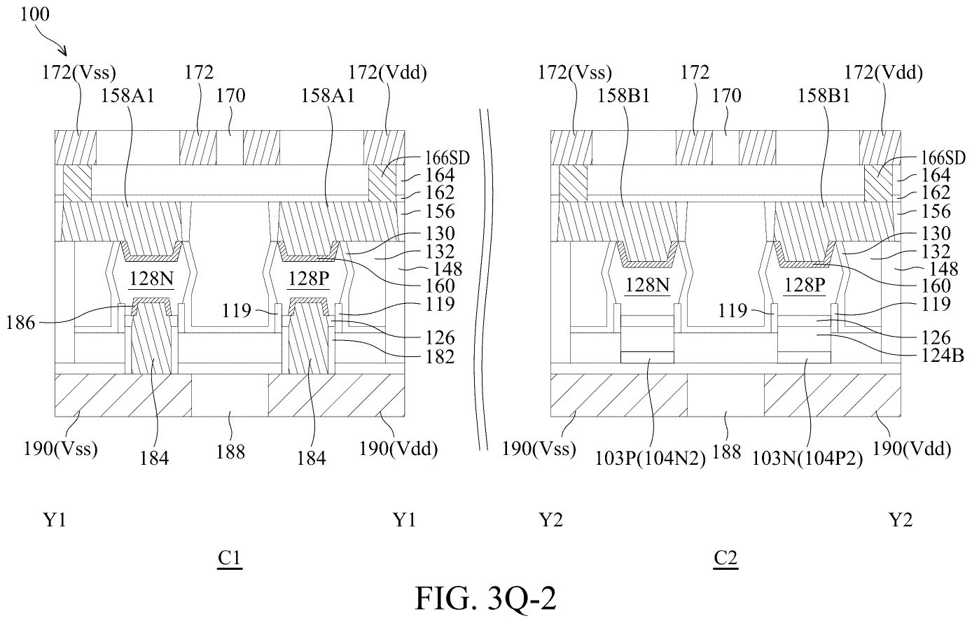

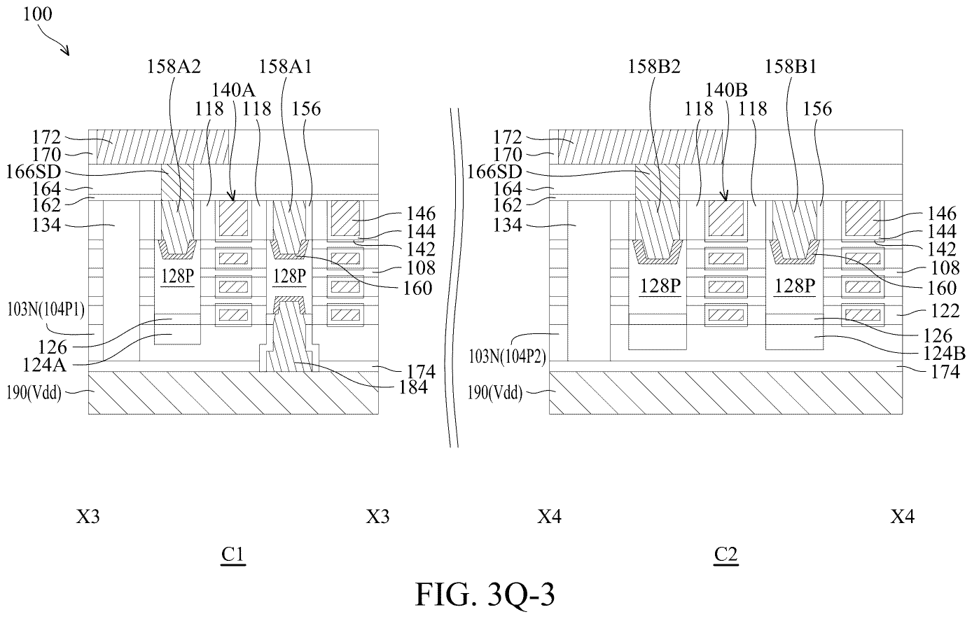

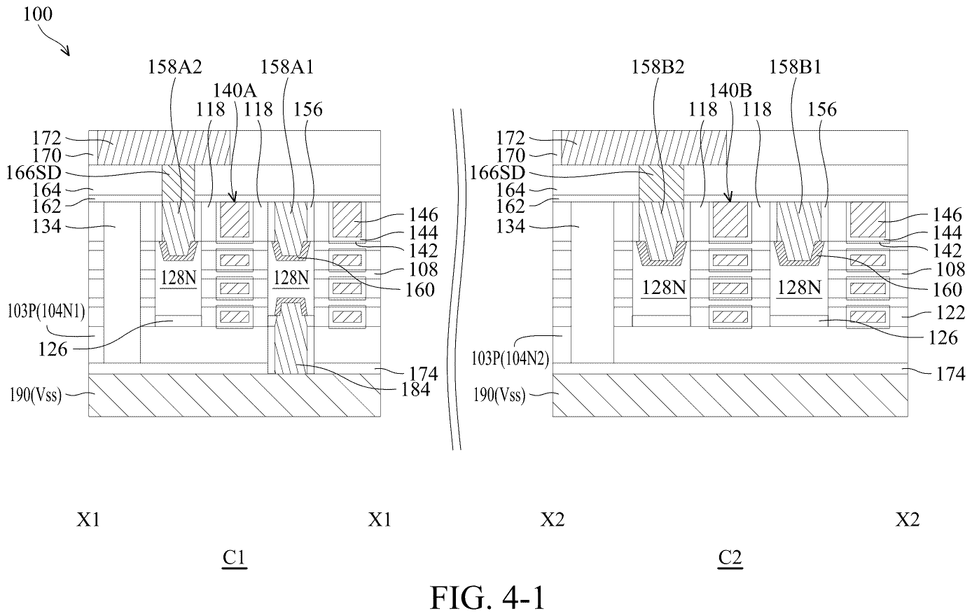

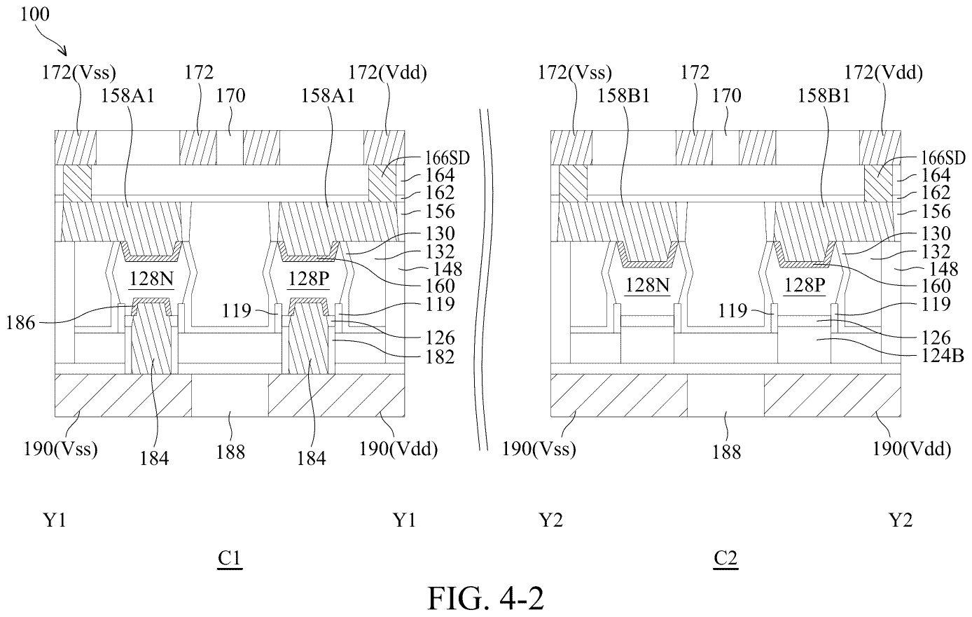

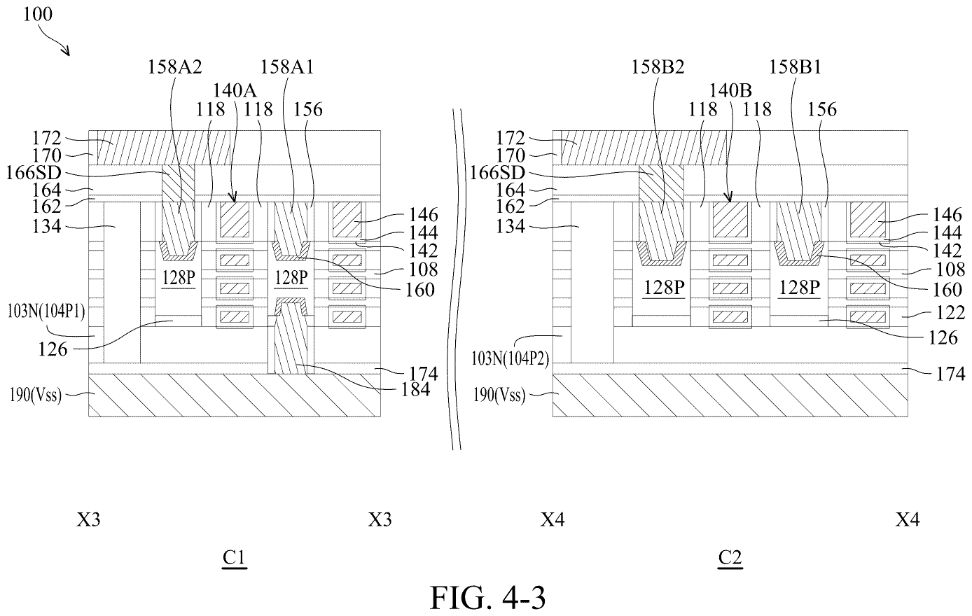

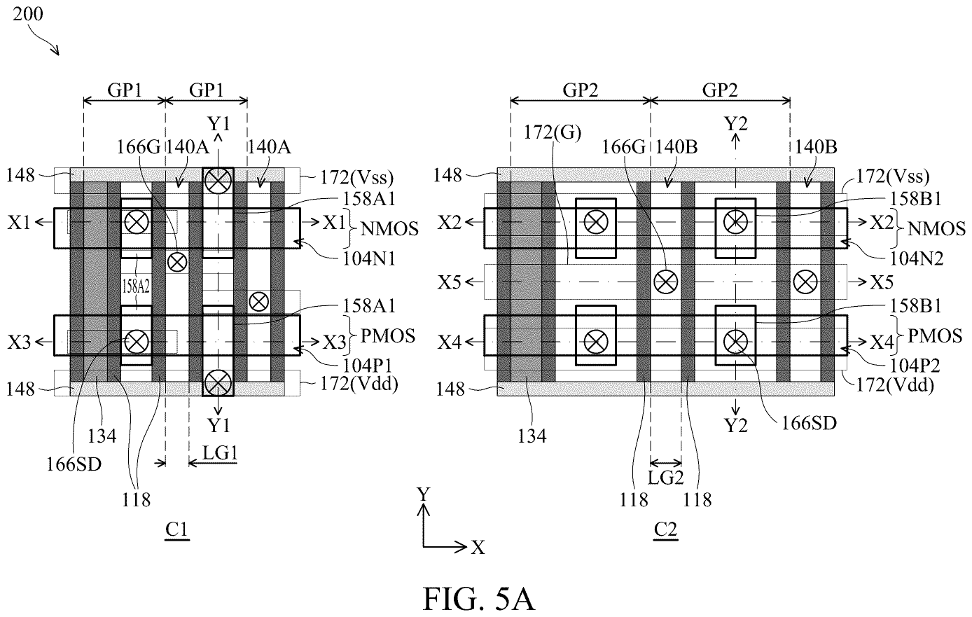

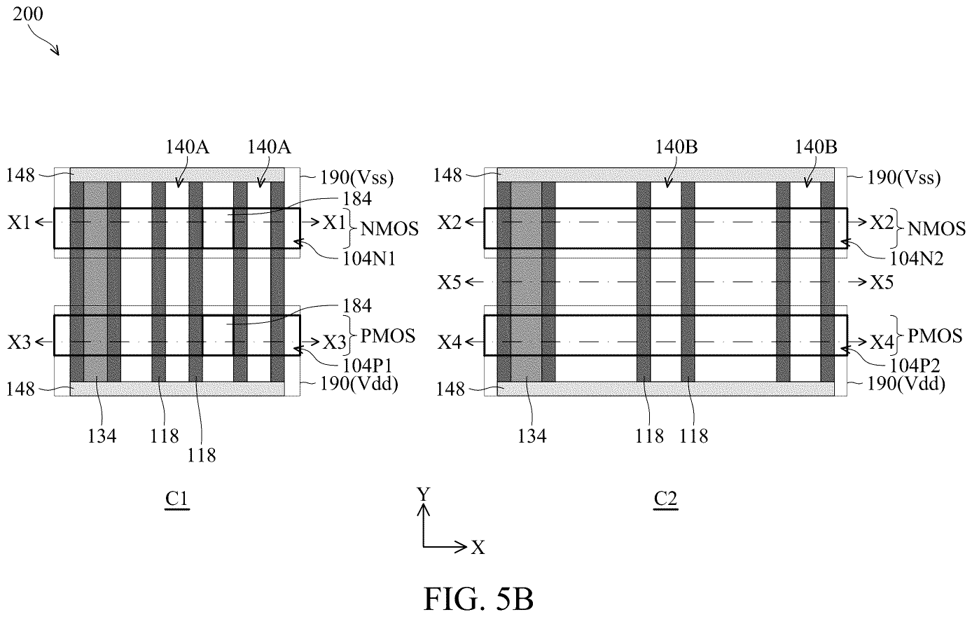

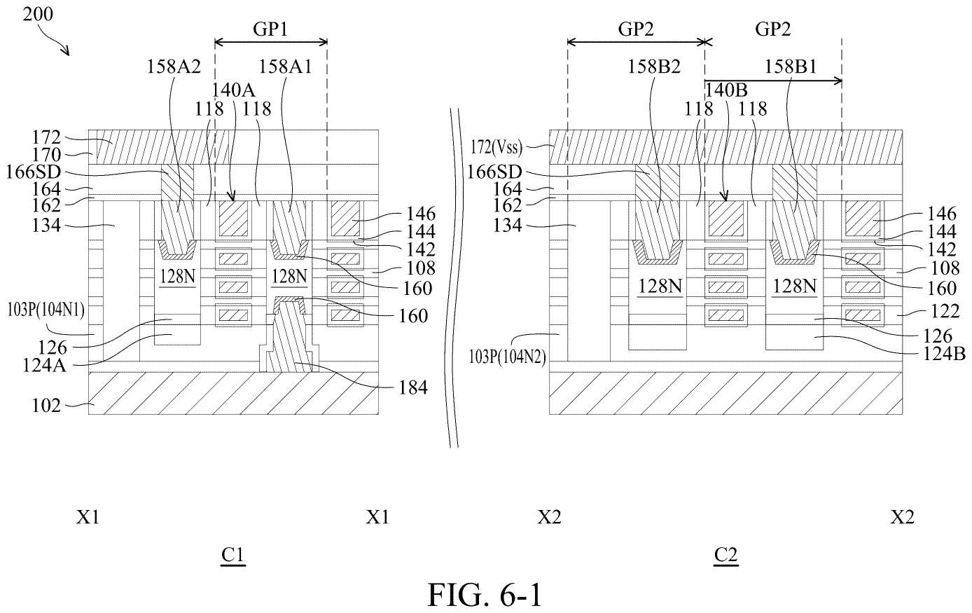

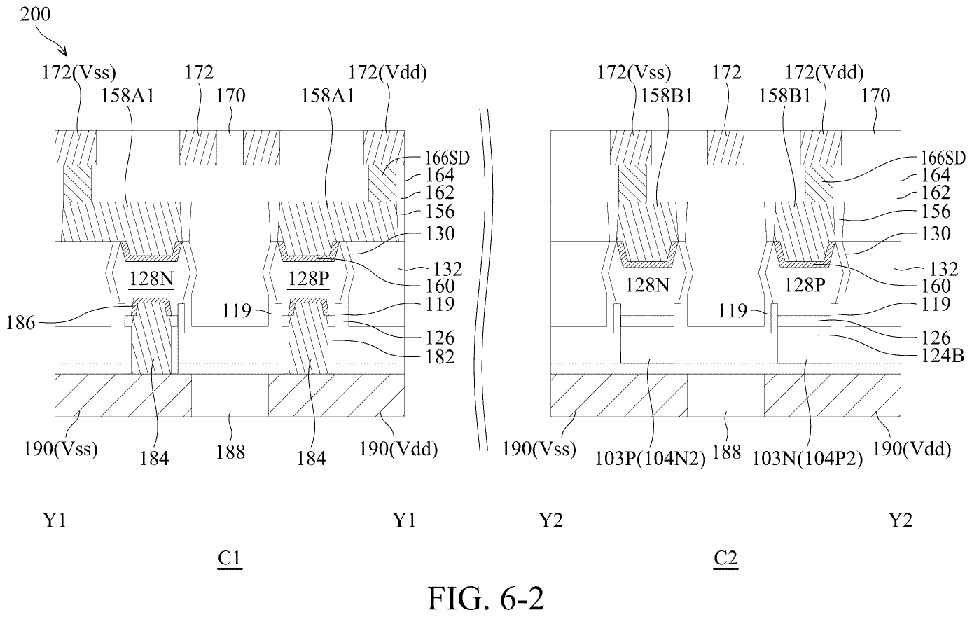

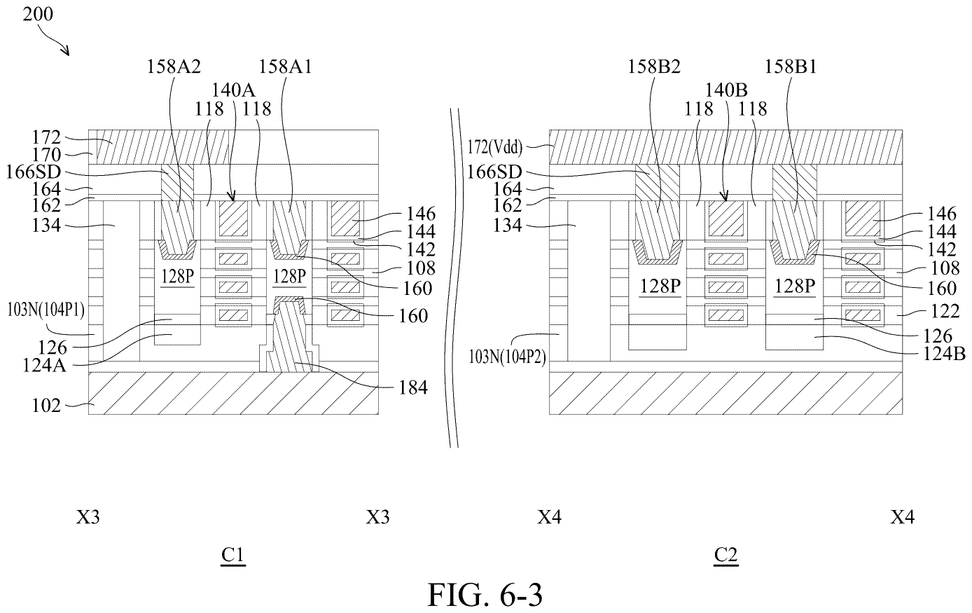

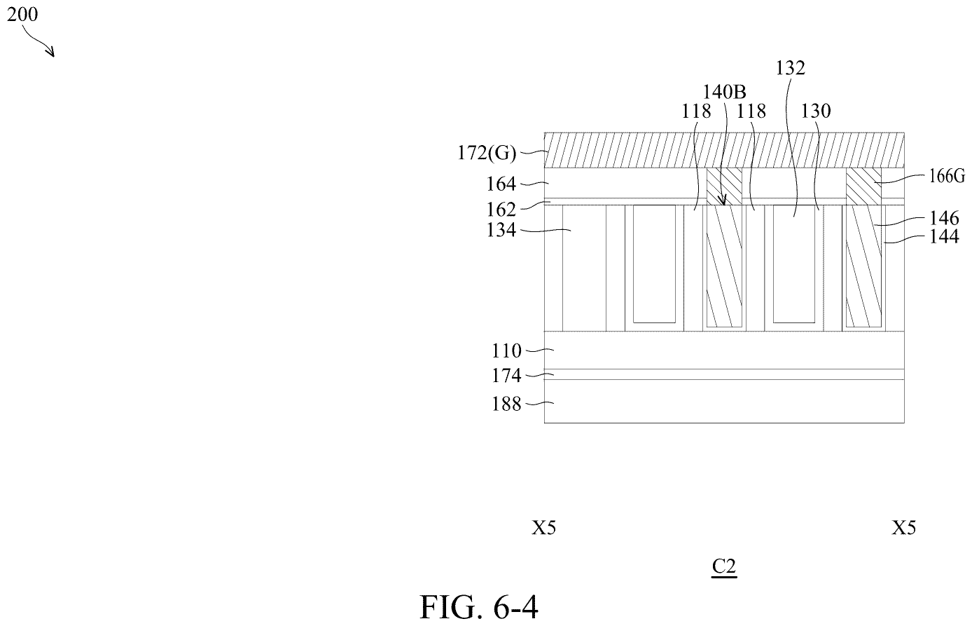

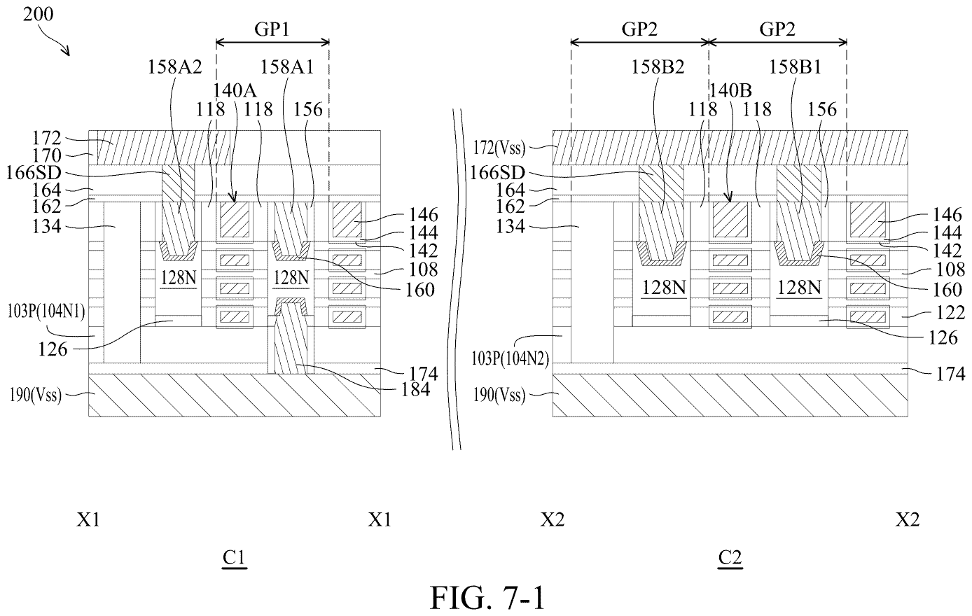

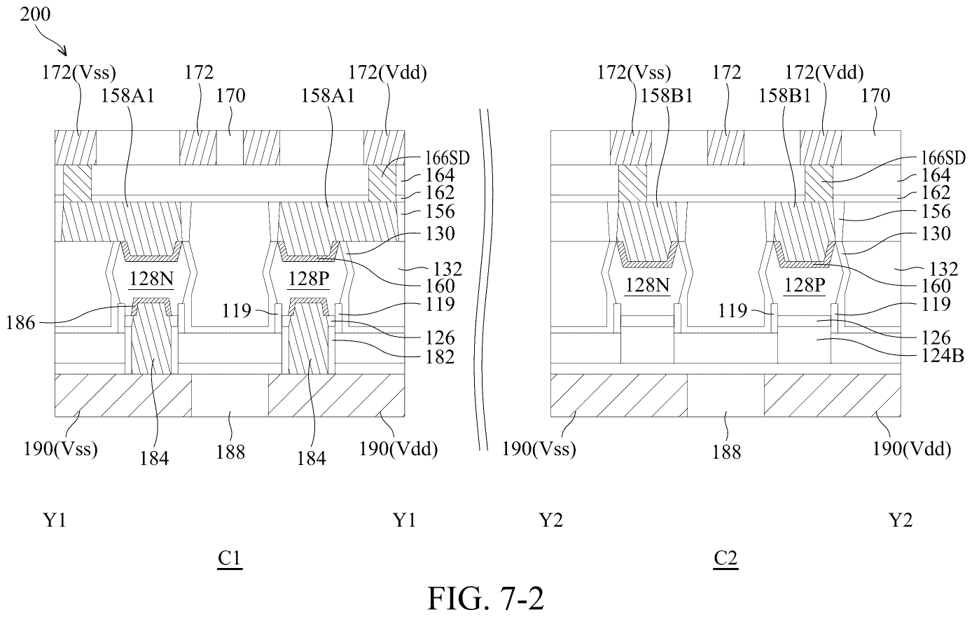

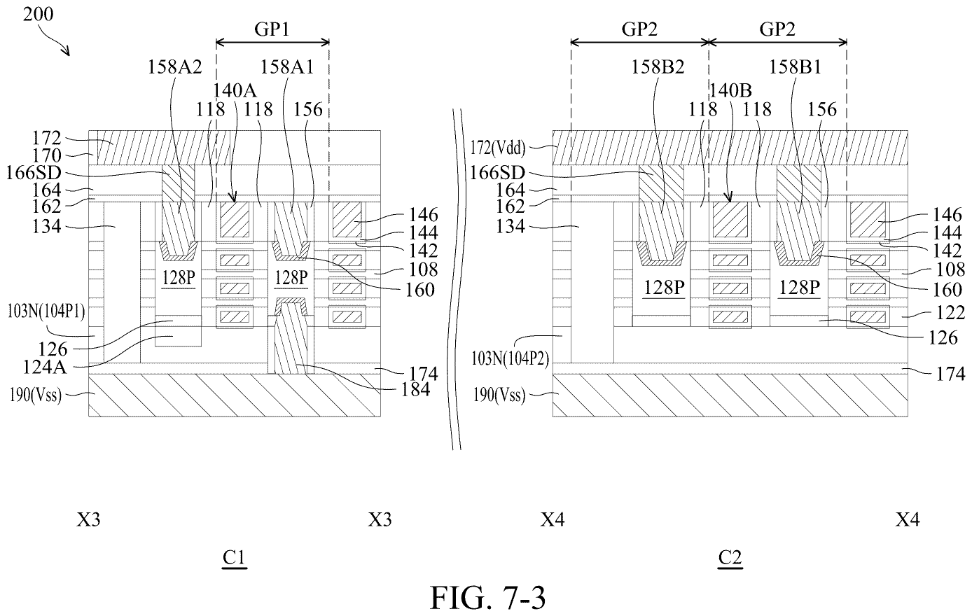

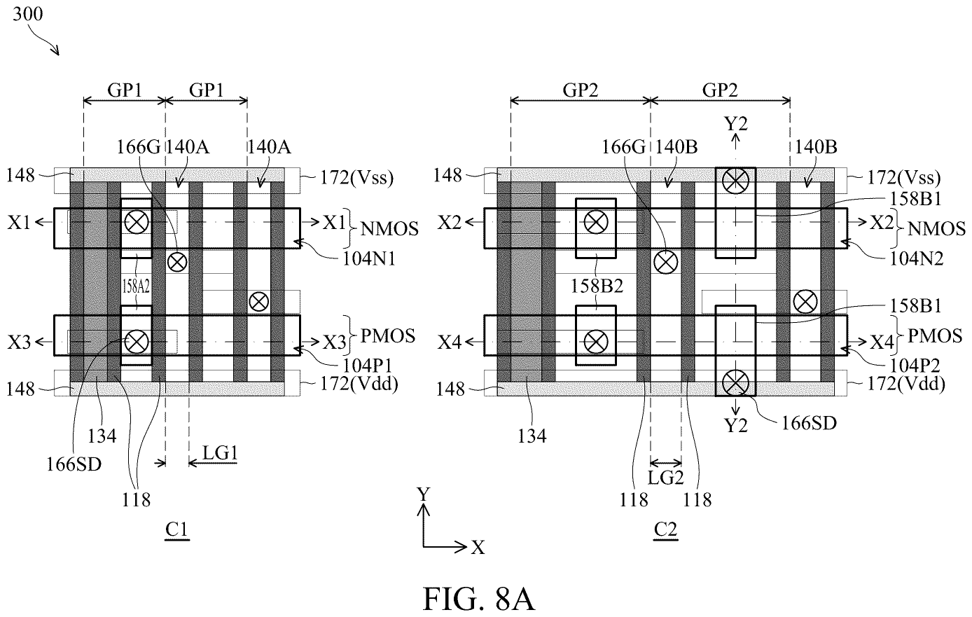

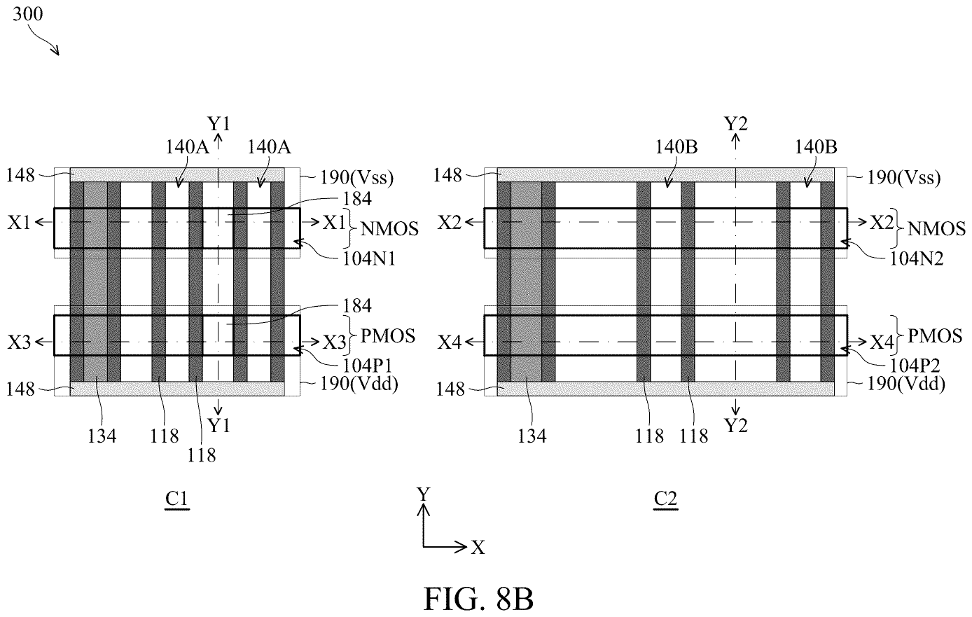

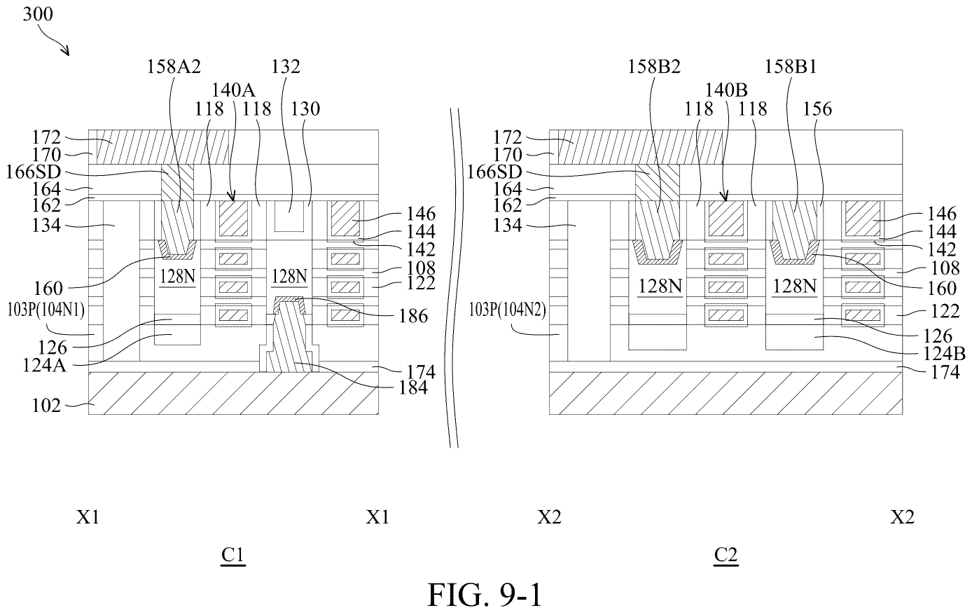

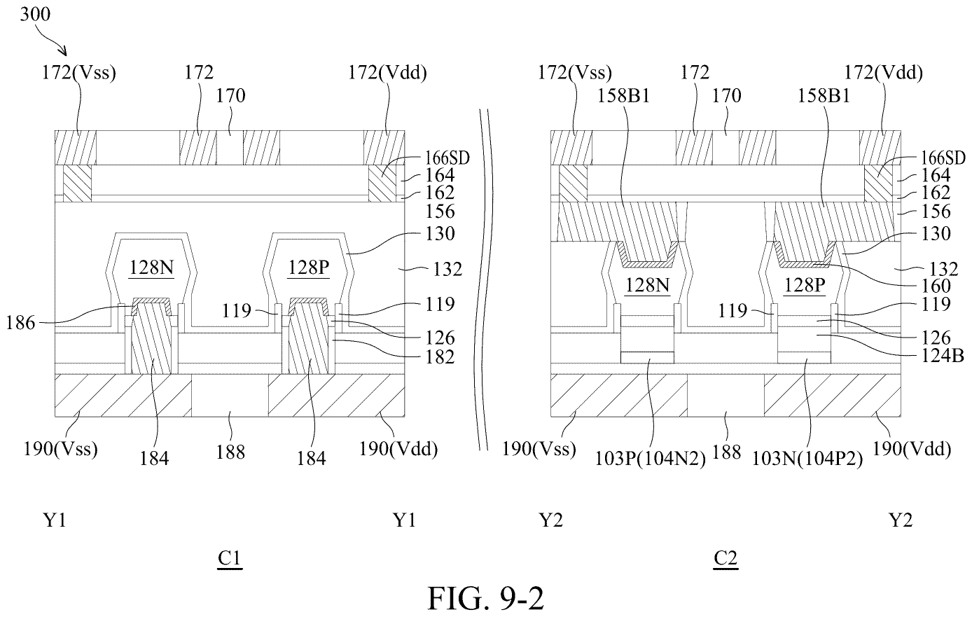

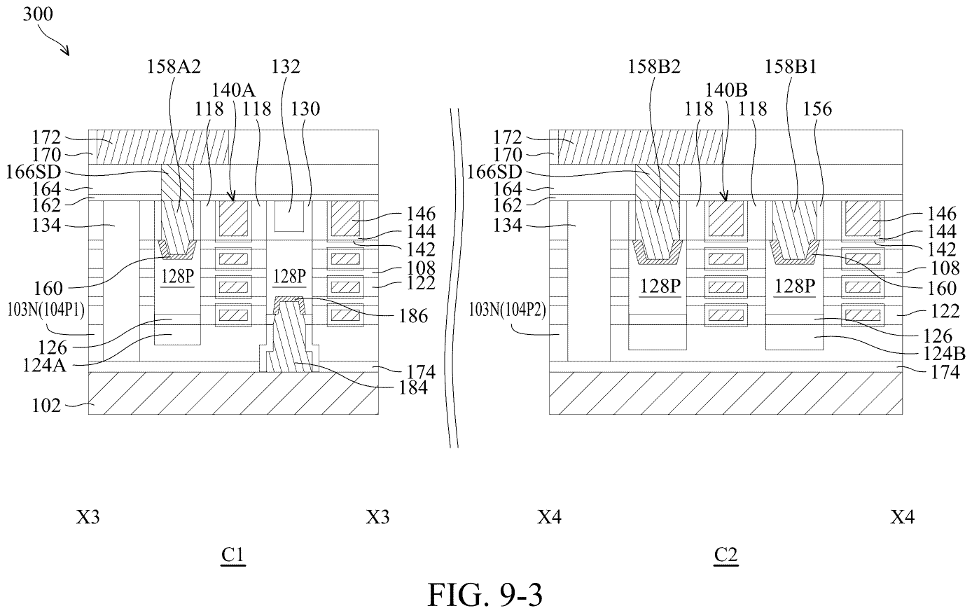

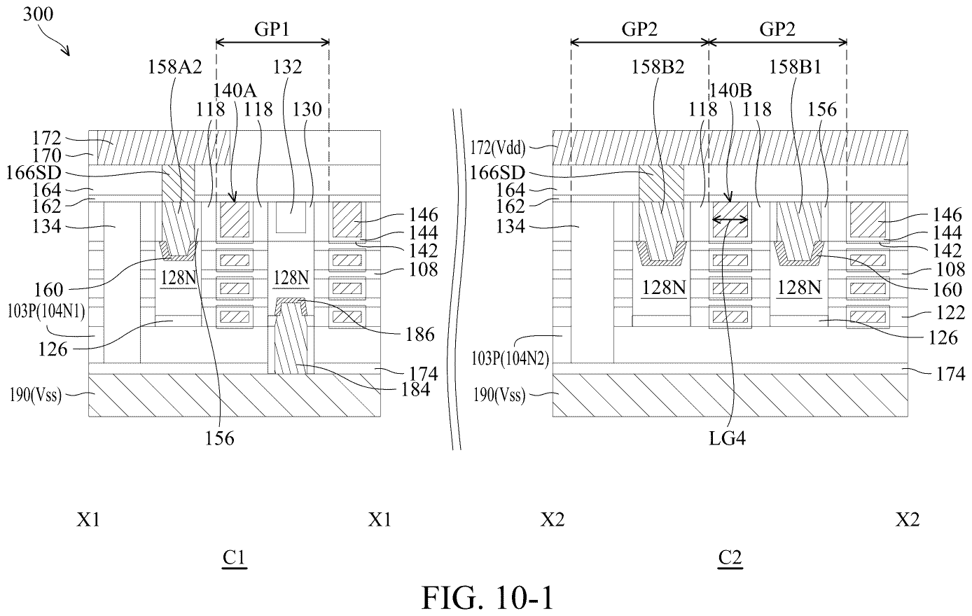

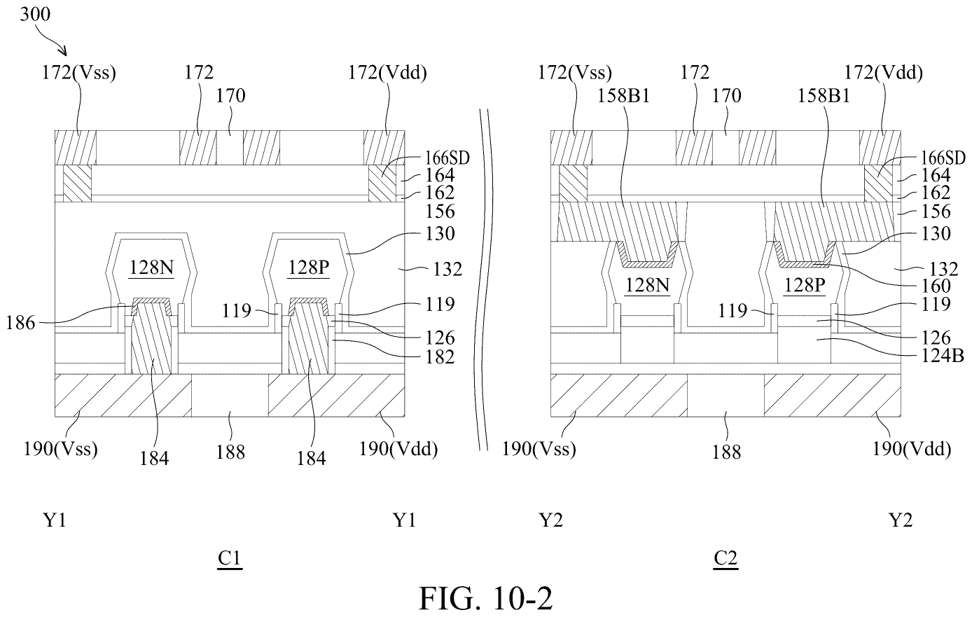

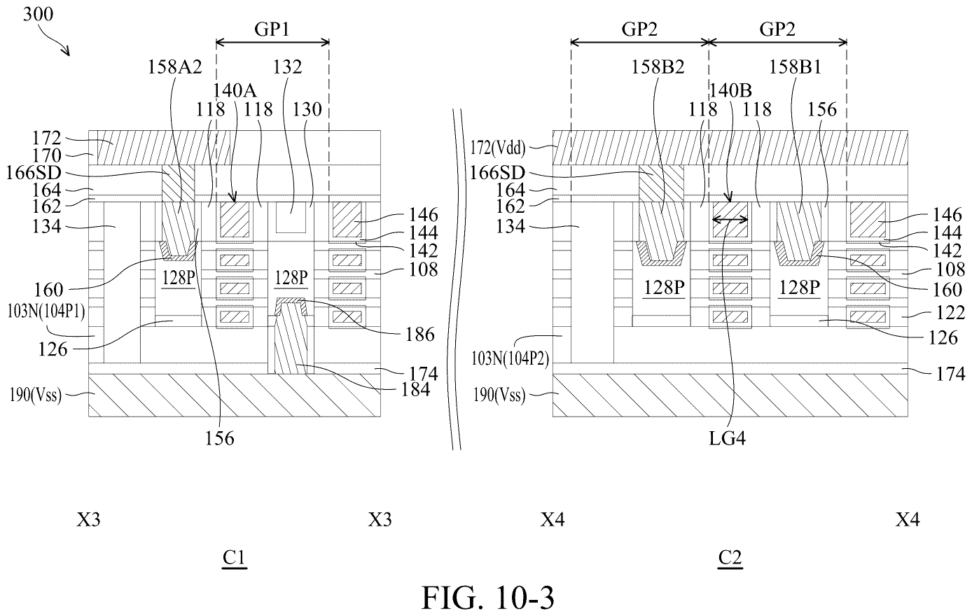

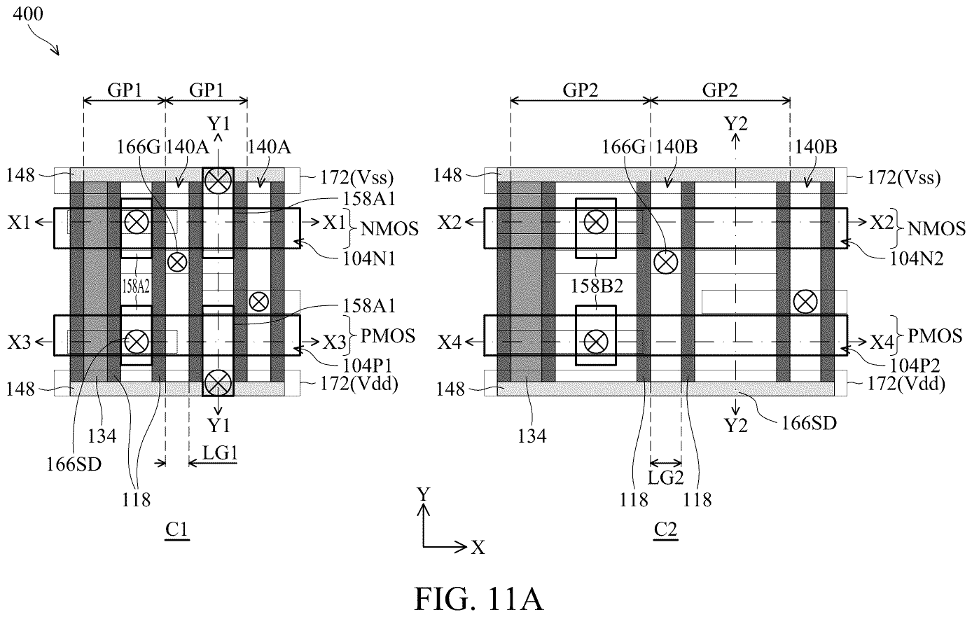

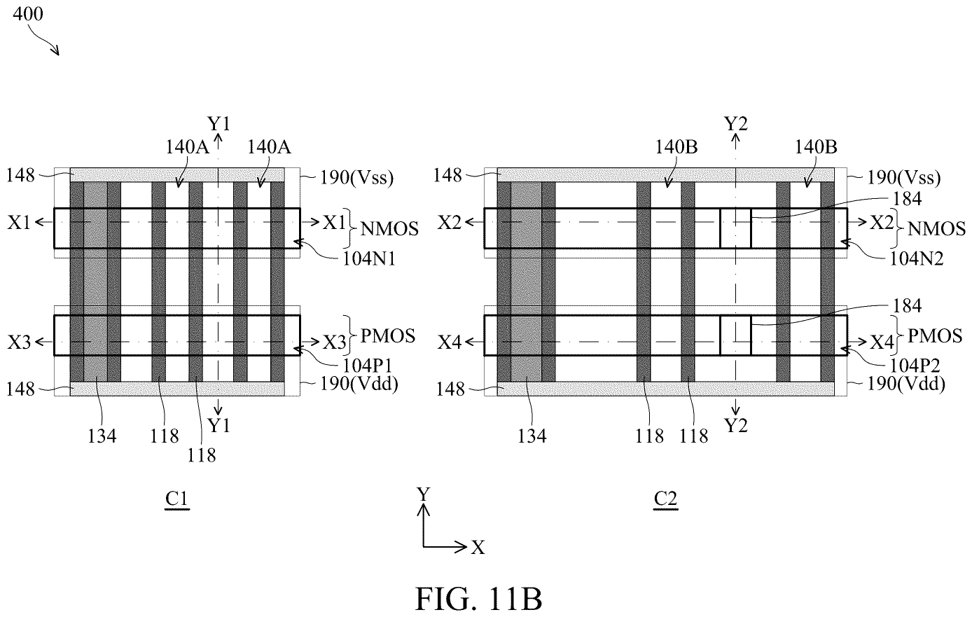

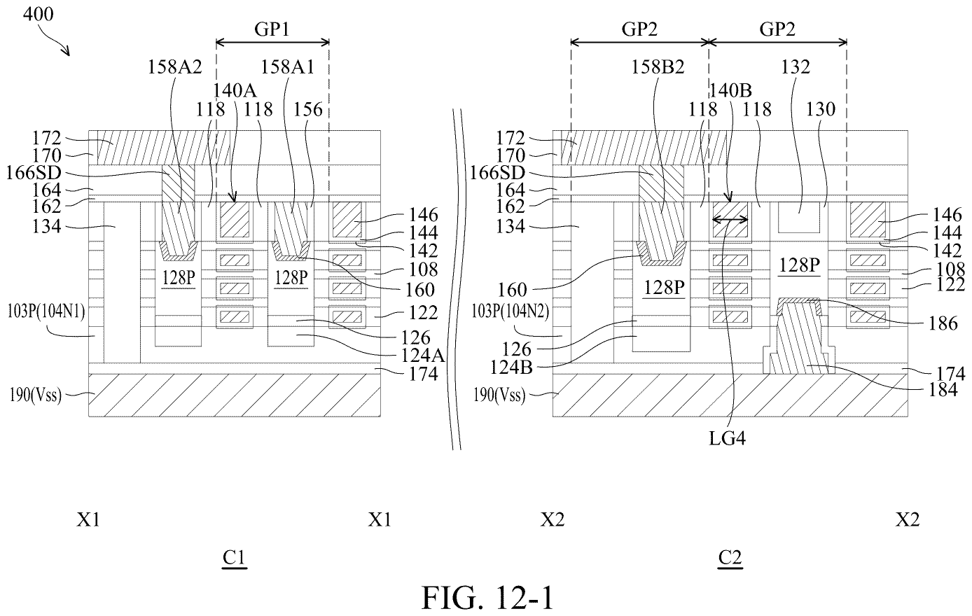

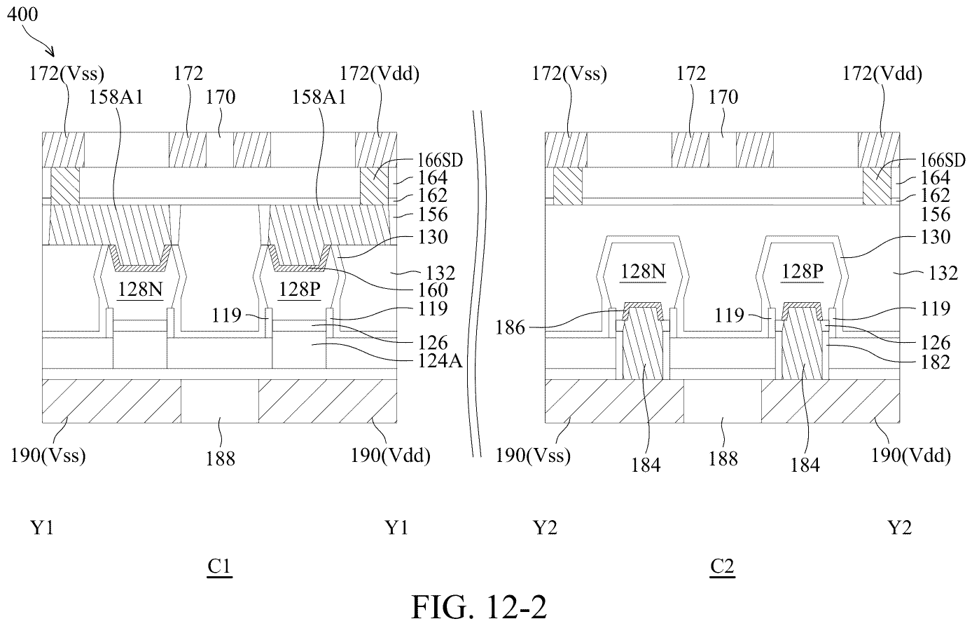

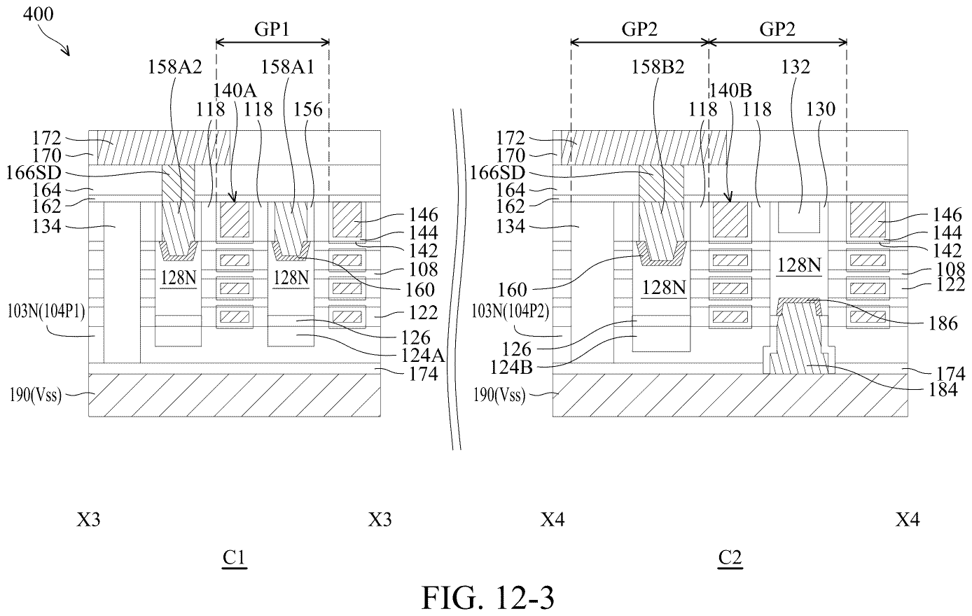

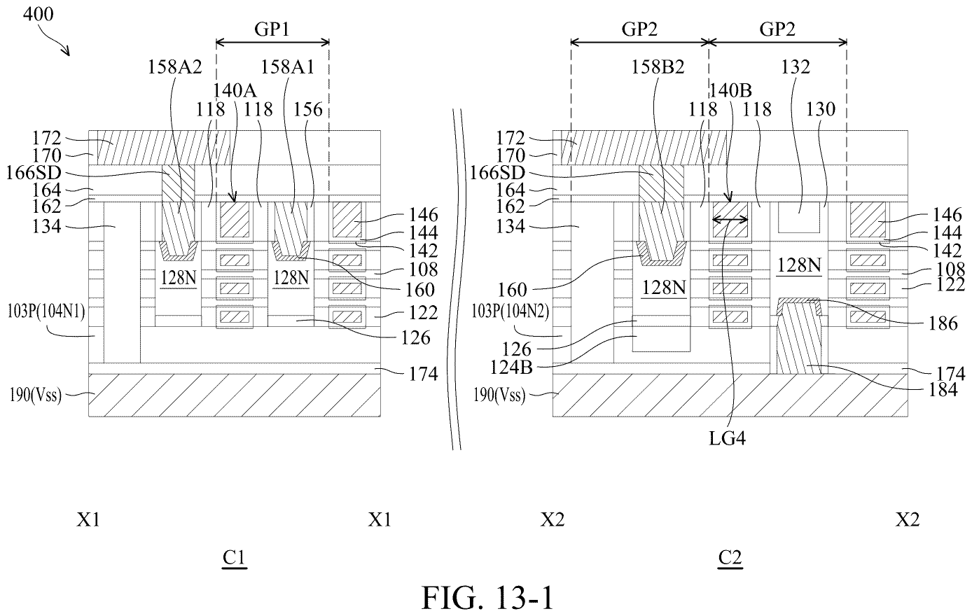

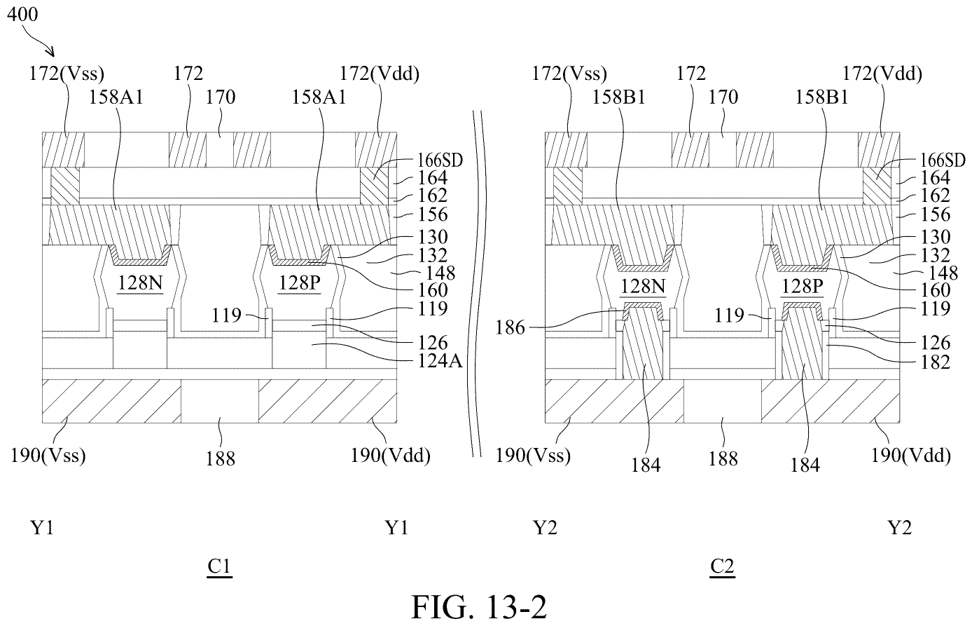

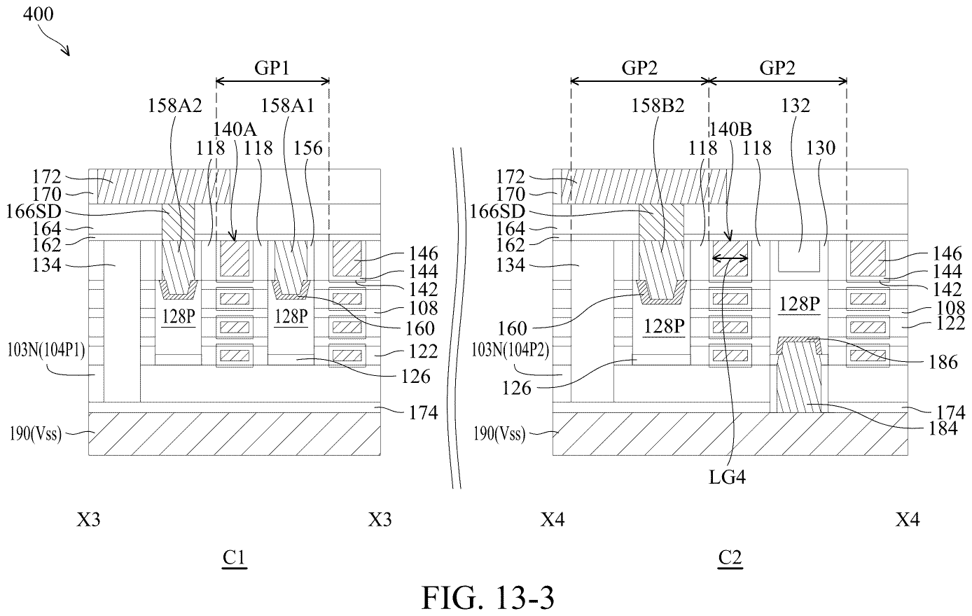

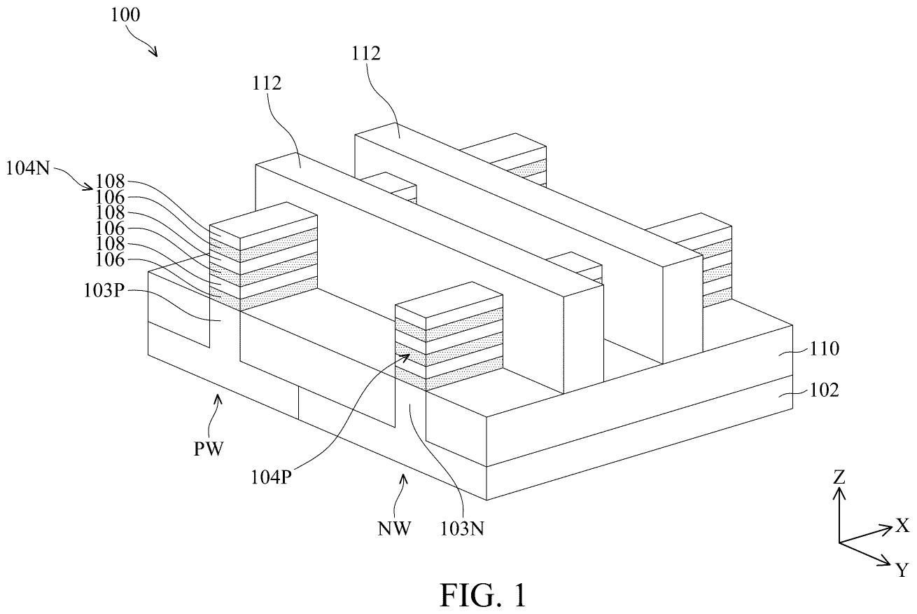

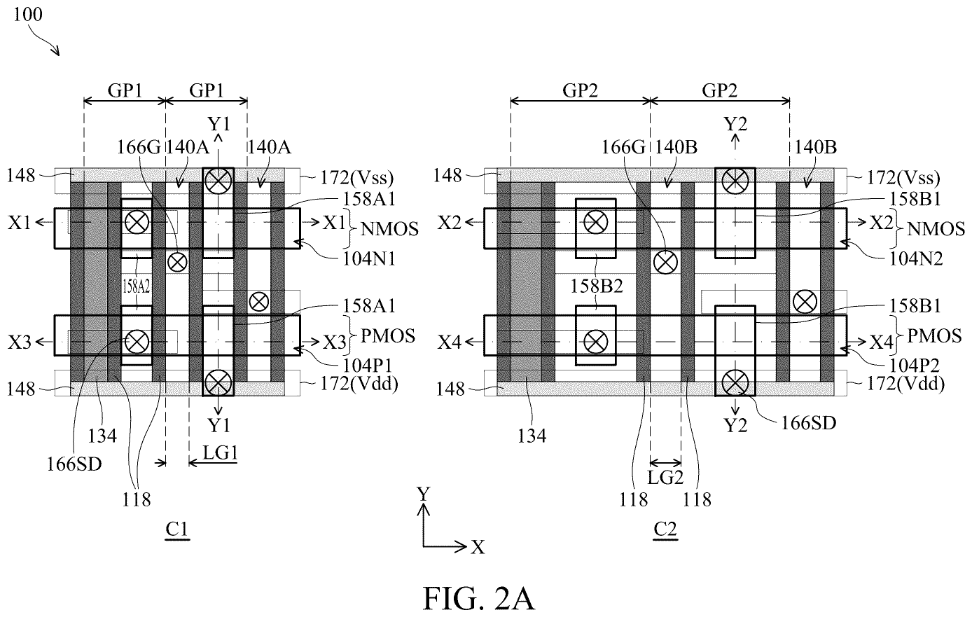

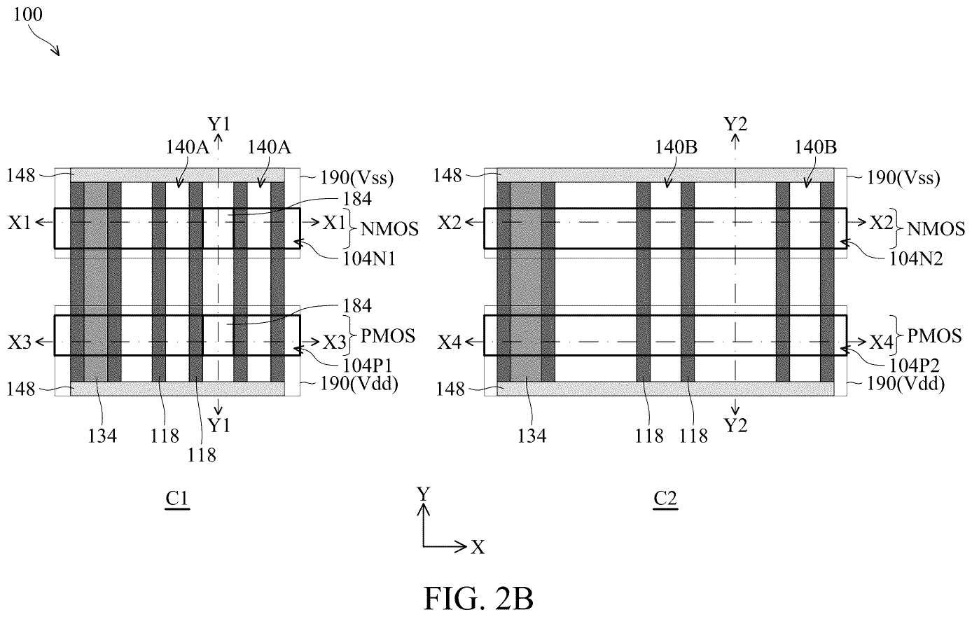

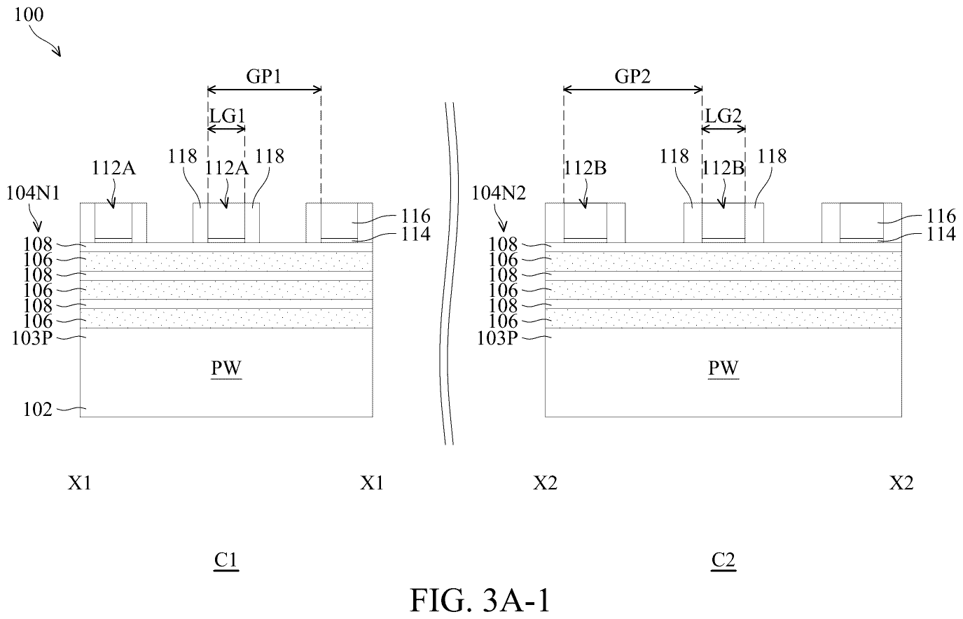

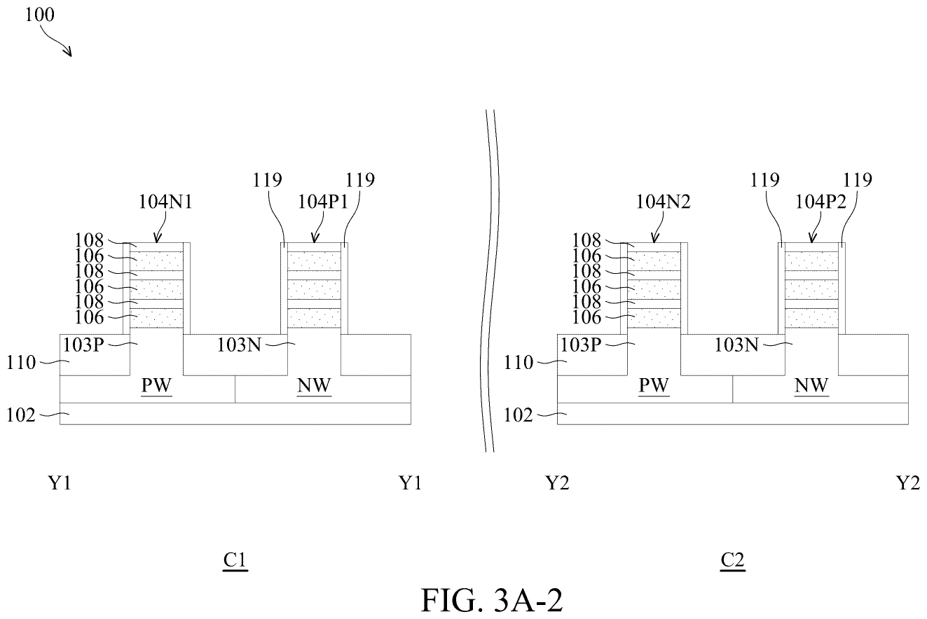

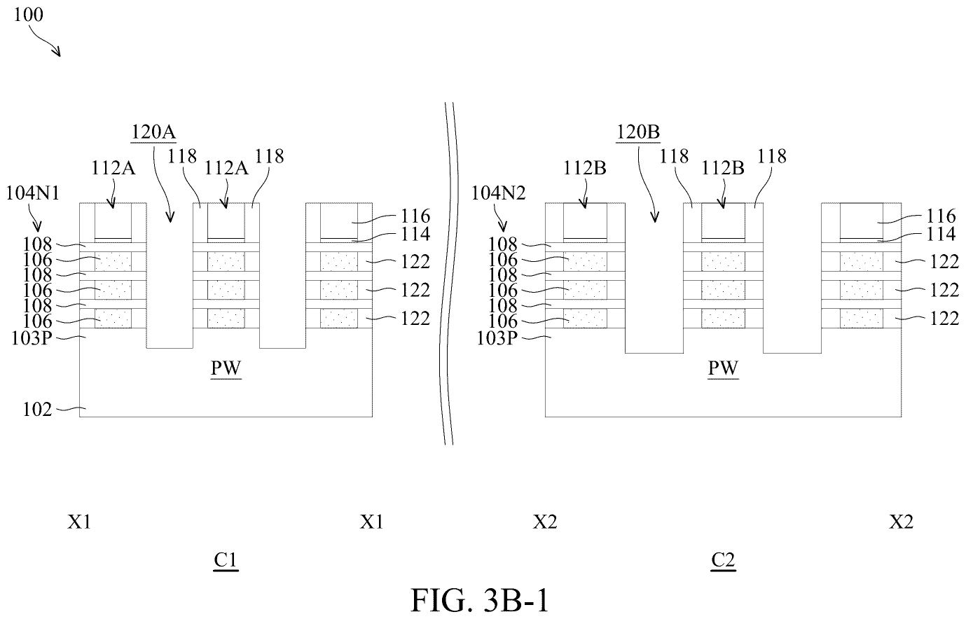

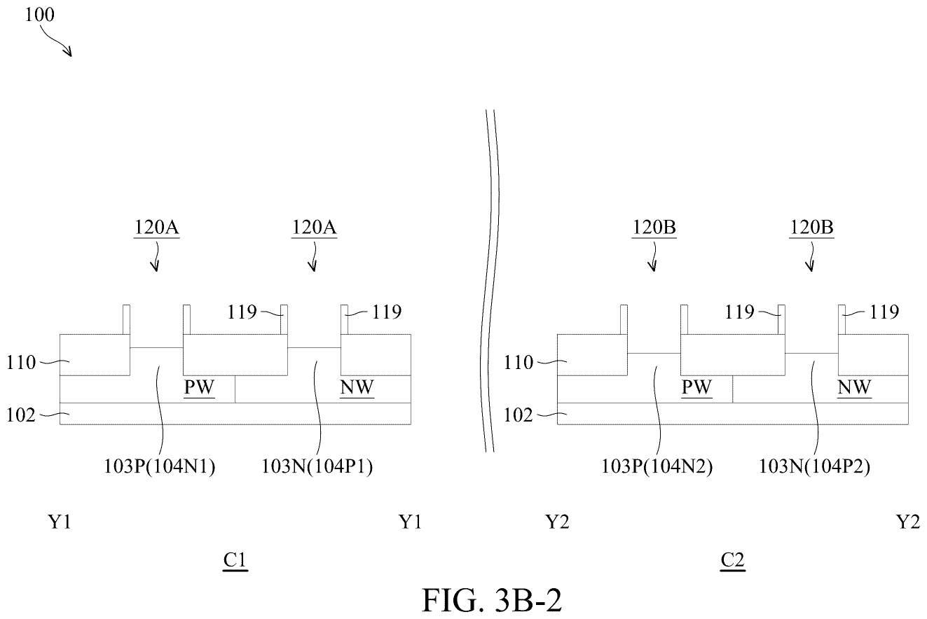

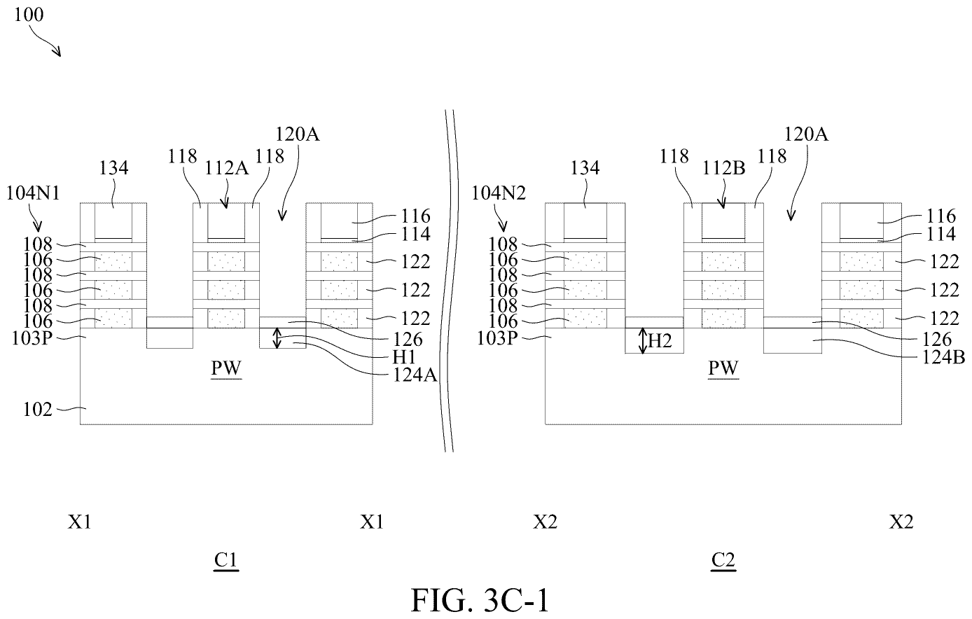

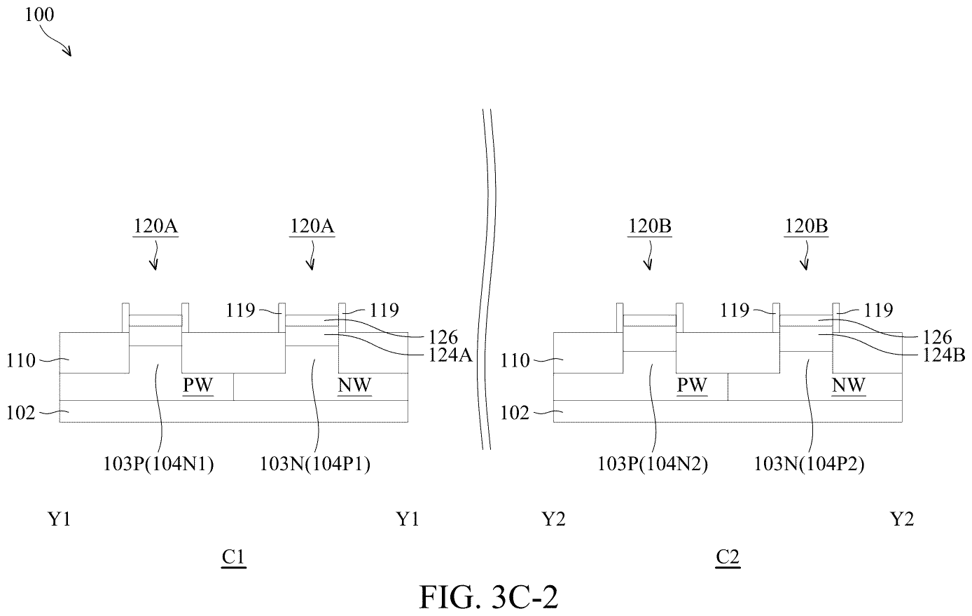

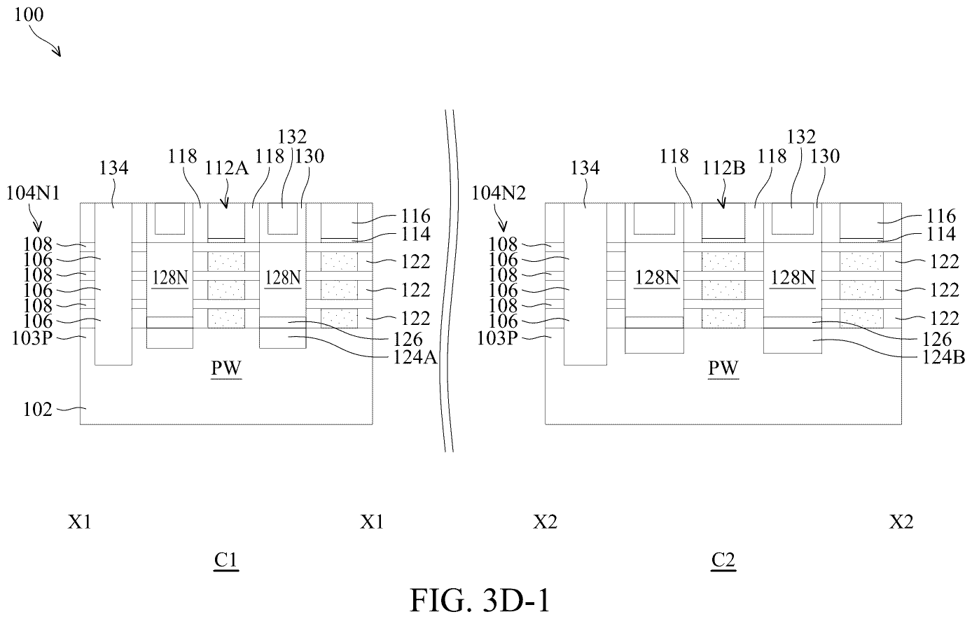

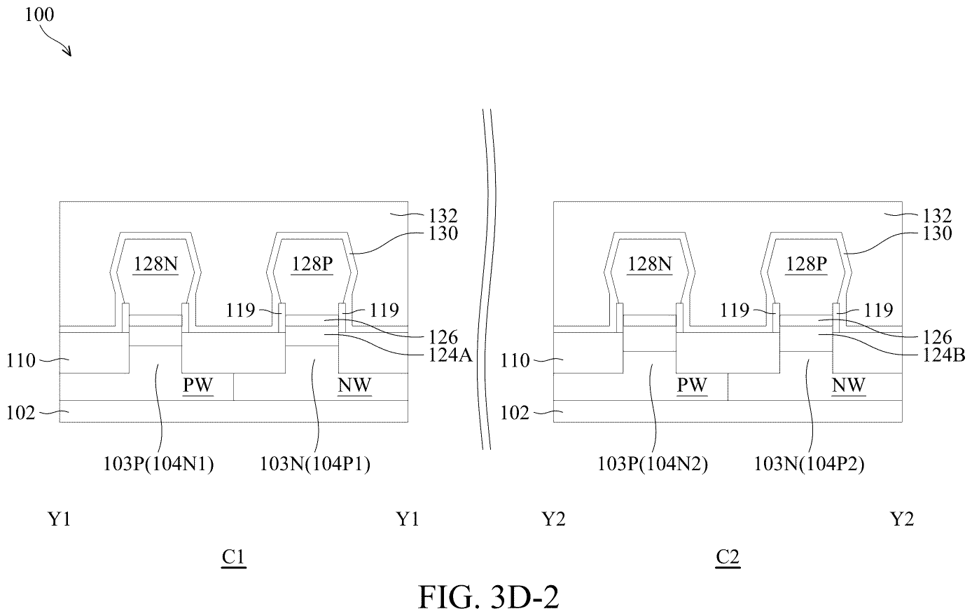

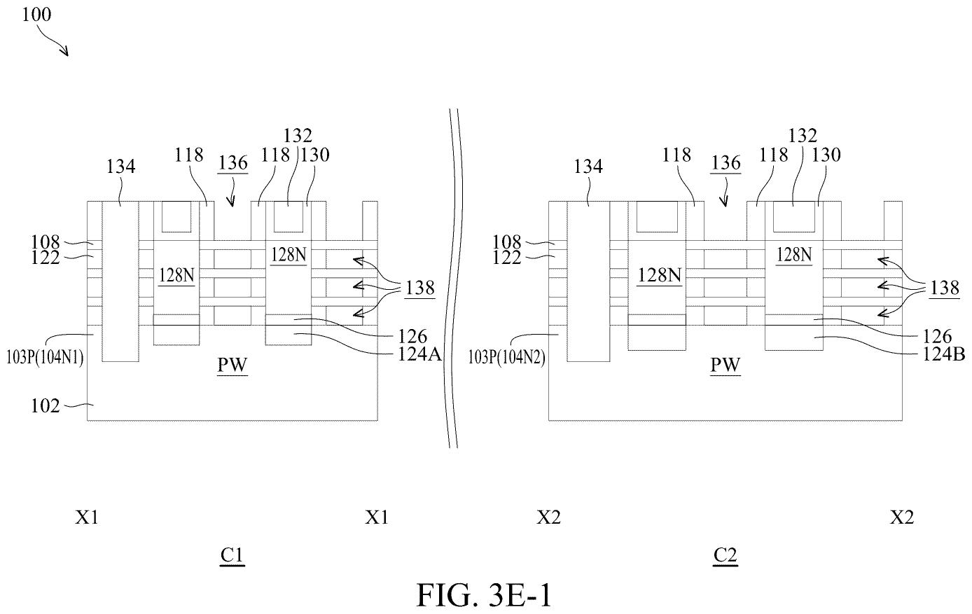

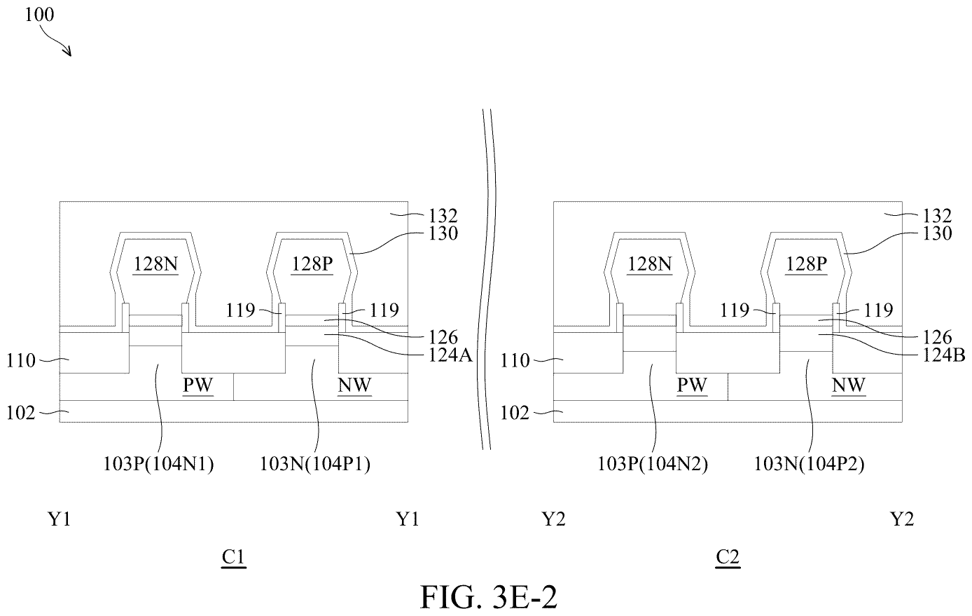

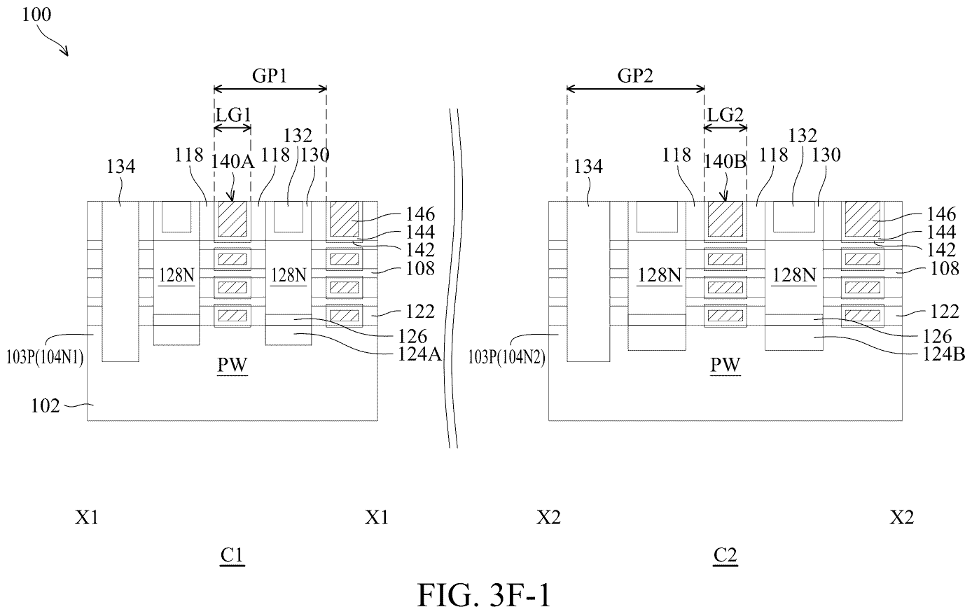

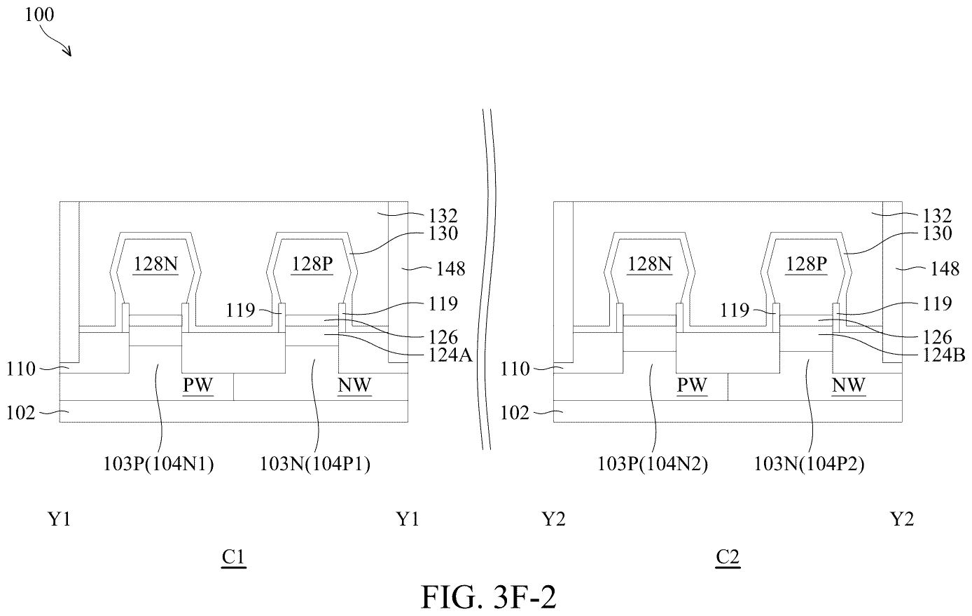

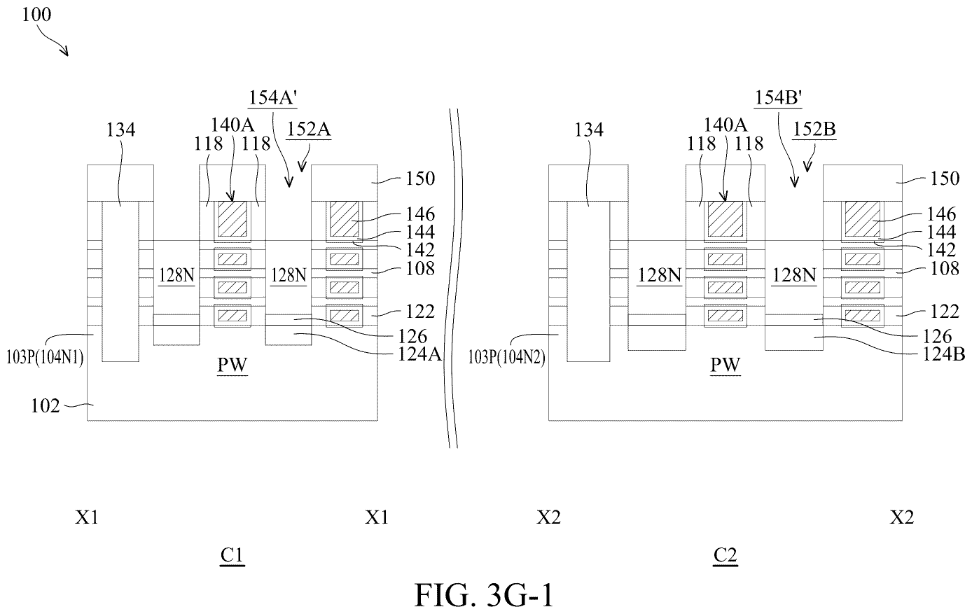

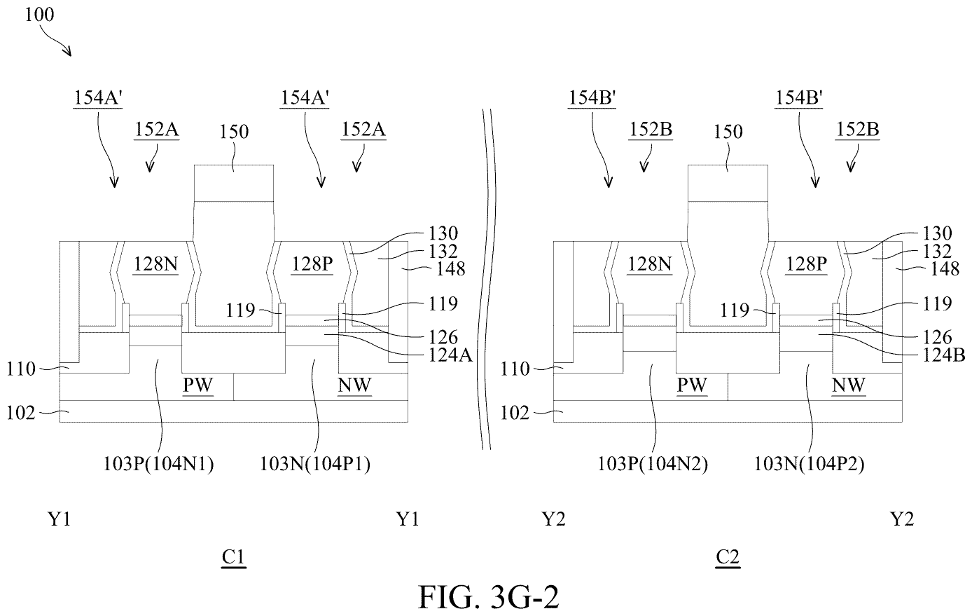

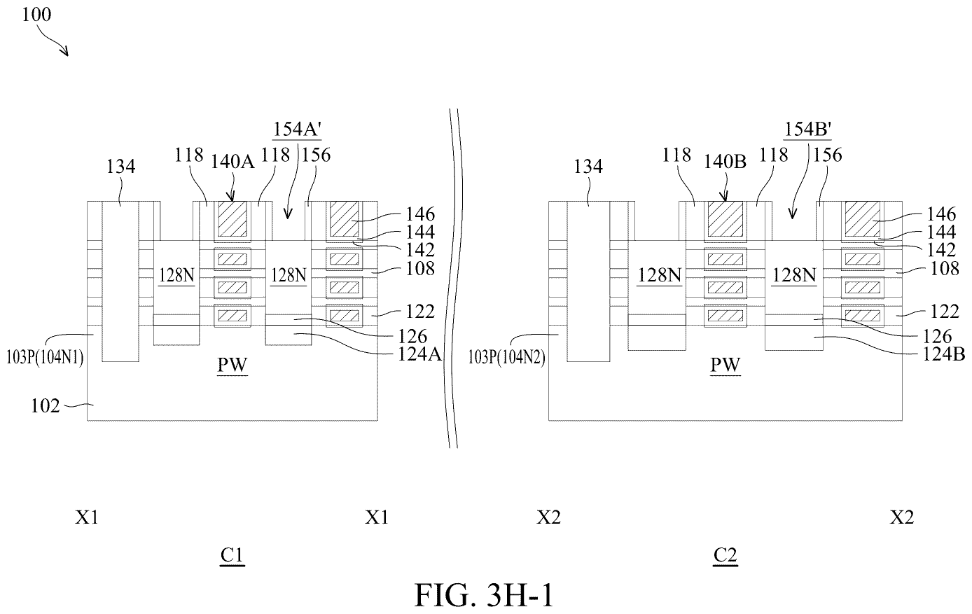

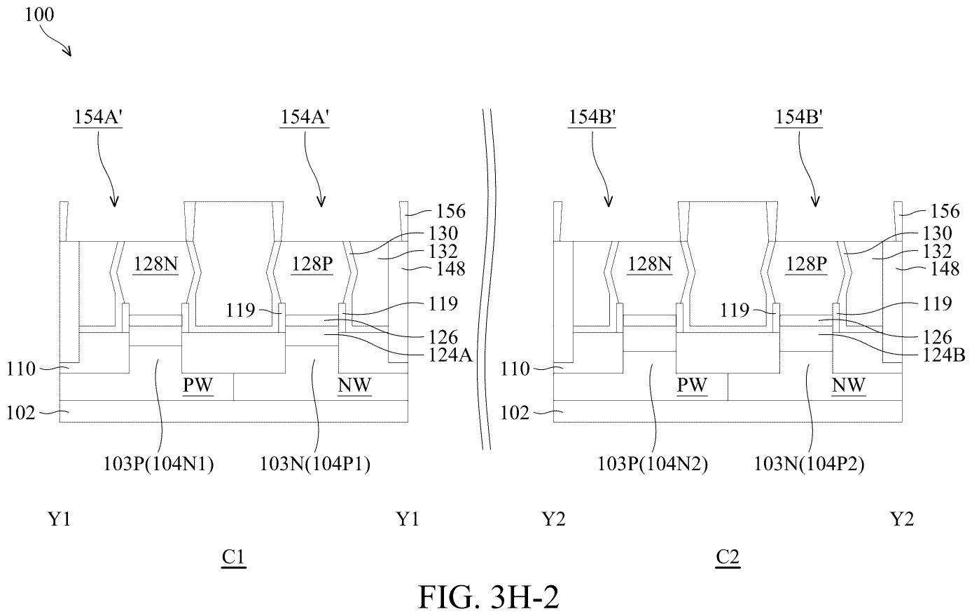

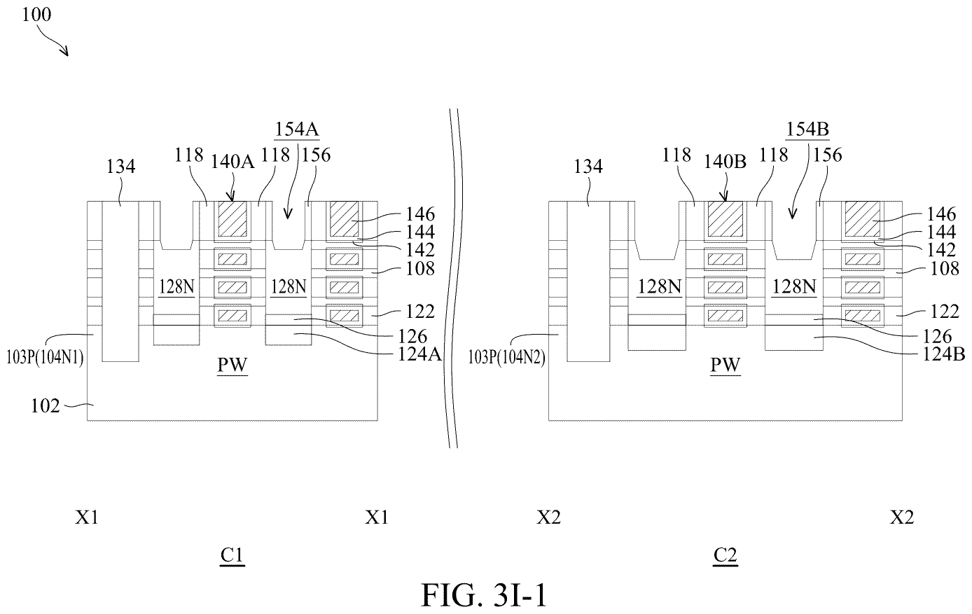

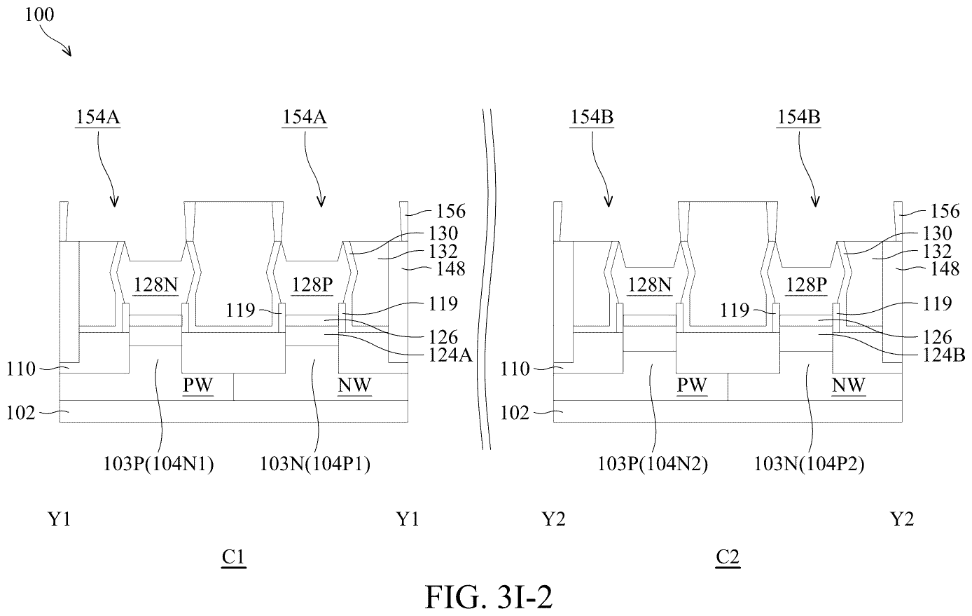

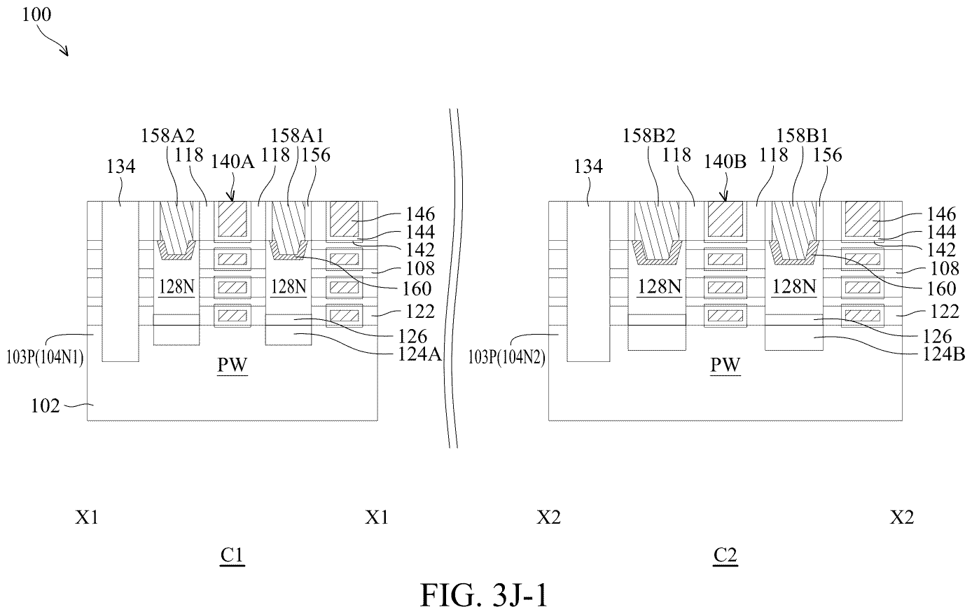

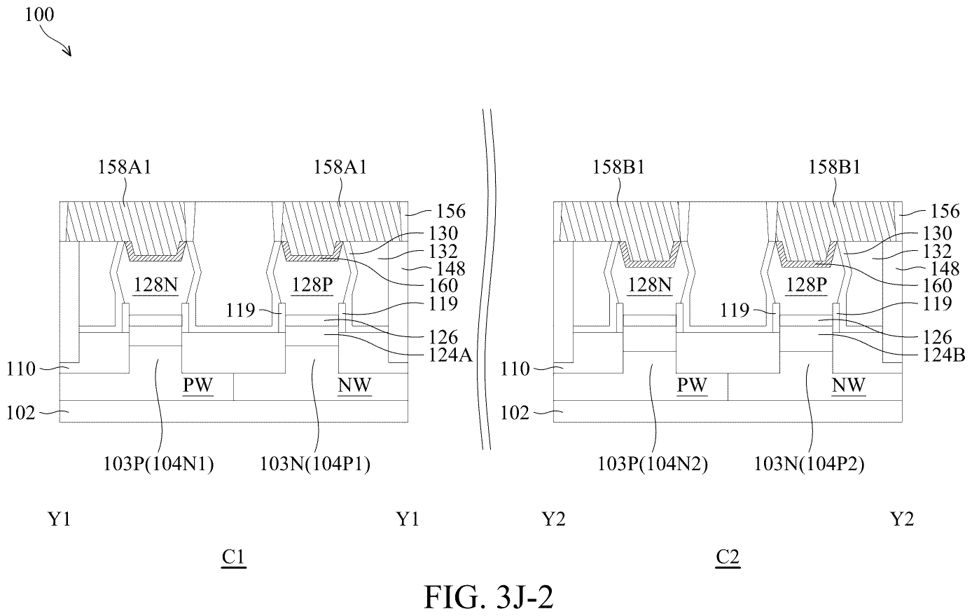

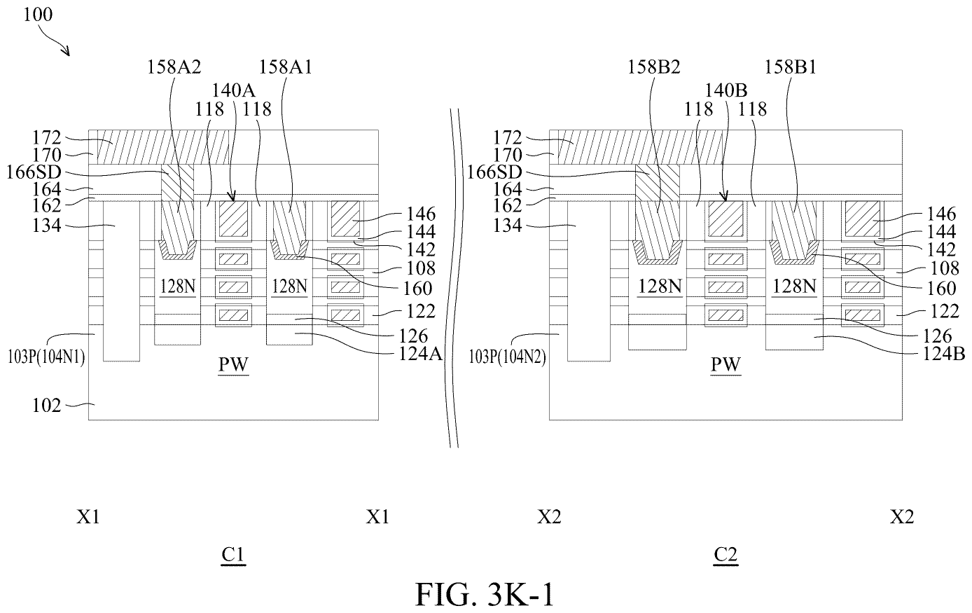

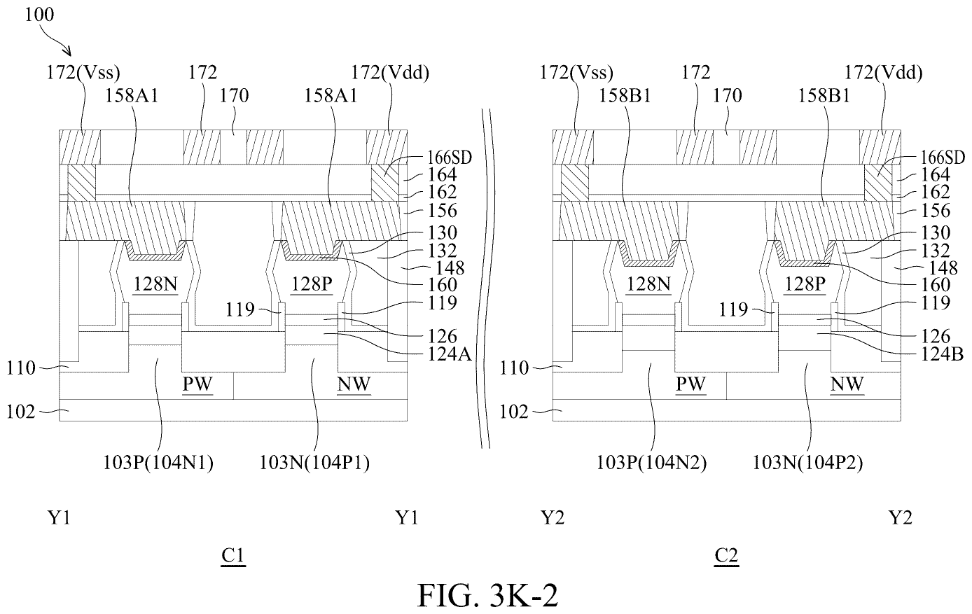

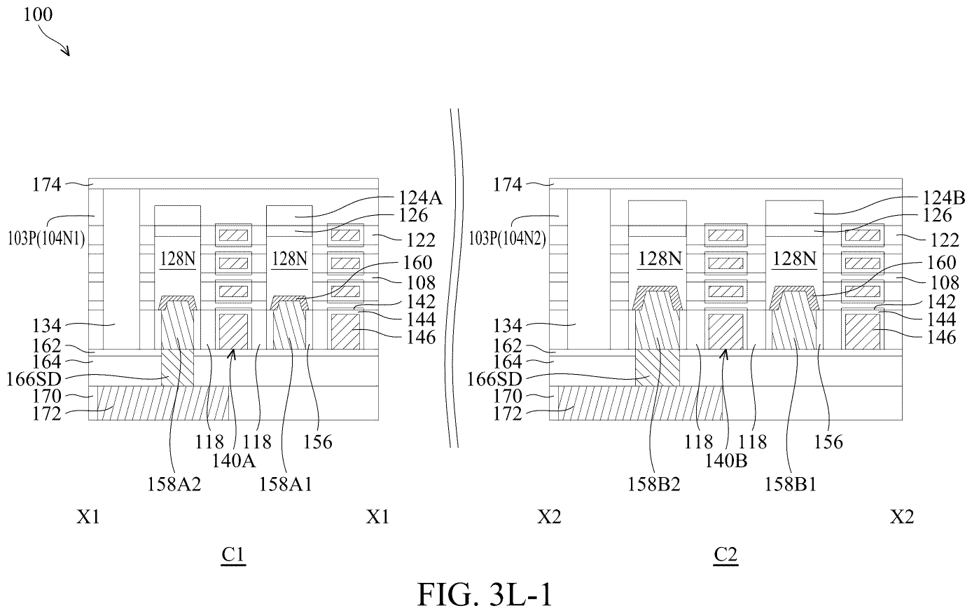

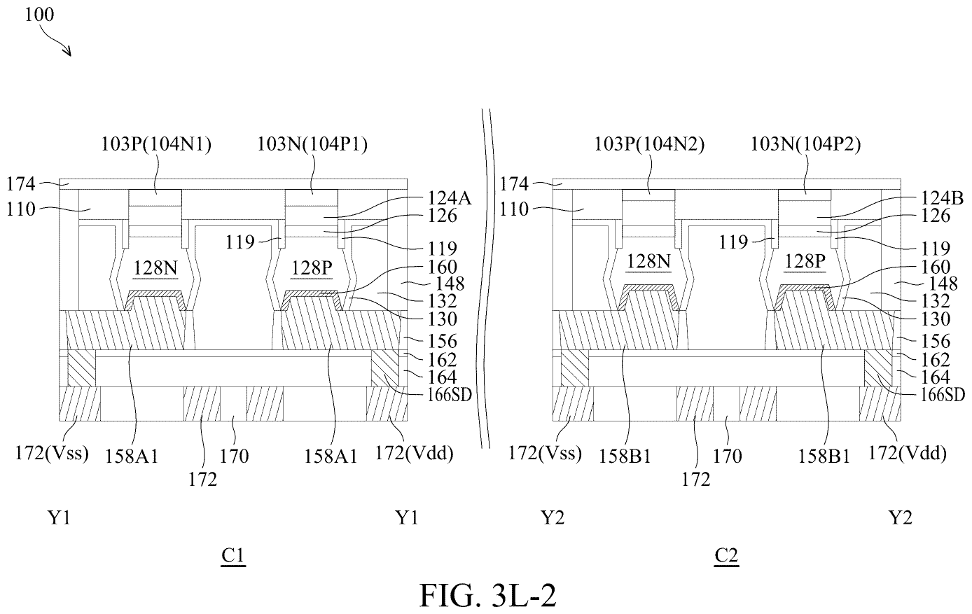

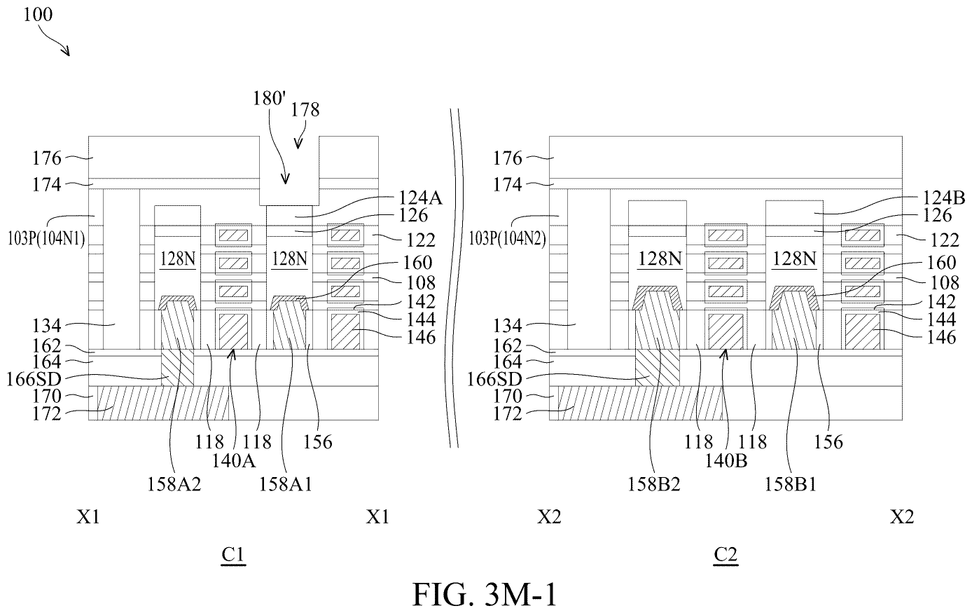

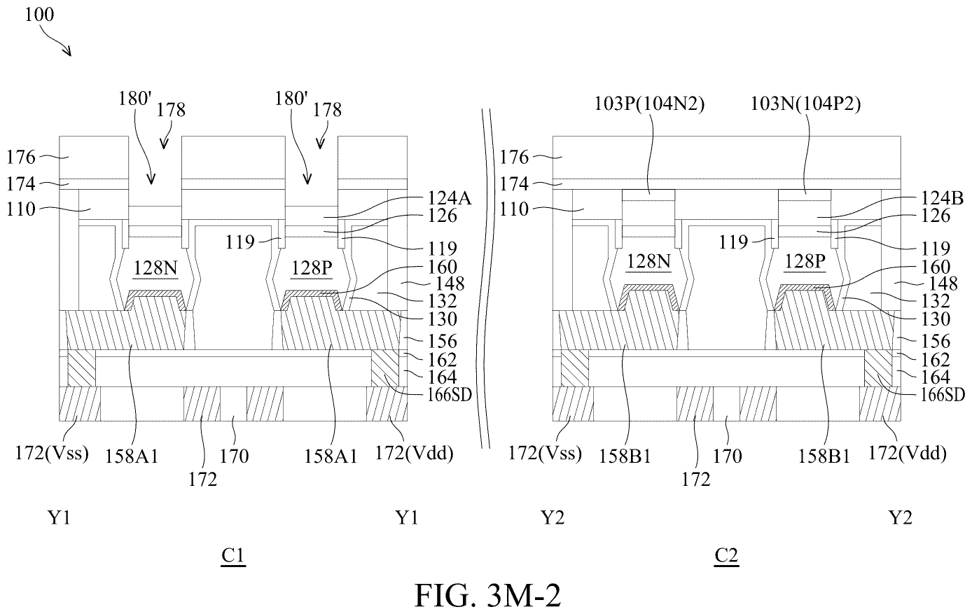

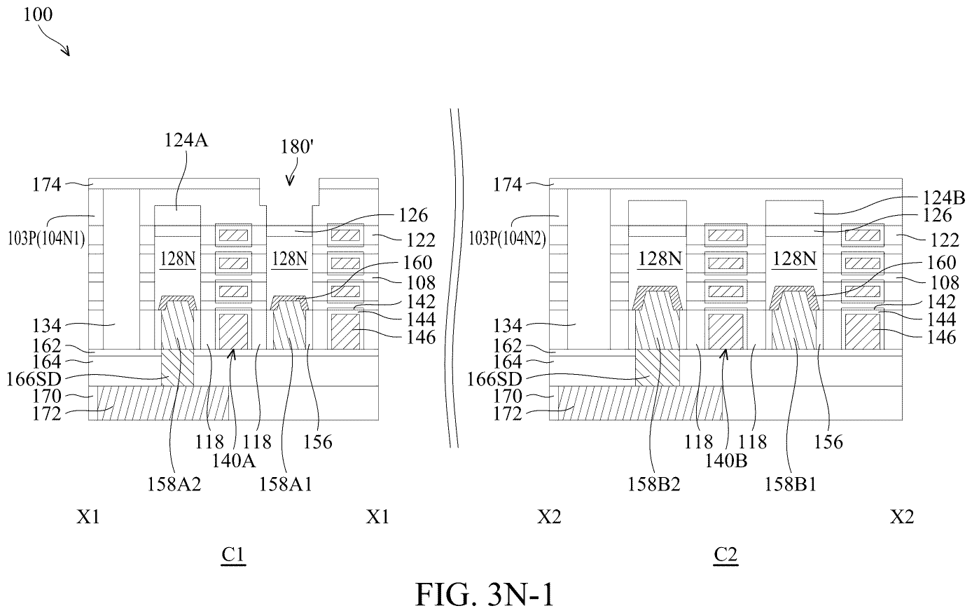

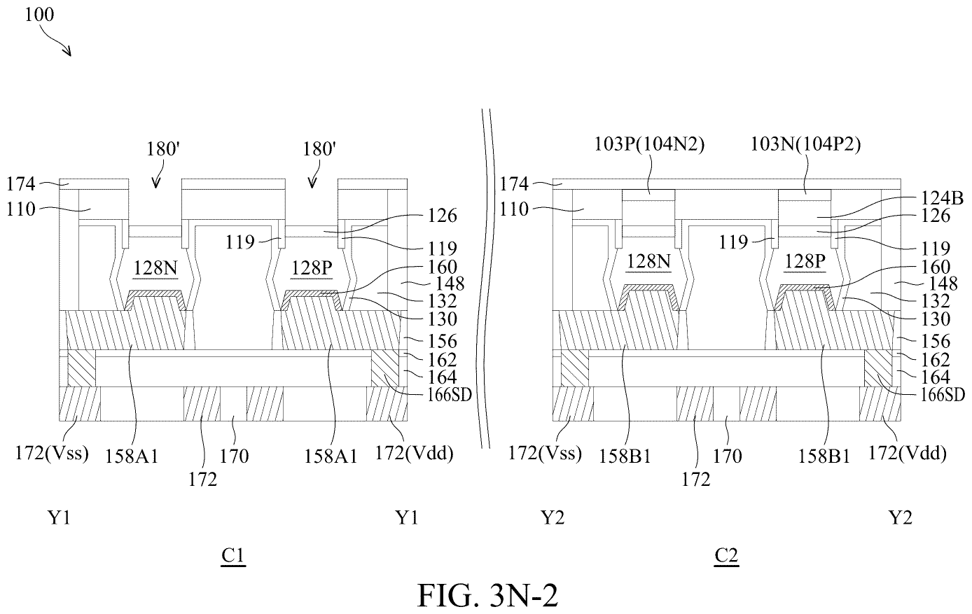

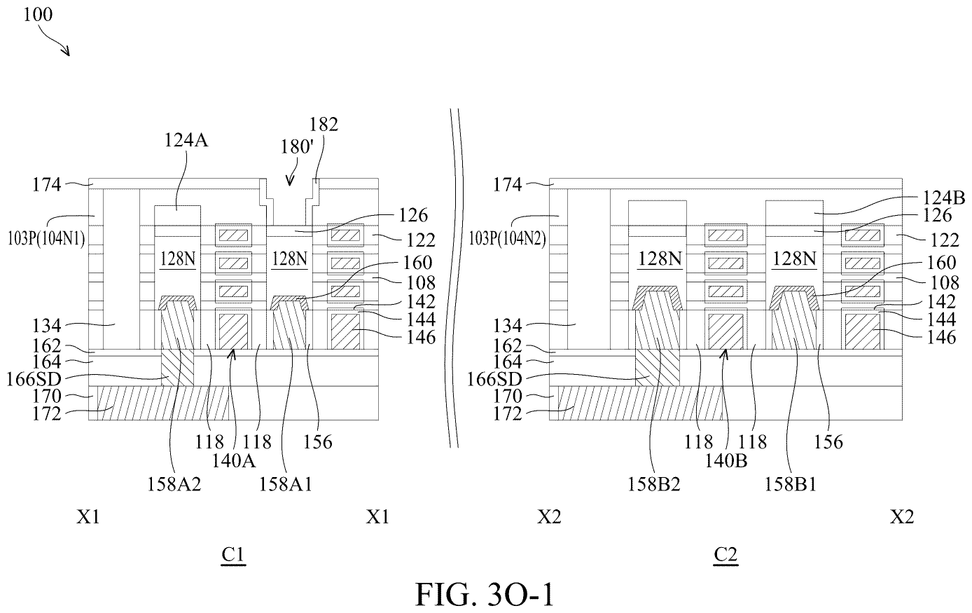

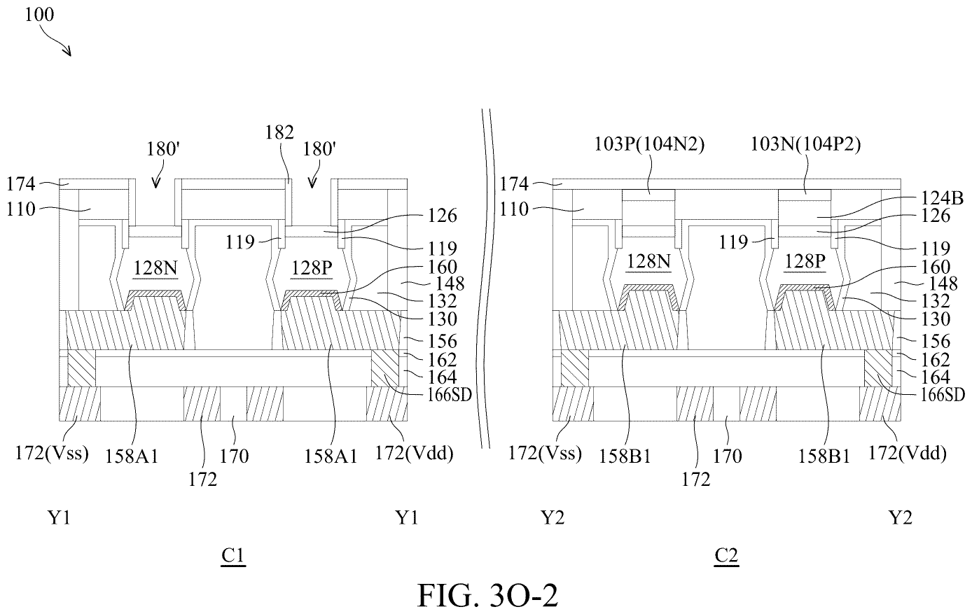

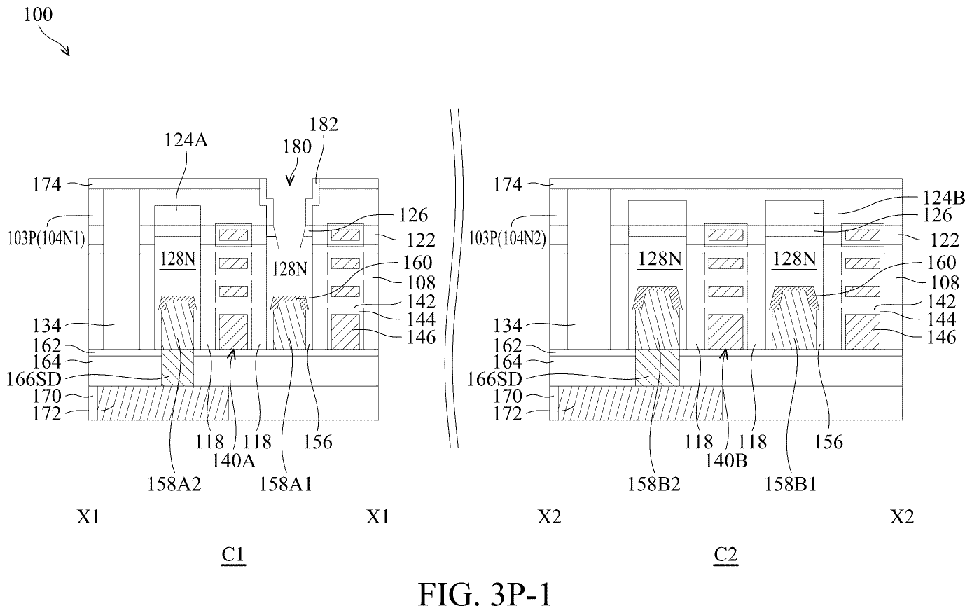

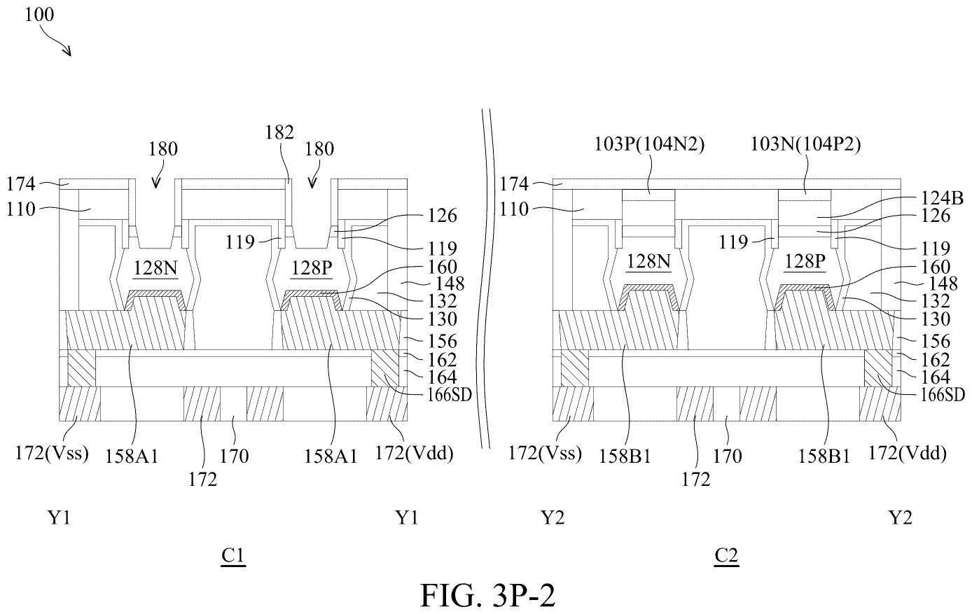

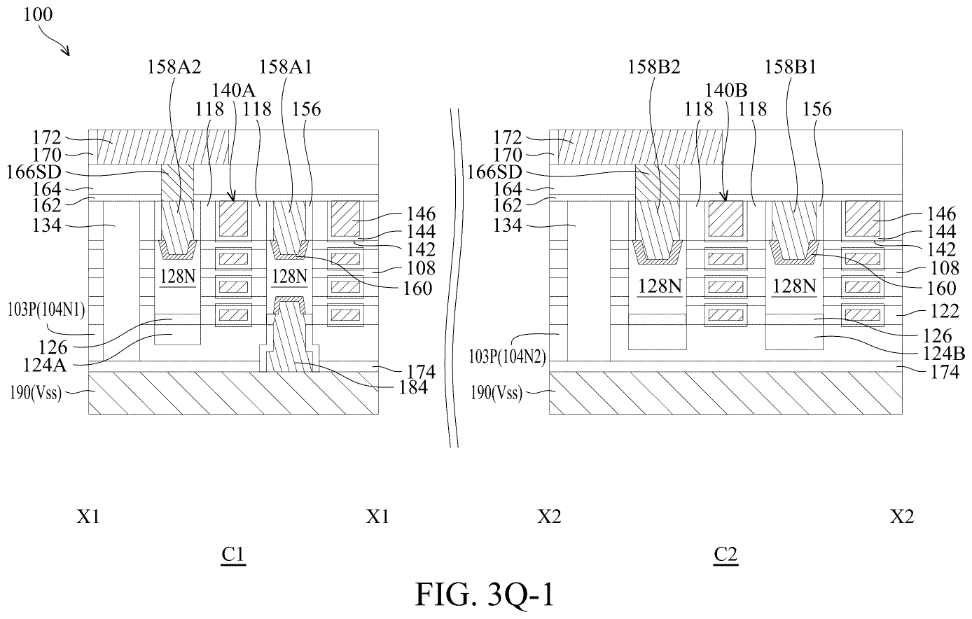

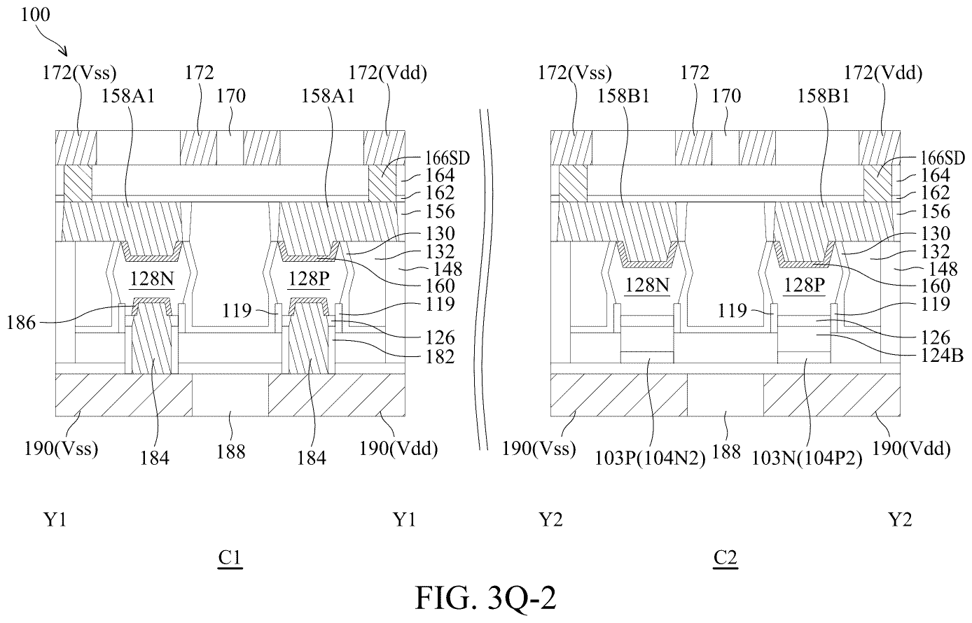

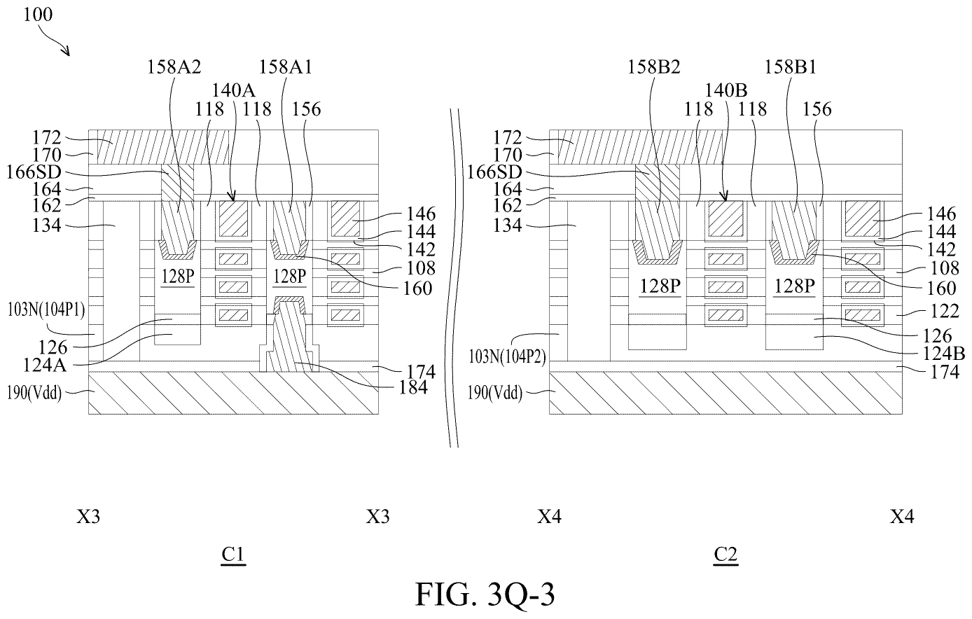

FIGS. 3A-1 through 3Q-3 are cross-sectional views illustrating the formation of the semiconductor structure 100 of FIGS. 2A and 2B at various intermediate stages, in accordance with some embodiments of the disclosure. FIGS. 3A-1, 3B-1, 3C-1, 3D-1, 3E-1, 3F-1, 3G-1, 3H-1, 3I-1, 3J-1, 3K-1, 3L-1, 3M-1, 3N-1, 3O-1, 3P-1 and 3Q-1 correspond to lines X1-X1 and X2-X2 shown in FIGS. 2A and 2B. FIGS. 3A-2, 3B-2, 3C-2, 3D-2, 3E-2, 3F-2, 3G-2, 3H-2, 3I-2, 3J-2, 3K-2, 3L-2, 3M-2, 3N-2, 3O-2, 3P-2 and 3Q-2 correspond to lines Y1-Y1 and Y2-Y2 shown in FIG. 2. FIG. 3Q-3 corresponds to lines X3-X3 and X4-X4 shown in FIGS. 2A and 2B.

FIGS. 3A-1 and 3A-2 illustrate the semiconductor structure 100 after the formation of active regions 104N and 104P (including 104N1, 104N2, 104P1 and 104P2), an isolation structure 110, dummy gate structures 112A and 112B and gate spacer layers 118 and fin spacer layers 119, in accordance with some embodiments.

A substrate 102 is provided, as shown in FIGS. 3A-1 and 3A-2, in accordance with some embodiments. The substrate 102 may be a portion of a semiconductor wafer, a semiconductor chip (or die), and the like. In some embodiments, the substrate 102 is a silicon substrate. The frontside surface of the substrate 102 (the frontside of the semiconductor structure 100) faces upward, in accordance with some embodiments.

In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

N-type dopants (such as phosphorus or arsenic) may be implanted into the substrate 102, thereby forming n-type wells NW, in accordance with some embodiments. P-type dopants (such as boron or BF₂) may be implanted into the substrate 102, thereby forming p-type wells PW, in accordance with some embodiments. In some embodiments, the respective concentrations of the dopants in the wells are in a range from about 10¹⁶/cm⁻³ to about 10¹⁸/cm⁻³. In some embodiments, the ion implantation processes may be performed several times with different dosages and different energy intensities. In some embodiments, the ion implantation process may include an anti-punch through (APT) implant.

Active regions 104N1, 104N2, 104P1 and 104P2 are formed over the substrate 102, as shown in FIGS. 3A-1 and 3A-2, in accordance with some embodiments. The active regions 104N1 and 104N2 are formed in the p-type wells PW, and the active regions 104P1 and 104P2 are formed in the n-type wells NW, in accordance with some embodiments. In some embodiments, the active regions 104N1, 104N2, 104P1 and 104P2 extend in the X direction. The formation of the active regions 104N1, 104N2, 104P1 and 104P2 includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N1, 104N2, 104P1 and 104P2 further includes patterning the epitaxial stack and the underlying wells NW and PW using photolithography and etching processes, thereby forming trenches and the active regions 104N1, 104N2, 104P1 and 104P2 protruding from between trenches, in accordance with some embodiments. The portion of the p-type wells PW protruding from between the trenches serves as lower fin elements 103P of the active regions 104N1 and 104N2, and the portion of the n-type wells NW protruding from between the trenches serves as lower fin elements 103N of the active regions 104P1 and 104P2, in accordance with some embodiments. A remainder of the epitaxial stack (including the first semiconductor layers 106 and the second semiconductor layers 108) serves as the upper fin elements of the active regions 104N1, 104N2, 104P1 and 104P2, in accordance with some embodiments. In some embodiments, the active regions 104N1, 104N2, 104P1 and 104P2 are the fin structures 104N and 104P as shown in FIG. 1.

In some embodiments, each of the first semiconductor layers 106 has a thickness in a range from about 6 nm to about 15 nm. In some embodiments, each of the second semiconductor layers 108 has a thickness in a range from about 4 nm to about 8 nm. The thickness of the second semiconductor layers 108 may be greater than, equal to, or less than the first semiconductor layers 106, depending on the amount of gate materials to be filled in spaces where the first semiconductor layers 106 are removed. Although three first semiconductor layers 106 and three second semiconductor layers 108 are shown in FIGS. 3A-1 and 3A-2, the number is not limited to three, and can be two or four, and is less than 10.

An isolation structure 110 is formed to surround the lower fin elements 103P and 103N of the active regions 104N1, 104N2, 104P1 and 104P2, as shown in FIG. 3A-2, in accordance with some embodiments. The isolation structure 110 is configured to electrically isolate the active regions 104N and 104P from each other and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104N1, 104N2, 104P1 and 104P2, in accordance with some embodiments. The planarization may be chemical mechanical polishing (CMP), etching back process, or a combination thereof. The insulating material is then recessed using an etching process (such as dry plasma etching and/or wet chemical etching) until the upper fin elements of the active regions 104N and 104P are exposed, in accordance with some embodiments. In some embodiments, the top surfaces of the lower fin elements 103N and 103P are higher than the top surface of the isolation structure 110.

Dummy gate structures 112A and 112B are formed across the channel regions of the active regions 104N1, 104N2, 104P1 and 104P2, as shown in FIG. 3A-1, in accordance with some embodiments. The dummy gate structures 112A and 112B are configured as sacrificial structures and will be replaced with the final gate stacks and the fin isolation structures, in accordance with some embodiments. In some embodiments, the dummy gate structures 112A and 112B extend in the Y direction. The dummy gate structures 112A and 112B surround the channel regions of the active regions 104N and 104P, in accordance with some embodiments. The dummy gate structures 112A and 112B may be the gate structures 112 shown in FIG. 1.

Each of the dummy gate structures 112A and 112B includes a dummy gate dielectric layer 114 and a dummy gate electrode layer 116 over the dummy gate dielectric layer 114, in accordance with some embodiments. In some embodiments, the dummy gate dielectric layer 114 is conformally formed along the upper fin elements of the active regions 104. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof.

In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112A and 112B using photolithography and etching processes.

In some embodiments, the gate pitch GP1 of the dummy gate structures 112A in the first cell region C1 is less than the gate pitch GP2 of the dummy gate structures 112B in the second cell region C2. In some embodiments, the ratio (GP2/GP1) of the gate pitch GP2 to the gate pitch GP1 is greater than about 1.1, for example, in a range from about 1.2 to about 3.

In some embodiment, the dimension LG1 of the dummy gate structures 112A in the X direction is less than the dimension LG2 of the dummy gate structures 112B in the X direction. In some embodiments, the ratio (LG1/LG2) of the dimension LG2 to the dimension LG1 is in a range from about 1.2 to 5.

In some embodiment, the spacing between the dummy gate structures 112A is less than the spacing between the dummy gate structures 112B. In some embodiments, the spacing between the dummy gate structures 112A to spacing between the dummy gate structures 112B is in a range from about 1.2 to 5.

Gate spacer layers 118 are formed along opposite sidewalls of the dummy gate structures 112, and fin spacer layers 119 are formed along opposite sidewalls of the active regions 104N and 104P, as shown in FIGS. 2A-1 and 2A-2, in accordance with some embodiments. The gate spacer layers 118 extend in the Y direction and across the active regions 104N1, 104N2, 104P1 and 104P2, in accordance with some embodiments. The gate spacer layers 118 are used to offset the subsequently formed source/drain features and separate the source/drain features from the gate structure, in accordance with some embodiments. The fin spacer layers 119 extend in the X direction, in accordance with some embodiments.

In some embodiments, the gate spacer layers 118 and the fin spacer layers 119 are formed from one or more continuous dielectric material(s). For example, in some embodiments, the formation of the gate spacer layers 118 and the fin spacer layers 119 includes globally and conformally depositing a dielectric material over the semiconductor structure 100 using ALD, CVD (such as LPCVD, PECVD or HDP-CVD or a combination thereof, followed by an anisotropic etching process, in accordance with some embodiments.

In some embodiments, the dielectric material may be silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the gate spacer layers 118 may include air gaps and/or a porous version of the above-mentioned dielectric materials. After the anisotropic etching process, the vertical portions of the dielectric material left remaining on the opposite sides of the dummy gate structures 112 form the gate spacer layers 118, while the vertical portions of the dielectric material left remaining on the opposite sides of the active regions 104N and 104P form the fin spacer layers 119, in accordance with some embodiments.

FIGS. 3B-1 and 3B-2 illustrate the semiconductor structure 100 after the formation of source/drain recesses 120 (including 120A and 120B), in accordance with some embodiments.

An etching process is performed to recess the source/drain regions of the active regions 104N1, 104N2, 104P1 and 104P2, thereby forming source/drain recesses 120A and 120B, as shown in FIGS. 3B-1 and 3B-2, in accordance with some embodiments. The etching process may be an anisotropic etching process such as dry plasma etching, an isotropic etching process such as dry chemical etching, remote plasma etching or wet chemical etching, or a combination thereof. The gate spacer layers 118 and the dummy gate structures 112A and 112B may serve as etch masks such that the source/drain recesses 120 are formed self-aligned on opposite sides of the dummy gate structures 112A and 112B, in accordance with some embodiments.

In some embodiments, the bottoms of the source/drain recesses 120A and 120B may extend into the lower fin elements 103N and 103P. The fin spacer layers 119 are also recessed in the etching process, in accordance with some embodiments. In some embodiments, the fin spacer layers 119 are removed in the etching process.

Due to the characteristics of the etching process, the larger the horizontal dimension of the opening (or opening pattern), the greater the etching amount. As a result, the source/drain recesses 120B in the second cell region C2 are formed to have a deeper depth, while the source/drain recess 120A in the first cell region C1 are formed to have a shallower depth, in accordance with some embodiments. That is, the bottom of the source/drain recess 120B is located at a lower position than the bottom of the source/drain recess 120A.

FIGS. 3C-1 and 3C-2 illustrate the semiconductor structure 100 after the formation of inner spacer layers 122, semiconductor sacrificial layers 124 (including 124A and 124B), dielectric separation layers 126, in accordance with some embodiments.

An etching process is performed to laterally recess, from the source/drain recesses 120A and 12B, the first semiconductor layers 106 of the active regions 104N1, 104N2, 104P1 and 104P2, thereby forming notches, and then inner spacer layers 122 are formed in the notches, as shown in FIG. 3C-1, in accordance with some embodiments. The inner spacer layers 122 are formed to abut the recessed side surfaces of the first semiconductor layers 106, in accordance with some embodiments. In some embodiments, the inner spacer layers 122 are located between adjacent second semiconductor layers 108 and between the bottommost second semiconductor layer 108 and the lower fin element 103N (or 103P). The inner spacer layers 122 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 122 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), a multilayer thereof, or a combination thereof. In some embodiments, the inner spacer layers 122 are made of low-k dielectric materials. For example, the dielectric constant (k) values of the inner spacer layers 122 may be lower than a k-value of silicon oxide (SiO), such as lower than 4.2, equal to or lower than about 3.9, such as in a range from about 3.5 to about 3.9. In some embodiments, the inner spacer layers 122 may include a porous version of an existing dielectric material or an air gap within the dielectric material to have a lower dielectric constant. In some embodiments, the width (i.e., the dimension in the X direction) of the gate spacer layer 118 is greater than the width (i.e., the dimension in the X direction) of the inner spacer layer 122 by about 0.5-5 nm.

In some embodiments, the inner spacer layers 122 are formed by depositing a dielectric material for the inner spacer layers 122 over the semiconductor structure 100 to overfill the notches, and then etching back the dielectric material to remove the dielectric material outside the notches. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

Semiconductor sacrificial layers 124A and 124B are grown in the source/drain recesses 120 on the lower fin elements 103N and 103P, as shown in FIGS. 3C-1 and 3C-2, in accordance with some embodiments. In some embodiments, the semiconductor sacrificial layers 124A and 124B are made of an epitaxial semiconductor material such as silicon germanium or germanium, formed by MBE, MOCVD, or VPE, another suitable technique, or a combination thereof. The semiconductor sacrificial layers 124A and 124B and the lower fin elements 103N and 103P are made of different materials and have a great difference in etching selectivity.

In some embodiments, the top surfaces of the semiconductor sacrificial layers 124A and 124B are located a position substantially level with the top surface of the lower fin elements 130N and 103P. In some embodiments, the thickness H1 (i.e., the dimension in the Z direction) of the semiconductor sacrificial layers 124A in the first cell region C1 is less than the thickness H2 (i.e., the dimension in the Z direction) of the semiconductor sacrificial layers 124B in the first cell region C2 by about 3-20 nm. In some embodiments, the thickness H1 is in a range from about 10 nm to about 60 nm. In some embodiments, the thickness H2 is in a range from about 10 nm to about 60 nm. In some embodiments, the ratio (H2/H1) of the thickness H2 to the thickness H1 is in a range from about 1.2 to about 5.

Dielectric separation layers 126 are formed on the semiconductor sacrificial layers 124, as shown in FIGS. 3C-1 and 3C-2, in accordance with some embodiments. In some embodiments, the dielectric separation layers 126 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric separation layers 126 are formed by a deposition process followed by and an etching-back process.

In some embodiments, the dielectric separation layers 126 are configured to block the leakage path of the planar transistor formed of the lower fin elements 103N/P and final gate stack. In addition, the dielectric separation layers 126 can separate the non-Vdd/Vss nodes (e.g., drain terminals) of the circuits from the lower fin elements 103N/P, which may reduce overall cell capacitance of the semiconductor device.

In some embodiments, the top surfaces of the dielectric separation layers 126 are lower than the bottom surfaces of the bottommost second semiconductor layers 108. That is, the sidewalls of the bottommost second semiconductor layers 108 are uncovered by the dielectric separation layers 126, in accordance with some embodiments. In some embodiments, the dielectric separation layers 126 in the n-type wells NW may be thicker than the dielectric separation layers 126 in the p-type wells PW by about 0.5-5 nm.

FIGS. 3D-1 and 3D-2 illustrate the semiconductor structure 100 after the formation of source/drain features 128N and 128P (including 128N and 128P), a contact etching stop layer 130, a first interlayer dielectric layer 132 and fin isolation structures 134, in accordance with some embodiments.

Source/drain features 128N and 128P are formed on the exposed sidewalls of the second semiconductor layers 108 using one or more epitaxial growth processes, as shown in FIGS. 3D-1 and 3D-2, in accordance with some embodiments. These epitaxial growth processes may be MBE, MOCVD, or VPE, another suitable technique, or a combination thereof. The source/drain features 128N and 128P are located on the dielectric separation layers 126 in the source/drain recesses 120A and 120B, in accordance with some embodiments. The source/drain features 128N and 128P are located on opposite sides of the dummy gate structures 112A and 112B, in accordance with some embodiments. In some embodiments, the source/drain features 128N have a different electrically conductive type than the source/drain features 128P.

In some embodiments, the source/drain features 128N are doped with the n-type dopant during the epitaxial growth process. For example, the n-type dopant may be phosphorous (P) or arsenic (As). For example, the n-type source/drain features 128N may be the epitaxially grown silicon phosphorous (SiP), silicon carbon (SiC), silicon phosphorous carbon (SiPC), silicon phosphorous arsenic (SiPAs), silicon arsenic (SiAs), silicon (Si), or a combination thereof doped with phosphorous and/or arsenic. In some embodiments, the concentrations of the dopant (e.g., P) in the source/drain features 128N are in a range from about 2×10¹⁹ cm⁻³ to about 3×10²¹ cm⁻³.

In some embodiments, the source/drain features 128P are doped with the p-type dopant during the epitaxial growth process. For example, the p-type dopant may be boron (B) or BF₂. For example, the p-type source/drain features 128P may be the epitaxially grown silicon germanium (SiGe), silicon germanium carbon (SiGeC), germanium (Ge), silicon (P), or a combination thereof doped with boron (B). In some embodiments, the concentrations of the dopant (e.g., B) in the source/drain features 128P are in a range from about 1×10¹⁹ cm⁻³ to about 6×10²⁰ cm⁻³. In some embodiments, the n-type source/drain features 128N and the p-type source/drain features 128P are made of different epitaxial materials. For example, the n-type source/drain features 128N are made of SiP, and the p-type source/drain features 128P are made of SiGe.

In some embodiments, the source/drain features 128N and the source/drain features 128P may be formed separately. For example, a patterned mask layer (such as a photoresist layer and/or a hard mask layer) may be formed to cover the semiconductor structure 100 over the n-type wells NW, and then the source/drain features 128N are grown. Afterward, the patterned mask layer may be removed. Similarly, a patterned mask layer (such as a photoresist layer and/or a hard mask layer) is formed to cover the semiconductor structure 100 over the p-type wells PW, and then the source/drain features 128P are grown. Afterward, the patterned mask layer may be removed. In some embodiments, the source/drain features 128N and 128P are in-situ doped during the epitaxial processes.

In some embodiments, the source/drain features 128N and 128P may grow to have a wider portion protruding from between the fin spacer layers 119. In some embodiments, the wider portion of the source/drain features 128N and 128P have facet surfaces that have specific crystalline orientations. Although the source/drain features 128N and 128P are illustrated as having facet surfaces, the wider portion of the source/drain features 128N and/or source/drain features 128P may have a curved surface in some other embodiments.

In some embodiments, the thicknesses (i.e., the dimensions in the Z direction) of the source/drain features 128N and 128P are different from the widths (i.e., the dimensions in the Y direction) of the source/drain features 128N and 128P. In some embodiments, the widths of the source/drain features 128N and 128P are greater than the widths of the lower fin elements 103P and 103N such that portions of the source/drain features 128N and 128P overhang the fin spacer layers 119 and the isolation structure 110. In some embodiments, in the X direction, the dimension of the source/drain features 128N and 128P in the first cell region C1 is less than the dimension of the source/drain features 128N and 128P in the second cell region C2.

A contact etching stop layer 130 is formed over the semiconductor structure 100 to cover the source/drain features 128N and 128P, as shown in FIGS. 3D-1 and 3D-2, in accordance with some embodiments. In some embodiments, the contact etching stop layer 130 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the contact etching stop layer 130 is globally and conformally deposited using ALD, CVD (such as LPCVD, PECVD, HDP-CVD and HARP), another suitable method, and/or a combination thereof. In some embodiments, the dielectric constant of the contact etching stop layer 130 is greater than the dielectric constant of the inner spacer layers 122 and the dielectric constant of the gate spacer layers 118.

A first interlayer dielectric layer 132 is formed over the contact etching stop layer 130, as shown in FIGS. 3D-1 and 3D-2, in accordance with some embodiments. The first interlayer dielectric layer 132 overfills the space between dummy gate structures 112A and 112B, in accordance with some embodiments. In some embodiments, the first interlayer dielectric layer 132 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), or another suitable dielectric material. In some embodiments, the dielectric material for the first interlayer dielectric layer 132 is deposited using such as CVD (such as HDP-CVD, PECVD, HARP or FCVD), another suitable technique, or a combination thereof. The dielectric materials for the contact etching stop layer 130 and the first interlayer dielectric layer 132 above the top surface of the dummy gate electrode layer 116 are removed using such as CMP, in accordance with some embodiments.

In some embodiments, the dielectric constant of the contact etching stop layer 130 is greater than the dielectric constant of the interlayer dielectric layer 132. In some embodiments, the thickness of the portion of the contact etching stop layer 130 along the gate spacer layer 128 and the source/drain features 128N and 128P is less than the thickness (i.e., dimension in the Z direction) and the width (i.e., dimension in the X and Y directions) of the interlayer dielectric layer 132.

Fin isolation structures 134 are formed through one of the dummy gate structures 112 and the underlying active regions 104N and 104P, as shown in FIG. 3D-1, in accordance with some embodiments. The fin isolation structures 134 into the lower fin elements 103N and 103P, in accordance with some embodiments. In some embodiments, the fin isolation structures 134 may extend into the substrate 102 and have bottom surfaces lower than the bottom surface of the isolation structure 110.

In some embodiments, each of the active regions 104N and 104P is cut through by the fin isolation structures 134 into several segments that are electrically isolated from one another. The fin isolation structures 134 have longitudinal axes parallel to the Y direction, in accordance with some embodiments. In some embodiments, the fin isolation structures 134 are configured to prevent leakage between the cell regions. The fin isolation structures 134 may be also referred to as cut poly gate on oxide definition edge (CPODE) pattern.

The fin isolation structures 134 are made of a dielectric material such as silicon oxide (SiO₂), silicon oxynitride (SiON), silicon nitride (SiN), silicon carbon nitride (SiCN), silicon oxycarbonitride (SiOCN), oxygen-doped silicon carbonitride (Si(O)CN), or a combination thereof. The formation of the fin isolation structures 134 includes patterning the dummy gate structure 112 and the active regions 104N and 104P using photolithography and etching processes to form cutting trenches (where the fin isolation structures 134 are to be formed), depositing a dielectric material for the fin isolation structures 134 to overfill the cutting trenches, in accordance with some embodiments. The etching process may be an anisotropic etching process such as dry plasma etching, an isotropic etching process such as dry chemical etching, remote plasma etching or wet chemical etching, or a combination thereof. In some embodiments, the deposition process is ALD, CVD (such as LPCVD, PECVD, HDP-CVD, or HARP), another suitable technique, or a combination thereof. A planarization process is then performed on dielectric material formed until the dummy gate structures 112 and the first interlayer dielectric layer 132 are exposed, in accordance with some embodiments. The planarization may be CMP, etching back process, or a combination thereof.

FIGS. 3E-1 and 3E-2 illustrate the semiconductor structure 100 after the formation of gate trenches 136 and gaps 138, in accordance with some embodiments.

One or more etching processes are performed to remove the dummy gate structures 112A and 112B to form gate trenches 136 and remove the first semiconductor layers 106 of the active regions 104N1, 104N2, 104P1 and 104P2 to form gaps 138, as shown in FIGS. 2D-1 and 2D-2, in accordance with some embodiments. In some embodiments, the gate trenches 136 expose the channel regions of the active regions 104N1, 104N2, 104P1 and 104P2. In some embodiments, the gate trenches 136 further expose the sidewalls of the gate spacer layers 118 facing the channel region. In some embodiments, the gaps 138 expose the sidewalls of the inner spacer layers 122 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 of the active region 104N and 104P form nanostructures 108, in accordance with some embodiments. As the term is used herein, “nanostructures” refers to the semiconductor layers with cylindrical shape, bar shaped and/or sheet shape.

FIGS. 3F-1 to 3F-3 illustrate the semiconductor structure 100 after the formation of final gate stacks 140 (including 140A and 140B) and gate isolation structures 148.

Final gate stacks 140A and 140B are formed in the gate trenches 136 and gaps 138, and they are thereby wrapped around the nanostructures 108, as shown in FIG. 3F-1, in accordance with some embodiments. In some embodiments, the final gate stacks 140A and 140B extend in the Y direction. The final gate stacks 140A and 140B engage the channel region so that current can flow between the source/drain regions during operation.

In some embodiments, the gate pitch GP1 of the final gate stacks 140A in the first cell region C1 is less than the gate pitch GP2 of the final gate stacks 140B in the second cell region C2. In some embodiment, the dimension LG1 of the final gate stacks 140A in the X direction is less than the dimension LG2 of the final gate stacks 140B in the X direction. In some embodiment, the spacing between the final gate stacks 140A is less than the spacing between the final gate stacks 140B.

In some embodiments, each of the final gate stacks 140A and 140B includes an interfacial layer 142, a gate dielectric layer 144 and a metal gate electrode layer 146, in accordance with some embodiments. The interfacial layer 142 is formed on the exposed surfaces of the nanostructures 108 and the exposed surfaces of the lower fin elements 103N and 103P, in accordance with some embodiments. The interfacial layer 142 wraps around the nanostructures 108, in accordance with some embodiments. In some embodiments, the interfacial layer 142 is made of a chemically formed silicon oxide. In some embodiments, the interfacial layer 142 is nitrogen-doped silicon oxide. In some embodiments, the interfacial layer 142 is formed using one or more cleaning processes such as including ozone (O₃), ammonia hydroxide-hydrogen peroxide-water mixture, and/or hydrochloric acid-hydrogen peroxide-water mixture. Semiconductor material from the nanostructures 108 and the lower fin elements 103N and 103P is oxidized to form the interfacial layer 142, in accordance with some embodiments.

The gate dielectric layer 144 is formed conformally along the interfacial layer 142 to wrap around the nanostructures 108, in accordance with some embodiments. The gate dielectric layer 144 is further formed along the exposed sidewalls of the gate spacer layers 118 and the inner spacer layers 122 facing the channel region, in accordance with some embodiments. The gate dielectric layer 144 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Si₃N₄, oxynitrides (SiON), a combination thereof, or another suitable material. The high-k dielectric layer may be deposited using ALD, PVD, CVD, or another suitable technique. In some embodiments, the dielectric constant of the gate dielectric layer 144 is higher than the dielectric constant of the gate spacer layer 118. In some embodiments, the dielectric constant of the gate dielectric layer 144 is at least twice the dielectric constant of the interlayer dielectric layer 132.

The metal gate electrode layer 146 is formed over the gate dielectric layer 144 and overfills the remainder of the gate trenches 136 and the gaps 138, in accordance with some embodiments. In some embodiments, the metal gate electrode layer 146 is made of more than one conductive material, such as a metal, metal alloy, conductive metal oxide and/or metal nitride, another suitable conductive material, or a combination thereof. For example, the metal gate electrode layer 146 may be made of Ti, Ag, Al, TiAlN, TaC, TaCN, TaSiN, Mn, Zr, TiN, TaN, Ru, Mo, WN, Cu, W, Re, Ir, Co, Ni, Pt, another suitable conductive material, or multilayers thereof. The metal gate electrode layer 146 may be a multi-layer structure with various combinations of a diffusion barrier layer, work function layers with a selected work function to enhance the device performance for n-channel FETs or p-channel FETs, a capping layer to prevent oxidation of work function layers, a glue layer, and a metal fill layer to reduce the total resistance of gate stacks, or another suitable layer.

A planarization process such as CMP may be performed on the semiconductor structure 100 to remove the materials of the gate dielectric layer 144 and the metal gate electrode layer 146 formed above the upper surface of the first interlayer dielectric layer 132, in accordance with some embodiments. The final gate stacks 140A and 140B that are wrapped around the nanostructures 108 combine with the neighboring source/drain features 128N or 128P to form nanostructure transistors. In some embodiments, the transistors formed on the nanostructures 108 in the p-type wells PW are the n-channel nanostructure transistors (NMOS in FIG. 2), and the transistors formed on the nanostructures 108 in the n-type wells NW are the p-channel nanostructure transistors (PMOS in FIG. 2).

Gate isolation structures 148 are formed in and/or through the final gate stacks 140A and 140B, the fin isolation structures 134 and the gate spacer layers 118 and land on the isolation structure 110, as shown in FIG. 3F-2, in accordance with some embodiments. In some embodiments, the gate isolation structures 148 extend into the isolation structure 110. The gate isolation structures 148 may be also referred to as cut metal gate (CMG) pattern. The gate isolation structures 148 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof.

The formation of the gate isolation structures 148 includes the semiconductor structure 100 to form gate-cut openings (where the gate isolation structures 148 are to be formed) using photolithography and etching processes until the isolation structure 110 is exposed. The etch processes may include dry etching such as reactive ion etch (RIE), neutral beam etch (NBE), inductive coupled plasma (ICP) etch, capacitively coupled plasma (CCP) etch, another suitable method, or a combination thereof. The formation of the gate isolation structures 148 further includes depositing a dielectric material for the gate isolation structures 148 to overfill the gate-cut openings, in accordance with some embodiments. Afterward, a planarization process is then performed on the dielectric material for the gate isolation structures 148 until the first interlayer dielectric layer 132 is exposed, in accordance with some embodiments. The planarization may be CMP, etching back process, or a combination thereof.

FIGS. 3G-1 and 3G-2 illustrate the semiconductor structure 100 after the formation of contact openings 154A′ and 154B′, in accordance with some embodiments.

A patterning process is performed on the first interlayer dielectric layer 132 and the contact etching stop layer 130 to form contact openings 154A′ and 154B′ using photolithography and etching processes, as shown in FIGS. 3G-1 and 3G-2, in accordance with some embodiments. The contact openings 154A′ and 154B′ correspond to and expose the top surfaces of the source/drain features 128N and 128P, in accordance with some embodiments.

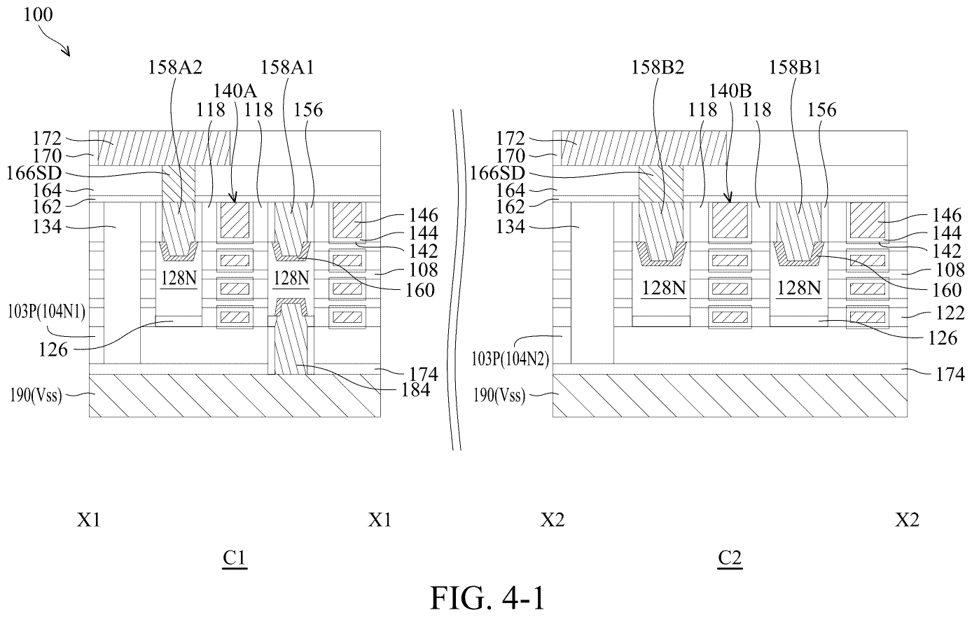

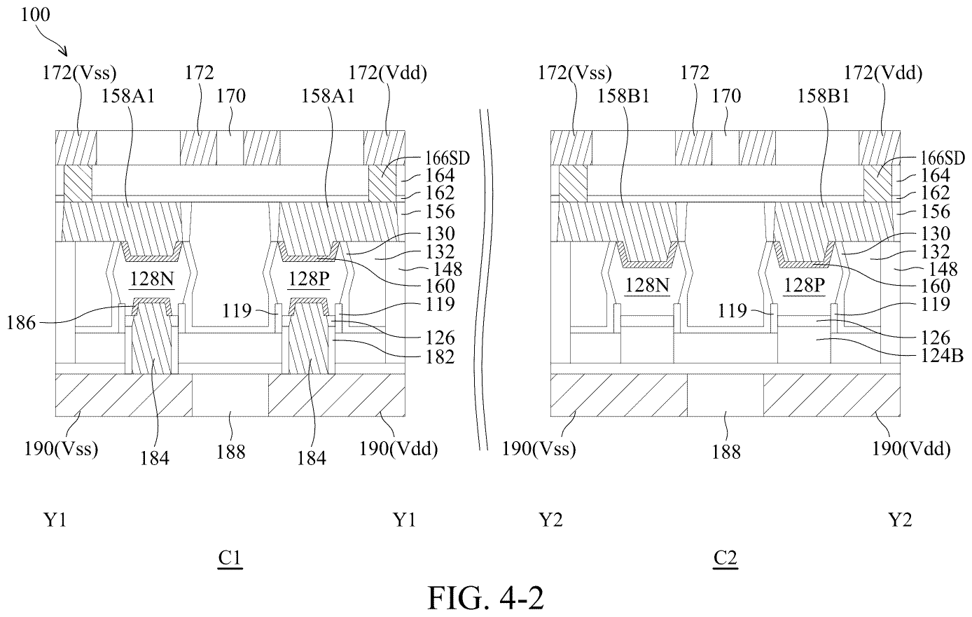

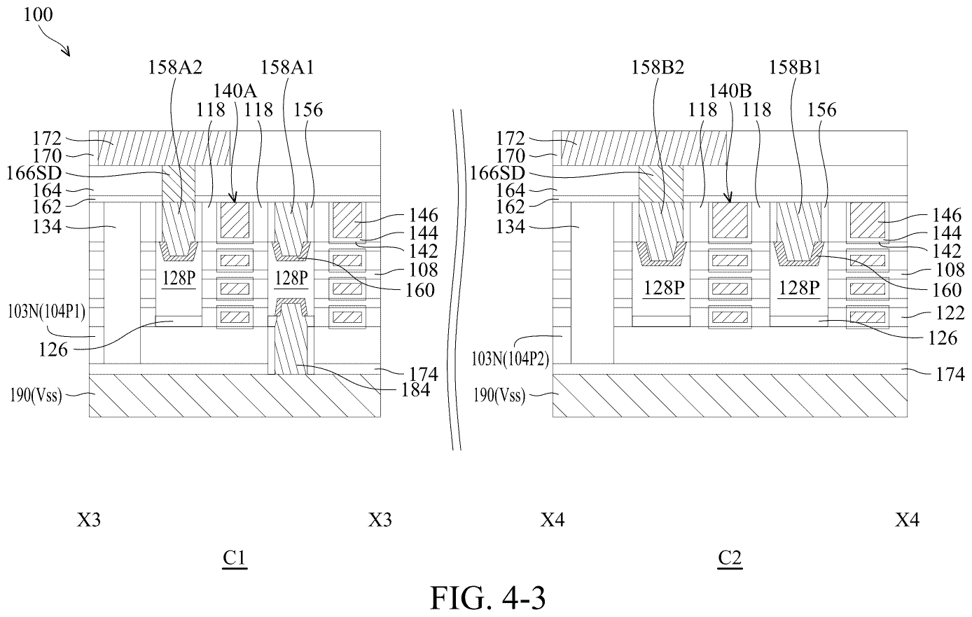

In some embodiments, the portion of the contact etching stop layer 130 along the sidewalls of the gate spacer layers 118 is also removed to expose the gate spacer layers 118. In some other embodiments, the contact etching stop layer 130 may remain on the sidewalls of the gate spacer layers 118 after the patterning process. In some embodiments, the gate-cut structures 148 are also exposed from the contact openings 154A′ and 154B′, as shown in FIG. 3G-4. In some embodiments, the dimension of the contact openings 154A′ in the X direction is less than the dimension of the contact openings 154B′ in the X direction.

The patterning process includes forming a patterned mask layer 150 over the semiconductor structure 100, in accordance with some embodiments. The patterned mask layer 150 has opening patterns 152A and 152B corresponding to the source/drain features 128N and 128P, in accordance with some embodiments. For example, a photoresist is formed such as by using spin-on coating, and then patterning the photoresist to have opening patterns 152A and 152B by exposing the photoresist to light using an appropriate photomask (or reticle). Exposed or unexposed portions of the photoresist may be removed depending on whether a positive or negative resist is used. The opening patterns of the photoresist may then be transferred to the first interlayer dielectric layer 132 and the contact etching stop layer 130, such as by using one or more suitable etch processes. The photoresist can be removed in an ashing or wet strip process, for example.

In alternative embodiments, a hard mask layer (not shown) may be formed on semiconductor structure 100. The hard mask layer may include, or be formed of, a nitrogen-free anti-reflection layer (NFARL), carbon-doped silicon dioxide (e.g., SiO₂:C), titanium nitride (TiN), titanium oxide (TiO), aluminum oxide (AlO), boron nitride (BN), a multilayer thereof, another suitable material, and/or a combination thereof. The hard mask layer may be etched using a patterned photoresist layer, which may be formed by the photolithography described above, thereby having opening patterns 152A and 152B. The patterned hard mask layer may transfer the opening patterns to the first interlayer dielectric layer 132 and the contact etching stop layer 130, which may be accomplished by using one or more suitable etch processes.

The etch processes may include dry etching such as a reactive ion etch (RIE), neutral beam etch (NBE), inductive coupled plasma (ICP) etch, another suitable method, or a combination thereof. The etch processes may be anisotropic. In some embodiments, the etching process is performed until the source/drain features 128N and 128P are exposed. Afterward, the patterned mask layer 150 may be removed using an etching process or ashing process.

FIGS. 3H-1 and 3H-2 illustrate the semiconductor structure 100 after the formation of contact liners 156, in accordance with some embodiments.

Contact liners 156 are formed in the contact openings 154A′ and 154B′, as shown in FIGS. 3H-1 and 3H-2, in accordance with some embodiments. The contact liners 156 extend along the sidewalls of the contact openings 154A′ and 154B′ and partially fill the contact openings 154A′ and 154B′, in accordance with some embodiments.

In some embodiments, the contact liners 156 are made of dielectric material such as nitrogen-containing dielectric material such as silicon nitride (SiN), silicon oxynitride (SiON), silicon carbon nitride (SiCN), silicon oxycarbonitride (SiOCN), and/or oxygen-doped silicon carbonitride (Si(O)CN), or a combination thereof. The nitrogen-containing dielectric material may have better etch resistance to protect the gate spacer layers 118 from being damaged during the source/drain clean process.

In some embodiments, the formation of the contact liners 156 includes depositing the dielectric material using ALD, CVD (such as LPCVD, PECVD or HDP-CVD), another suitable method, and/or a combination thereof, and etching-back the dielectric material to remove the dielectric material from the top surface of the second interlayer dielectric layer 148 and the bottom surface of the contact openings 154A′ and 154B′. The top surfaces of the source/drain features 128N and 128P are exposed from the contact openings 154A′ and 154B′ again, in accordance with some embodiments.

FIGS. 3I-1 and 3I-2 illustrate the semiconductor structure 100 after an etching process, in accordance with some embodiments.

An etching process is performed on the semiconductor structure 100 to vertically enlarge the contact openings 154A′ and 154B′, as shown in FIGS. 3I-1 and 3I-2, in accordance with some embodiments. The source/drain features 128N and 128P are etched thereby extending the contact openings 154A′ and 154B′ to a deeper position, in accordance with some embodiments. The enlarged contact openings 154A′ and 154B′ are denoted as 154A and 154B. The etching processes may include an anisotropic etching process such as dry plasma etching, an isotropic etching process such as dry chemical etching, remote plasma etching or wet chemical etching, or a combination thereof.

Due to the characteristics of the etching process, the larger the horizontal dimension of the contact opening (or opening pattern), the greater the etching amount. As a result, the contact openings 154B are formed to have a deeper depth, while the contact openings 154A are formed to have a shallower depth, in accordance with some embodiments. Each of the contact openings 154A and 154B includes an upper portion penetrating through the first interlayer dielectric layer 132 and the contact etching stop layer 130 and a lower portion penetrating through the upper portions of source/drain features 128N and 128P, in accordance with some embodiments.

FIGS. 3J-1 and 3J-2 illustrate the semiconductor structure 100 after the formation of contact structures 158A1, 158A2, 158B1 and 158B2, in accordance with some embodiments.

Silicide layers 160 are formed on the exposed top surfaces of the source/drain features 128N and 128P, as shown in FIGS. 3J-1 and 3J-2, in accordance with some embodiments. In some embodiments, the silicide layers 160 formed on the n-type source/drain features 128N are made of WSi, NiSi, TiSi and/or CoSi. In some embodiments, the silicide layers 160 formed on the p-type source/drain features 128P are made of WSiGe, NiSiGe, TiSiGe and/or CoSiGe.

In some embodiments, the formation of the silicide layers 160 includes pre-cleaning the exposed surface of the source/drain features 128N and 128P, depositing a metal material followed by one or more annealing processes. The semiconductive material (e.g., Si or SiGe) from the source/drain features 128N and 128P reacts with the metal material to form the silicide layers 160, in accordance with some embodiments. The unreacted metal material is then removed using a post-cleaning process.

Contact structures 158A1, 158A2, 158B1 and 158B2 are formed in the contact openings 154A and 154B on the silicide layers 160, as shown in FIGS. 3J-1 and 3J-2, in accordance with some embodiments. The contact structures 158A1, 158A2, 158B1 and 158B2 land on the source/drain features 128N and 128P and extends into the source/drain features 128N and 128P, in accordance with some embodiments.

The contact structures 158A1, 158A2, 158B1 and 158B2 may have a multilayer structure. For example, one or more conductive materials include a barrier/adhesive layer and a metal bulk layer on the barrier/adhesive layer. In some embodiments, the barrier/adhesive layer may be made of tantalum (Ta), tantalum nitride (TaN), titanium (Ti), titanium nitride (TiN), cobalt tungsten (CoW), another suitable material, or a combination thereof. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

In some embodiments, one or more conductive materials are deposited using CVD, PVD, e-beam evaporation, ALD, electroplating (ECP), electroless deposition (ELD), another suitable method, or a combination thereof to overfill the contact openings. In some embodiments, the metal bulk layer is formed using a selective deposition technique such as cyclic CVD process or ELD process, and it is not necessary to form the barrier/adhesive layer before depositing the metal bulk material.

The one or more conductive materials over the top surface of the first interlayer dielectric layer 132 are planarized using, for example, CMP until the gate electrode layer 144 is exposed. In some embodiments, the top surface of the gate electrode layer 144 is leveled with the top surfaces of the contact structures 158A1, 158A2, 158B1 and 158B2 and the top surface of the first interlayer dielectric layer 132.

In some embodiments, the electrical conductivity of the contact structures 158A1, 158A2, 158B1 and 158B2 is greater than the electrical conductivity of the silicide layer 160, and the electrical conductivity of the silicide layer 160 is greater than the electrical conductivity of the source/drain features 128N and 128P.

In some embodiments, the width (the dimension in the X direction) of the contact openings 158A1 and 158A2 is less than the width (the dimension in the X direction) of the contact openings 158B1 and 158B2. In some embodiment, the contact openings 158B1 and 158B2 have a deeper depth, while the contact openings 158A1 and 158A2 have a shallower depth, in accordance with some embodiments.

Each of the contact structures 158A1, 158A2, 158B1 and 158B2 may have a kinked profile, in accordance with some embodiments. As the term is used herein, “kink” refers to a pattern extending in a direction, with a dent or protrusion on one or both sides of the pattern. The contact structures 158A1, 158A2, 158B1 and 158B2 with the kink structure may include narrower lower portions penetrating through the upper portions of source/drain features 128N and 128P and wider upper portions penetrating through the first interlayer dielectric layer 132 and the contact etching stop layer 130, as shown in 3J-1, in accordance with some embodiments. In some embodiments, the sidewall of the lower portion is not coplanar with the sidewall of the upper portion. The sidewall of the lower portion is indented from the sidewall of the upper portion by a distance, in accordance with some embodiments.

FIGS. 3K-1 and 3K-2 illustrate the semiconductor structure 100 after the formation of an etching stop layer 162, a second interlayer dielectric layer 164, vias 166SD, intermetal dielectric layer 170 and metal lines 172, in accordance with some embodiments.

An etching stop layer 162 and a second interlayer dielectric layer 164 are subsequentially formed on the semiconductor structure 100, as shown in FIGS. 3K-1 and 3K-2, in accordance with some embodiments. In some embodiments, the second etching stop layer 162 is made of dielectric material, such as silicon nitride (SiN), silicon oxide (SiO₂), silicon oxynitride (SiON), silicon carbide (SiC), oxygen-doped silicon carbide (SiC:O), oxygen-doped silicon carbonitride (Si(O)CN), or a combination thereof.

In some embodiments, the second interlayer dielectric layer 164 is made of dielectric material, such as USG, BPSG, FSG, PSG, BSG, or another suitable dielectric material. In some embodiments, the etching stop layer 162 and the second interlayer dielectric layer 164 are deposited using CVD (such as HDP-CVD, PECVD, HARP or FCVD), another suitable technique, or a combination thereof. In some embodiments, the thickness of the second interlayer dielectric layer 164 is less than the thickness of the first interlayer dielectric layer 132.

Vias 166SD are formed in or through the second interlayer dielectric layer 164 and the etching stop layer 162 and land on the contact structures 158A1, 158A2, 158B1 and 158B2, as shown in FIGS. 3K-1 and 3K-2, in accordance with some embodiments. Although not shown, gate vias (e.g., 166G in FIG. 2) are formed in or through the second interlayer dielectric layer 164 and the etching stop layer 162 and land on the final gate stacks 140A and 140B.

In some embodiments, the formation of the vias 166SD includes patterning the second interlayer dielectric layer 164 and the etching stop layer 162 to form via openings (where the vias 166SD and 166G are to be formed) using photolithography and etching processes. The etch processes may include dry etching such as RIE, NBE, ICP etch, another suitable method, or a combination thereof. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the second interlayer dielectric layer 164 are planarized using, for example, CMP.

The vias 166SD may have a multilayer structure. For example, a barrier/adhesive layer (not shown) may optionally be deposited along the sidewalls and the bottom surfaces of the via openings. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the via openings. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), or a combination thereof.

In some embodiments, the dimension of the vias 166SD and 166G (in the X direction or Y direction) in the second cell region C2 may be greater than the dimension (in the X direction or Y direction) of the vias 166SD and 166G in the first cell region C1. For example, the ratio of the dimension of the vias 166SD and 166G in the second cell region C2 to the dimension of the vias 166SD and 166G in the first cell region C1 is greater than about 1.1, for example, in a range from about 1.2 to about 3.

An intermetal dielectric layer 170 is formed over the vias 166SD and the second interlayer dielectric layer 164, and metal lines 172 of a first-level metal layer (M1) are formed through the intermetal dielectric layer 170, as shown in FIGS. 3K-1 and 3K-2, in accordance with some embodiments. The metal lines 172 extend in the X direction, in accordance with some embodiments. The Vss power rails 172 are electrically connected to the n-type source/drain features 128N, and the Vdd power rails 172 are electrically connected to the p-type source/drain features 128P, in accordance with some embodiments.

In some embodiments, the intermetal dielectric layer 170 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the intermetal dielectric layer 170 is made of an extremely low-k (ELK) dielectric material with a dielectric constant (k) less than about 3.0, or even less than about 2.5. In some embodiments, the dielectric constant of the intermetal dielectric layer 170 is lower than the dielectric constant of the second interlayer dielectric layer 164 and the dielectric constant of the first interlayer dielectric layer 132.

In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂). In some embodiments, the intermetal dielectric layer 170 is formed using CVD (such as LPCVD, HARP, and FCVD), ALD, spin-on coating, another suitable method, or a combination thereof. A post-curing process (e.g., UV curing) may be performed on the as-deposited ELK dielectric material for the intermetal dielectric layer 170 to form a porous structure.

In some embodiments, the formation of the metal lines 172 includes patterning the intermetal dielectric layer 170 to form trenches using photolithography and etching processes. Afterward, one or more conductive materials are deposited using CVD, PVD, e-beam evaporation, ALD, ECP, ELD, another suitable method, or a combination thereof to overfill the trenches, in accordance with some embodiments. The one or more conductive materials over the upper surface of the intermetal dielectric layer 170 are planarized using, for example, CMP. The metal lines 172 may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

The semiconductor structure 100 may undergo further frontside BEOL processes to form various interconnection conductive features (not shown) over the semiconductor structure 100, such as frontside second metal layer (F_M2) to frontside tenth metal layer (F_M10) and vias between neighboring two metal layers.

FIGS. 3L-1 and 3L-2 illustrate the semiconductor structure 100 after flipping the semiconductor structure 100 and the formation of a third interlayer dielectric layer 174, in accordance with some embodiments.

The semiconductor structure 100 is flipped upside down, as shown in FIGS. 3L-1 and 3L-2, in accordance with some embodiments. In some embodiments, a carrier substrate (not shown) may be formed over and seal the frontside of the semiconductor structure 100 before flipping the semiconductor structure 100 to protect the components of the semiconductor structure 100 during subsequent backside processes. After flipping the semiconductor structure 100, the backside surface of the substrate 102 (the backside of the semiconductor structure 100) faces upward, in accordance with some embodiments.

The substrate 102 is removed from the backside of the semiconductor structure 100 using a planarization process such as CMP, an etching process, or a combination thereof until the lower fin elements 103N and 103P and the isolation structure 110 are exposed, as shown in FIGS. 3L-1 and 3L-2, in accordance with some embodiments.

A third interlayer dielectric layer 174 is optionally formed over the backside of the semiconductor structure 100, as shown in FIGS. 3L-1 and 3L-2, in accordance with some embodiments. In some embodiments, the third interlayer dielectric layer 174 is made of dielectric material, such as USG, BPSG, FSG, PSG, BSG, or another suitable dielectric material. In some embodiments, the third interlayer dielectric layer 174 is deposited using CVD (such as HDP-CVD, PECVD, HARP or FCVD), another suitable technique, or a combination thereof. In some embodiments, the thickness of the third interlayer dielectric layer 174 is in a range from about 3 nm to about 50 nm.

FIGS. 3M-1 and 3M-2 illustrate cross-sectional views of the semiconductor structure 100 after the formation of the contact openings 180′, in accordance with some embodiments.

A patterning process is performed on the third interlayer dielectric layer 174 and the lower fin elements 103N and 103P to form contact openings 180′ in the first cell region C1 using photolithography and etching processes, as shown in FIGS. 3M-1 and 3M-2, in accordance with some embodiments. The patterning process includes forming a patterned mask layer 176 over the backside of the semiconductor structure 100, in accordance with some embodiments. The material and the formation of the patterned mask layer 176 may be the same as or similar to the patterned mask layer 150 described above.

The patterned mask layer 176 has opening patterns 178 which are located in the first cell region C1 and correspond to the source/drain features 128N and 128P used for the Vdd/Vss nodes, in accordance with some embodiments. In some embodiments, the dimension of the opening patterns 178 (and the contact openings 180′) in the X direction is greater than the dimension of the semiconductor sacrificial layers 124A in the X direction.

The etch processes may include dry etching such as a reactive ion etch (RIE), neutral beam etch (NBE), inductive coupled plasma (ICP) etch, another suitable method, or a combination thereof. The etch processes may be anisotropic. In some embodiments, the etching process is performed until the sacrificial layers 124A are exposed. Because the semiconductor sacrificial layers 124A and the lower fin elements 103N and 103P have a great difference in etching selectivity, the semiconductor sacrificial layers 124A may serve as etch stop layers. The second cell region C2 is covered by the patterned mask layer 176 during the etch processes, in accordance with some embodiments. Afterward, the patterned mask layer 176 may be removed using an etching process or ashing process.

FIGS. 3N-1 and 3N-2 illustrate the semiconductor structure 100 after an etching process, in accordance with some embodiments.

An etching process is performed to extend the contact openings 180′ through the semiconductor sacrificial layers 124A, in accordance with some embodiments. Due to the great difference in etching selectivity, the contact openings 180′ are formed self-aligned to the semiconductor sacrificial layers 124A, and thus the risk leakage between the backside contact structure and the final gate stack may not increase, which may facilitate scaling down the semiconductor devices. In some embodiments, the etch processes may include dry etching such as a reactive ion etch (RIE), neutral beam etch (NBE), inductive coupled plasma (ICP) etch, another suitable method, or a combination thereof. In some embodiments, the etching process for removing the lower fin elements 103N and 103P and the etching process for removing semiconductor sacrificial layers 124A are continuous steps of an etching process.

FIG. 3O-1 and 3O-2 illustrate the semiconductor structure 100 after the formation of contact liners 182, in accordance with some embodiments.

Contact liners 182 are formed in the contact openings 180′, as shown in FIG. 3O-1 and 3O-2 in accordance with some embodiments. The contact liners 182 extend along the sidewalls of the contact openings 180′ and partially fill the contact openings 180′, in accordance with some embodiments. The material and the formation of the contact liners 182 may be the same as or similar to the contact line 156 as described above.

FIGS. 3P-1 and 3P-2 illustrate the semiconductor structure 100 after an etching process, in accordance with some embodiments.

An etching process is performed on the semiconductor structure 100 to vertically enlarge the contact openings 180′, as shown in FIGS. 3P-1 and 3P-2, in accordance with some embodiments. The dielectric separation layers 126 and the source/drain features 128N and 128P in the first cell region C1 are etched thereby extending the contact openings 180′ to a deeper position, in accordance with some embodiments. The enlarged contact openings 180′ are denoted as 180. The etching processes may include an anisotropic etching process such as dry plasma etching, an isotropic etching process such as dry chemical etching, remote plasma etching or wet chemical etching, or a combination thereof.

FIGS. 3Q-1 to 3Q-3 illustrate cross-sectional views of the semiconductor structure 100 after the formation of backside contact structures 184, an intermetal dielectric layer 188, and a backside first metal layer (B_M1), in accordance with some embodiments. FIGS. 3Q-1 to 3Q-3 illustrate that the frontside of the semiconductor structure 100 faces upward.

Silicide layers 186 are formed on the backside surfaces of the source/drain features 128N and 128P exposed the contact openings 180, as shown in FIGS. 3Q-1 to 3Q-3, in accordance with some embodiments. In some embodiments, the material and the formation of the silicide layers 186 may be similar to or the same as the silicide layers 160 described above.

Backside contact structures 184 are then formed on the silicide layers 186 in the contact openings 180, as shown in FIGS. 3Q-1 to 3Q-3, in accordance with some embodiments. Backside contact structures 184 abut the backsides of the source/drain features 128N and 128P, in accordance with some embodiments. In some embodiments, the formation of the contact structures 184 includes depositing one or more conductive materials for the contact structures 184 to overfill the contact openings 180, in accordance with some embodiments. In some embodiments, one or more conductive materials are deposited using CVD, PVD, e-beam evaporation, ALD, ECP, ELD, another suitable method, or a combination thereof to overfill the contact openings 184. The one or more conductive materials are planarized using, for example, CMP until the third interlayer dielectric layer 174 is exposed.

The contact structures 184 may have a multilayer structure. For example, a barrier/adhesive layer (not shown) may optionally be deposited along the sidewalls and the bottom surfaces of the contact openings 180. The barrier layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings 180. In some embodiments, the metal bulk layers are made of one or more conductive materials, such as cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), or a combination thereof.

In some embodiments, the electrical conductivity of the contact structures 184 is greater than the electrical conductivity of the silicide layer 186, and the electrical conductivity of the silicide layer 186 is greater than the electrical conductivity of the source/drain features 128N and 128P.

In some embodiments, the electrical conductivity of the contact structures 184 is greater than the electrical conductivity of the silicide layer 184, and the electrical conductivity of the silicide layer 184 is greater than the electrical conductivity of the source/drain features 128N and 128P.

Each of the contact structures 184 may have at least two kinked profiles, in accordance with some embodiments. Each of the contact openings 184 includes a narrower upper portion penetrating through the bottom portions of source/drain features 128N and 128P, and a wider lower portion penetrating through the third interlayer dielectric layer 174 and the lower fin elements 103N and 103P, as shown in FIGS. 3Q-1 and 3Q-3. The contact opening 184 further includes a middle portion penetrating through the semiconductor sacrificial layers 124A and the dielectric separation layer 126. The middle portion has a width between the narrower upper portion and the wider lower portion, in accordance with some embodiments.

In some embodiments, the sidewall of the lower portion is not coplanar with the sidewall of the middle portion, and the sidewall of the middle portion is not coplanar with the sidewall of the upper portion. The sidewall of the upper portion is indented from the sidewall of the middle portion by a distance, and the sidewall of the upper portion is indented from the sidewall of the middle portion by a distance, in accordance with some embodiments.

The wider lower portions of the contact structures 184 may be helpful in reducing their resistance, thereby further improving the RC delay of the metal conductors (e.g., metal lines) and the IR voltage drop of the power supply. Therefore, the performance (e.g., speed) of the resulting semiconductor devices may improve.

In addition, the narrower lower portions of the contact structures 184 may be kept at a sufficient distance from the final gate stacks 140A, thereby reducing the parasitic capacitance and/or the risk leakage between the backside contact structures 184 and the final gate stack 136. Therefore, the continued scaling of the semiconductor devices may not be limited by the process window of the photobiography process for forming the backside contact structure.

An intermetal dielectric layer 188 is formed over the backside contact structures 184 and the third interlayer dielectric layer 174, as shown in FIGS. 3Q-1 to 3Q-3, in accordance with some embodiments. In some embodiments, the material and the formation of the intermetal dielectric layer 188 may be the same as or similar to the intermetal dielectric layer 170 described above.

Metal lines 190 of a backside first metal layer (B_M1) are formed through the intermetal dielectric layer 188, in accordance with some embodiments. The backside first metal layer (B_M1) includes backside power rails 190, shown in FIGS. 3Q-1 to 3Q-3, in accordance with some embodiments. In some embodiments, the backside power rails 190 are formed in both the cell regions C1 and C2. In some other embodiments, the backside power rails 190 are formed only in the first cell region C1, but not formed in the second cell region C2. In some embodiments, the material and the formation of the backside power rails 190 in the backside first metal layer (B_M1) may be the same as or similar to the metal lines 172 of the first-level metal layer (M1) described above.

The power rails 190 extend in the X direction. In some embodiments, in the Y direction, the backside power rails 190 is wider than the frontside power rails 172. In some embodiments, the power rails 190 are in contact with the backside contact structures 184. In the first cell region C1, the Vss backside power rail 190 is electrically connected to the n-type source/drain features 128N, and the Vdd backside power rail 190 is electrically connected to the p-type source/drain features 128P, in accordance with some embodiments.

The semiconductor structure 100 may undergo further backside BEOL processes to form various interconnection conductive features (not shown) over the backside of the semiconductor structure 100, such as backside second metal layer (B_M2) to backside eighth metal layer (B_M8), vias between neighboring two metal layers, passivation layers, bump pads, etc.

As the scale of the semiconductor devices continues to shrink, the overall resistance of the source/drain region becomes one of the key factors affecting the performance of the semiconductor devices. For example, because the top channel is closer to the frontside contact structure, the top channel may provide a shorter current path (i.e., lower resistance) and receive more current flow than other underlying channels, and thus the current crowding at the interface between the top channel and the epitaxial source/drain features may be becoming more and more of a concern.

In the embodiments of the present disclosure, the backside contact structure 184 is disposed in the first cell region C1 with a relatively small gate pitch (or critical poly-gate pitch) and electrically connects the backside power rails 190 to the Vdd/Vss nodes of the circuit in the first cell region C1, and thus the current can adequately flow through the middle and bottom channels. As a result, the current crowding may be alleviated. Therefore, the performance of the circuit in the first cell region C1 may improve.

In addition, the backside power rail can provide a backend metal routing for the semiconductor devices on the backside of the substrate, thereby further reducing the contact resistance and/or sheet resistance of the BEOL metal layers, and/or reducing the complexity of the metal routing on the frontside of the substrate.

On the other hand, because the second cell region C2 has a relatively large gate pitch (or critical poly-gate pitch), the distance between the top channel and frontside contact structure is greater, and the frontside contact structure may extend to a deeper position. Thus, the current crowding is less of a concern for the second cell region C2. Furthermore, due to the characteristics of the etching process the source/drain recess 120B in the second cell region C2 may be formed with a greater depth than the source/drain recess 120A in the first cell region C1, and thus it may be difficult to simultaneously control the back contact openings in both the first cell region C1 and the second cell region C2 to have respective desired depths. As a result, forming the backside contact structure only in the first cell region C1 may reduce the difficulty of the patterning process for forming the backside contact opening, and may not negatively affect the resistance of the circuit in the second cell region C2. Therefore, the manufacturing yield of the resulting semiconductor structure may improve, and the performance.

The embodiments of FIGS. 3A-1 through 3Q-3 are discussed in the context of the nano-sheet transistors, the embodiments of the present disclosure may be applied to nano-wire transistors, fork-sheet transistors, CFET (complementary FET), and the like.

FIGS. 4-1, 4-2 and 4-3 are a modification of the semiconductor structure 100 of FIGS. 3Q-1, 3Q-2 and 3Q-3, in accordance with some embodiments of the disclosure. The embodiments of FIGS. 4-1, 4-2 and 4-3 are similar to the embodiments of FIGS. 3A-1 through 3Q-3 where like reference numerals indicate like elements formed by like processes, except that the semiconductor sacrificial layers 124A and 124B are omitted.

After the source/drain recesses 120A and 120B are formed, a semiconductor separation layers (not shown) may be optionally formed on the lower fin elements 103N and 103P, and the dielectric separation layers 126 are formed on the semiconductor separation layers. In some embodiments, the semiconductor separation layers are made of non-doped silicon.

The dimension of the contact openings 180′ (FIG. 3M-2) in the X direction may be substantially the same as the dimension of the lower fin elements 103N and 103P in the X direction, and thus each of the backside contact structures 184 may have one kinked profile, in accordance with some embodiments. Each of the contact openings 184 includes a narrower upper portion penetrating through the bottom portions of source/drain features 128N and 128P, and a wider lower portion penetrating through the third interlayer dielectric layer 174 and the lower fin elements 103N and 103P.

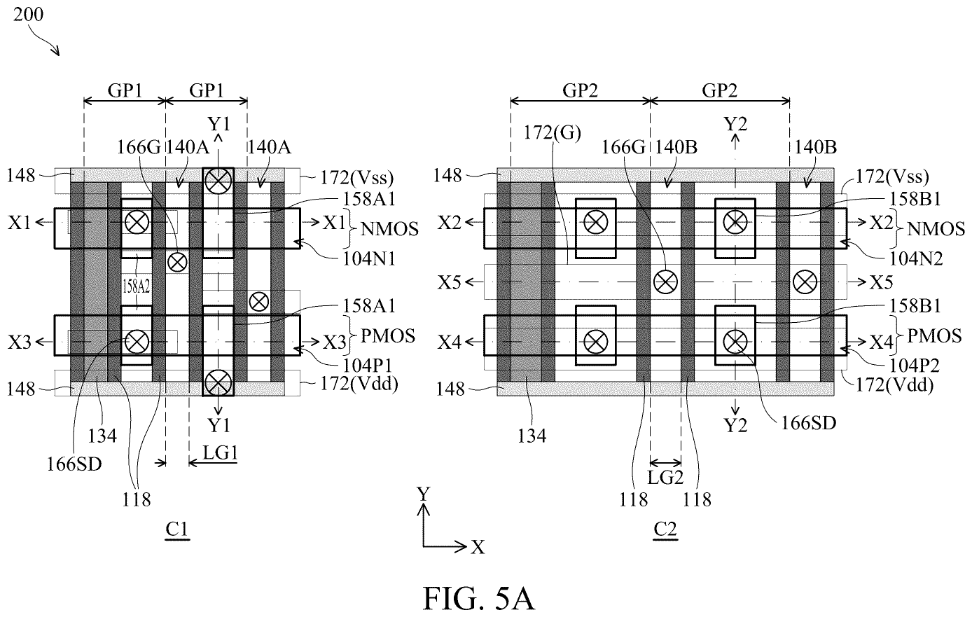

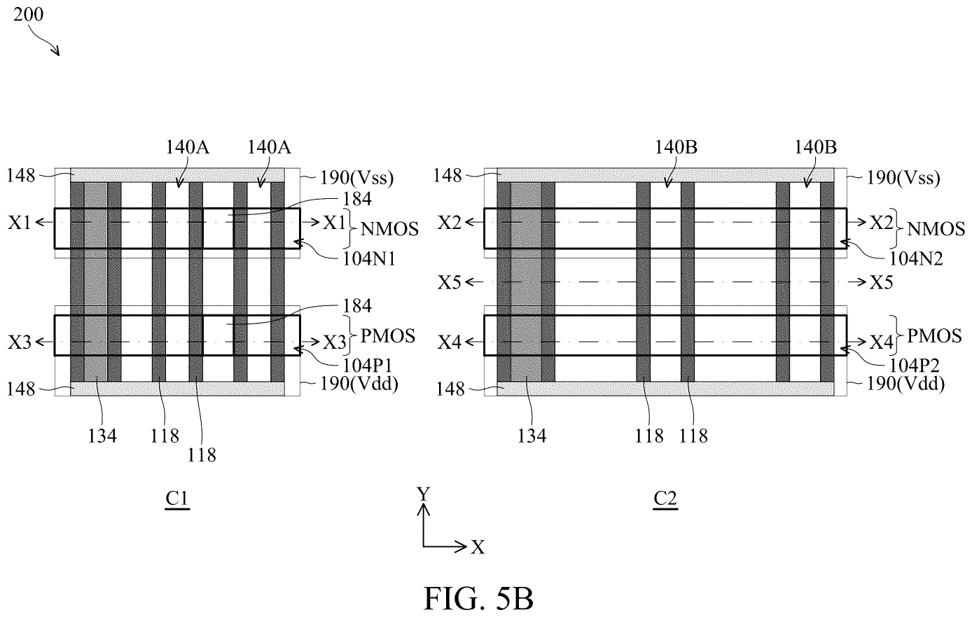

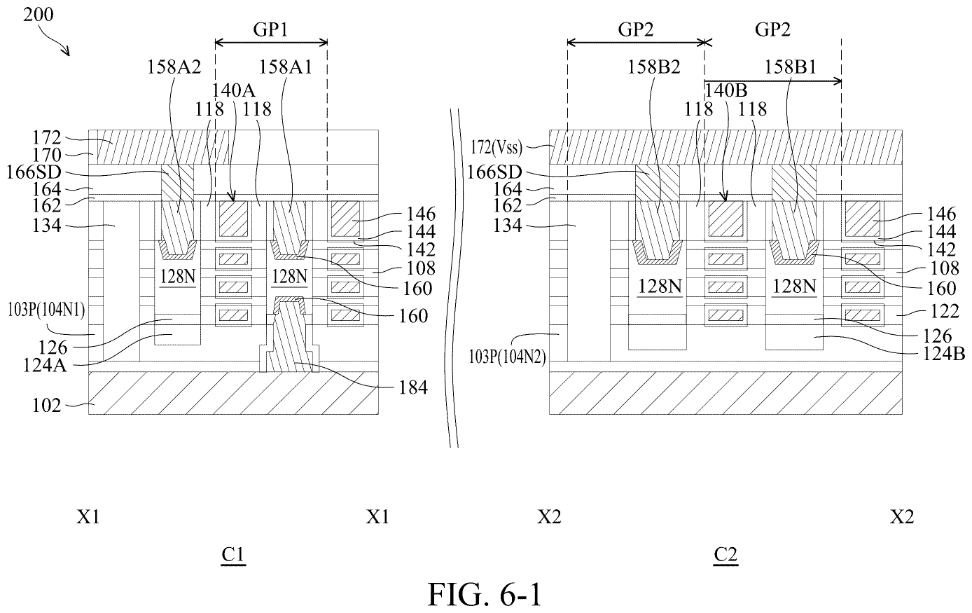

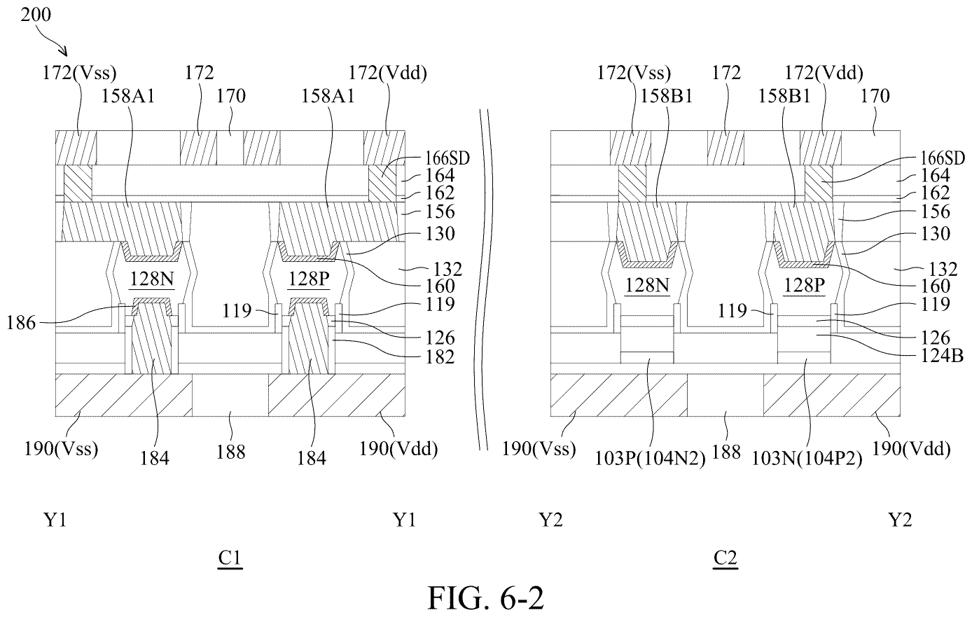

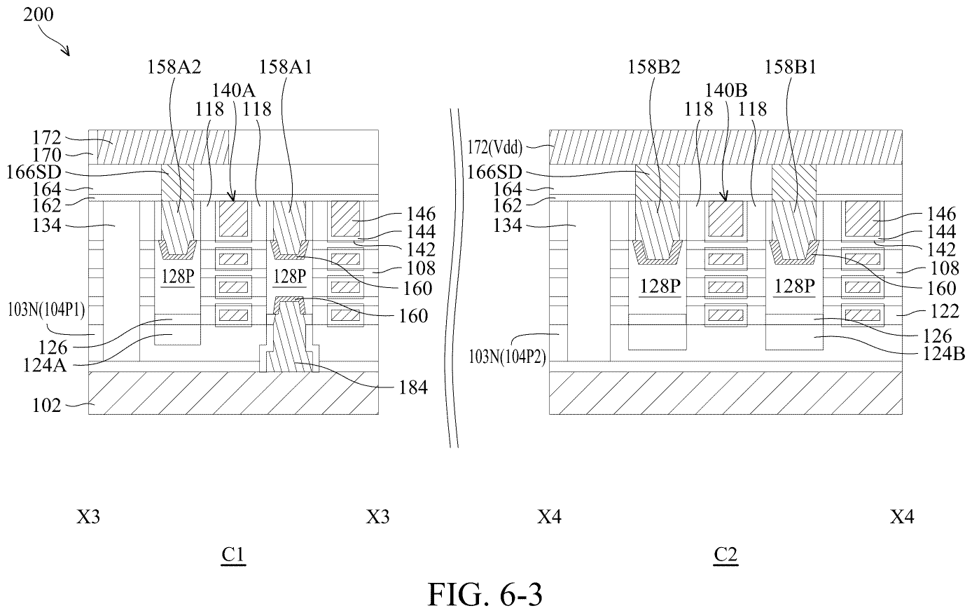

FIGS. 5A and 5B respectively illustrate the frontside layout and the backside layout of a semiconductor structure 200 with a backside power rail architecture, in accordance with some embodiments. The embodiments of FIGS. 5A and 5B are similar to the embodiments of FIGS. 2A and 2B where like reference numerals indicate like elements formed by like processes, except that the transistors in the second cell regions C2 have common source/drain terminals and common gate terminals. FIGS. 6-1, 6-2 and 6-3 are cross-sectional views respectively corresponding to lines X1-X1 and X2-X2, lines Y1-Y1 and Y2-Y2 and lines X3-X3 and X4-X4 shown in FIGS. 5A and 5B. FIG. 6-4 is a cross-sectional view corresponding to line X5-X5.

In some embodiments, the second cell region C2 includes a capacitor device. In the second cell region C2, the metal gate electrode layers 146 of the final gate stacks 140B of the n-channel nanostructure transistors NMOS and the p-channel nanostructure transistors PMOS are electrically connected to a metal line 172(G). In the second cell region C2, the source/drain features 128N of the n-channel nanostructure transistors NMOS are electrically connected to the power rail 172(Vss). In the second cell region C2, the source/drain features 128P of the p-channel nanostructure transistors PMOS are electrically connected to the power rail 172(Vdd).

In the second cell region C2, the metal gate electrode layers 146 of the final gate stacks 140B serve as first electrode plates, the source/drain features 128N serve as second electrode plates, and the source/drain features 128P serve as third electrode plates, in accordance with some embodiments. The dielectric material (e.g., gate dielectric layer 144, the gate spacer layers 118, the inner spacer layers 122, etc.) between the metal gate electrode layers 146 and the source/drain features 128N and between the metal gate electrode layers 146 and the source/drain features 128P serve as capacitor dielectric layers, in accordance with some embodiments.

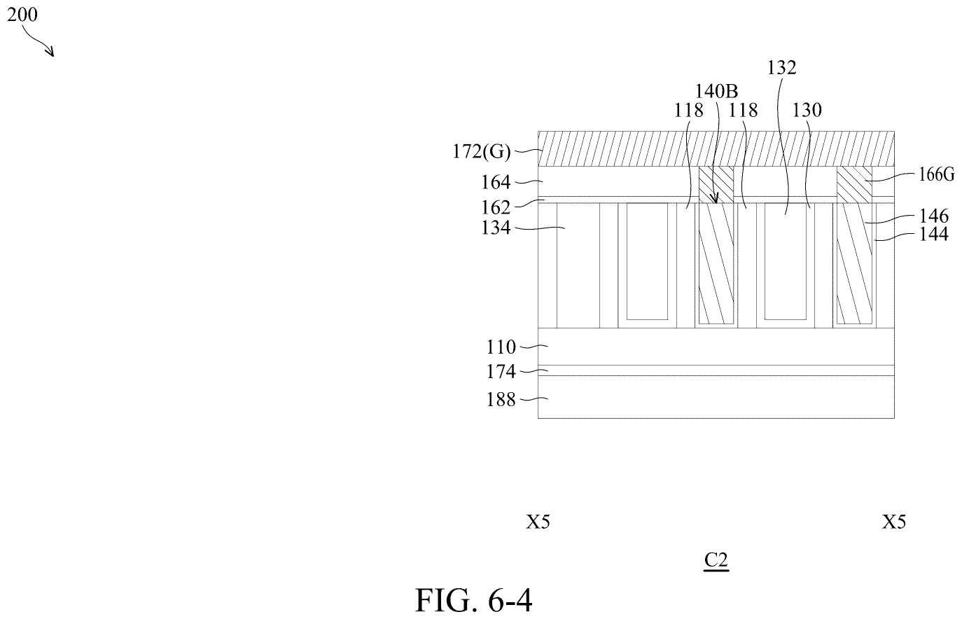

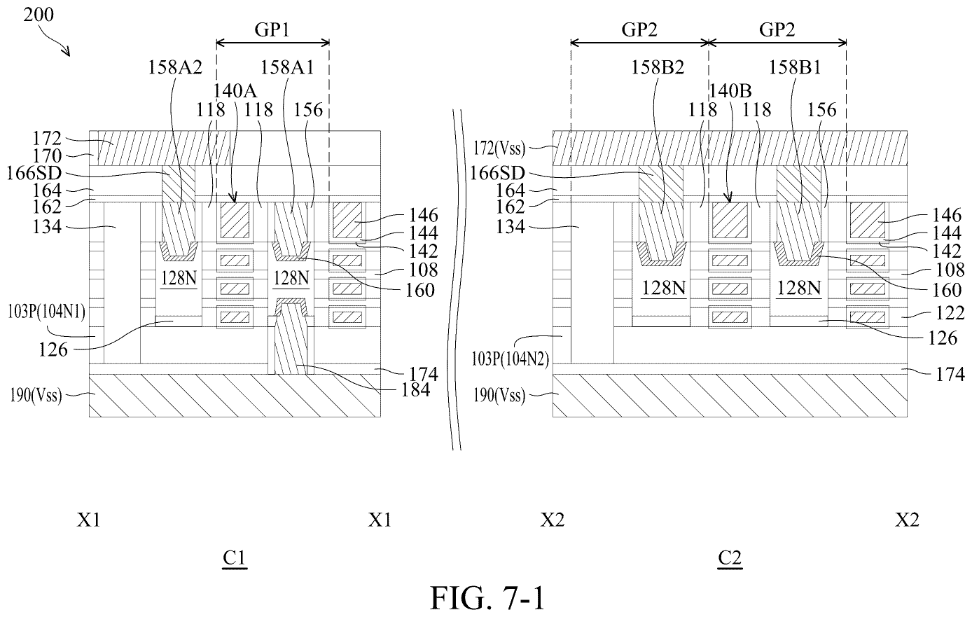

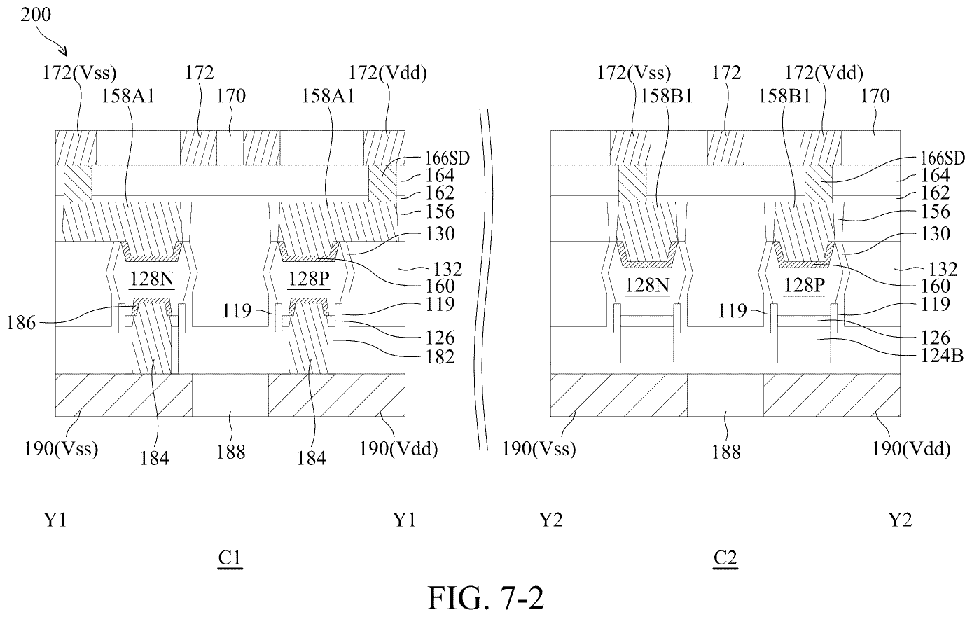

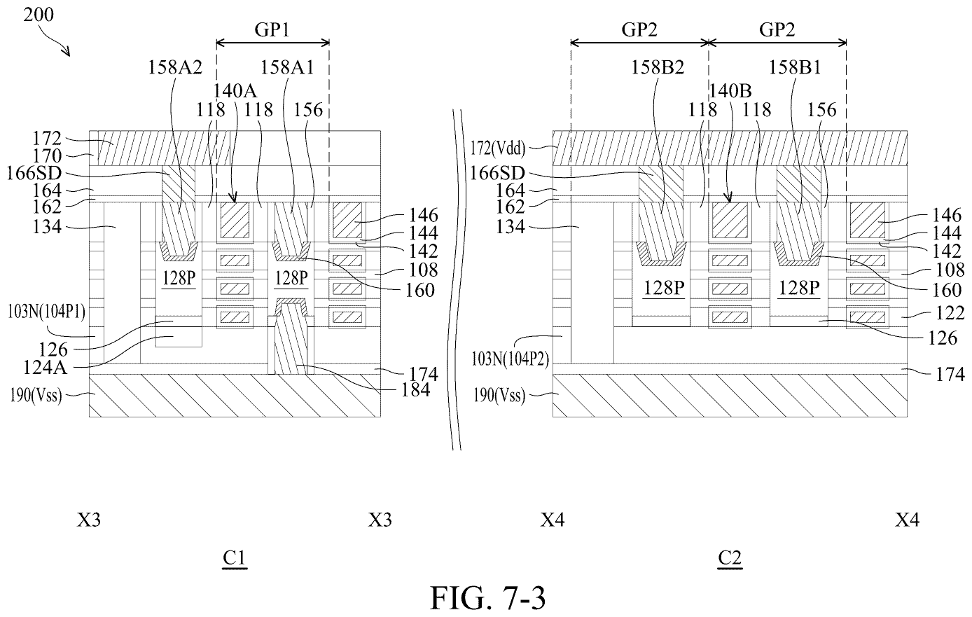

FIGS. 7-1, 7-2 and 7-3 are a modification of the semiconductor structure 200 of FIGS. 6-1, 6-2 and 6-3, in accordance with some embodiments of the disclosure. The embodiments of FIGS. 7-1, 7-2 and 7-3 are similar to the embodiments of FIGS. 6-1 through 6-4 where like reference numerals indicate like elements formed by like processes, except that the semiconductor sacrificial layers 124A and 124B are omitted.

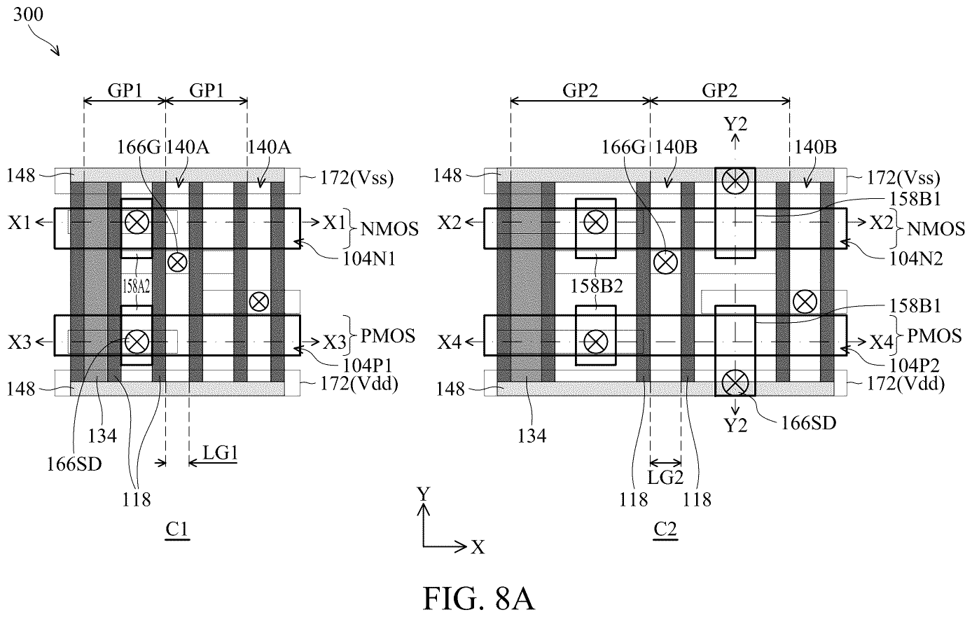

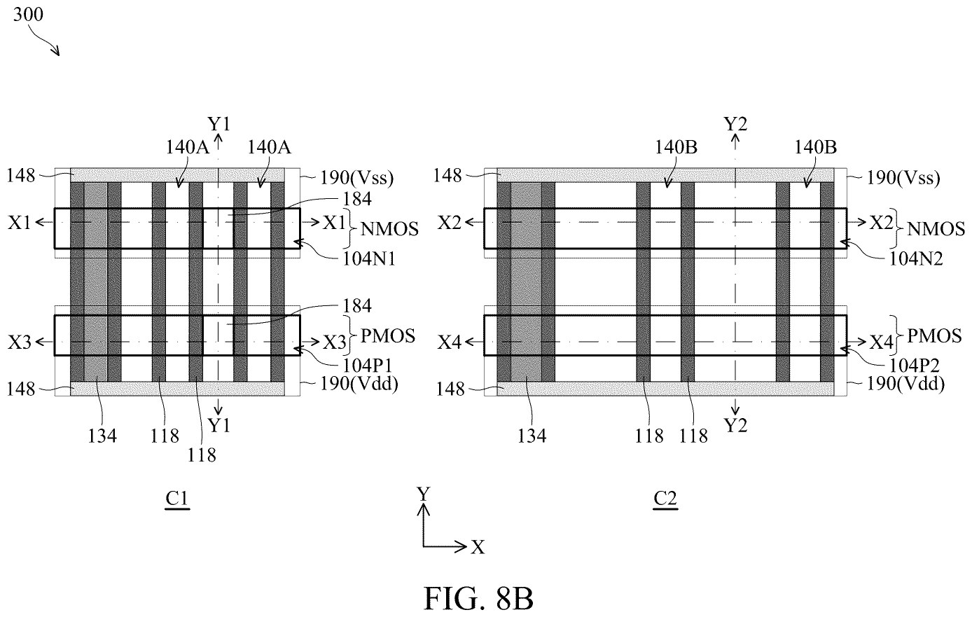

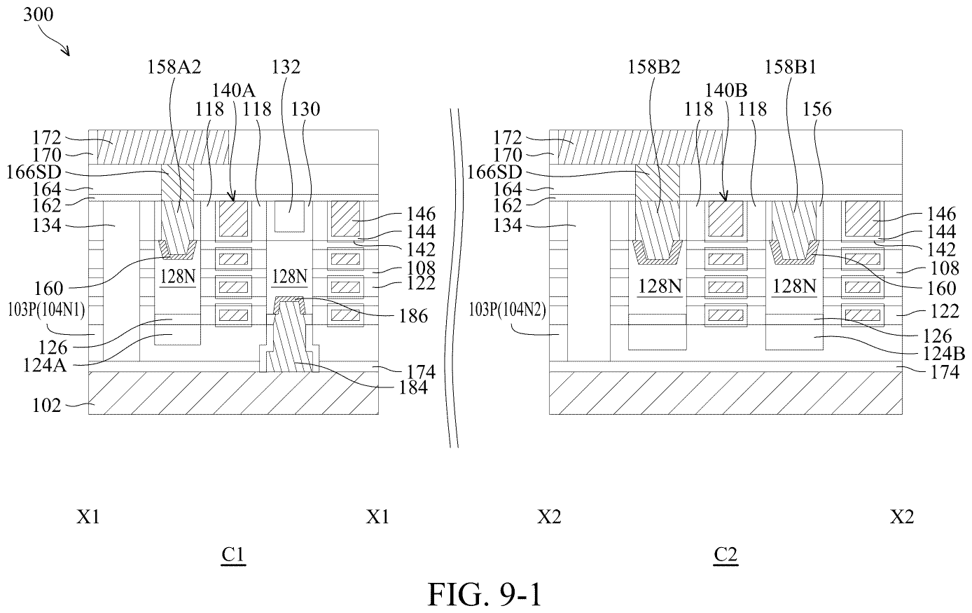

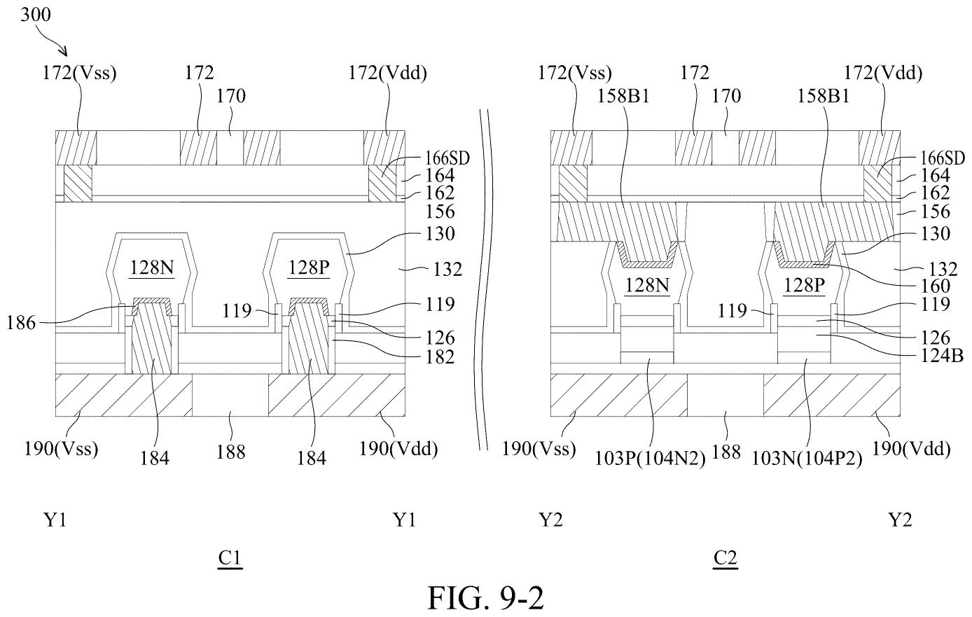

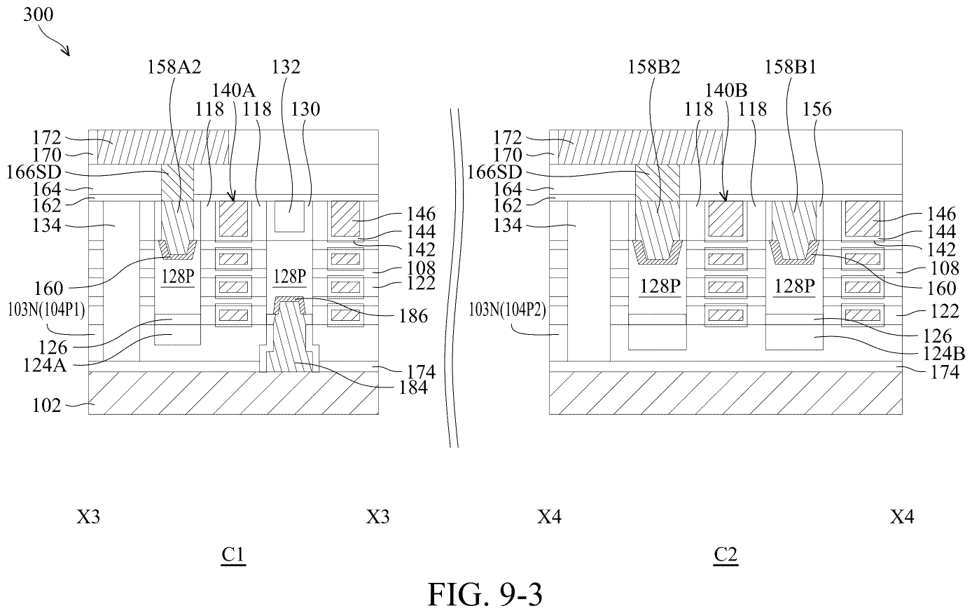

FIGS. 8A and 8B respectively illustrate the frontside layout and the backside layout of a semiconductor structure 300 with a backside power rail architecture, in accordance with some embodiments. The embodiments of FIGS. 8A and 8B are similar to the embodiments of FIGS. 2A and 2B where like reference numerals indicate like elements formed by like processes, except the frontside contact structures 158A1 in the first cell region C1 are omitted. FIGS. 9-1, 9-2 and 9-3 are cross-sectional views respectively corresponding to lines X1-X1 and X2-X2, lines Y1-Y1 and Y2-Y2 and lines X3-X3 and X4-X4 shown in FIGS. 8A and 8B.

The circuit in the first cell region C1 is powered only from the backside of the semiconductor structure 300, in accordance with some embodiments. In some embodiments, the top surfaces of source/drain features 128N and 128P in the first cell region C1 remain covered by the contact etching stop layer 130. Although the frontside power rails 172(Vss) and 172(Vdd) extend across the first cell region C1, the frontside power rails are not electrically connected to the source terminals of the nanostructures in first cell region C1. In some other embodiments, no frontside power rails 172(Vss) and 172(Vdd) extend across the first cell region C1.

In the embodiments of the present disclosure, the backside contact structures 184 are disposed in the first cell region C1 with a relatively small gate pitch (or critical poly-gate pitch) and electrically connect the backside power rails 190 to the Vdd/Vss nodes of the circuit in the first cell region C1, and thus the current crowding may be alleviated. Therefore, the performance of the circuit in the first cell region C1 may improve.

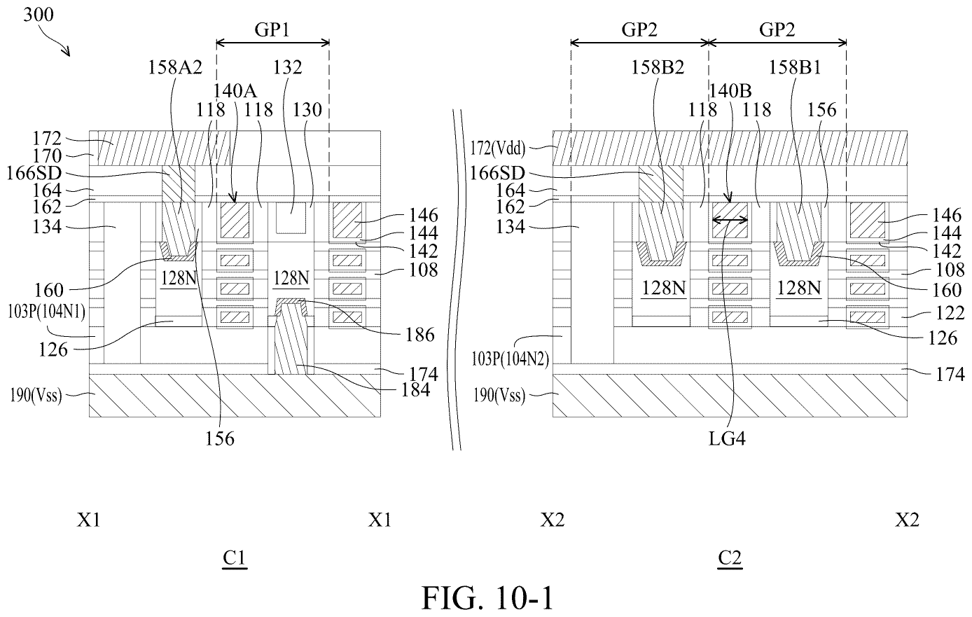

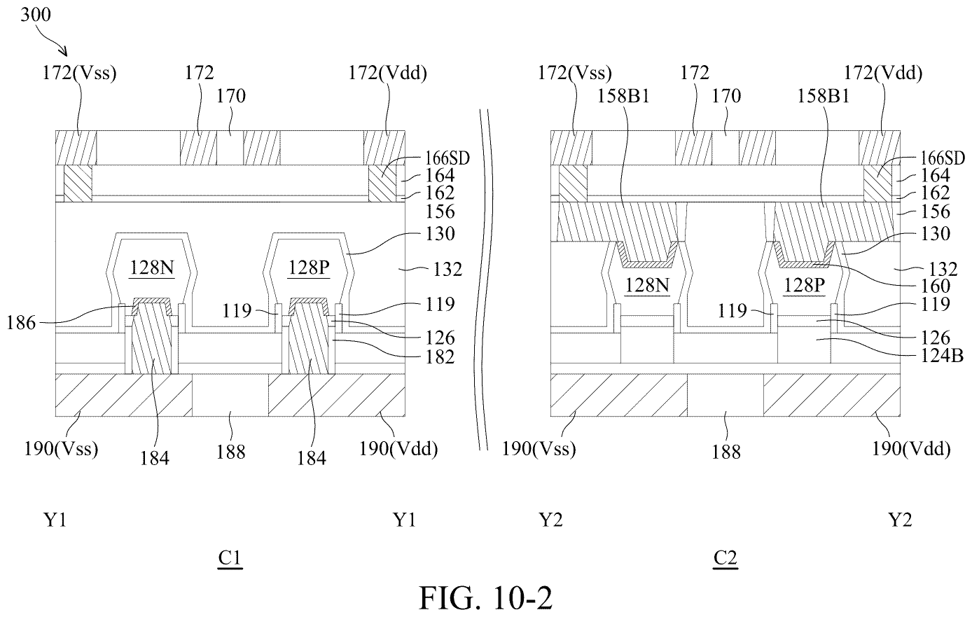

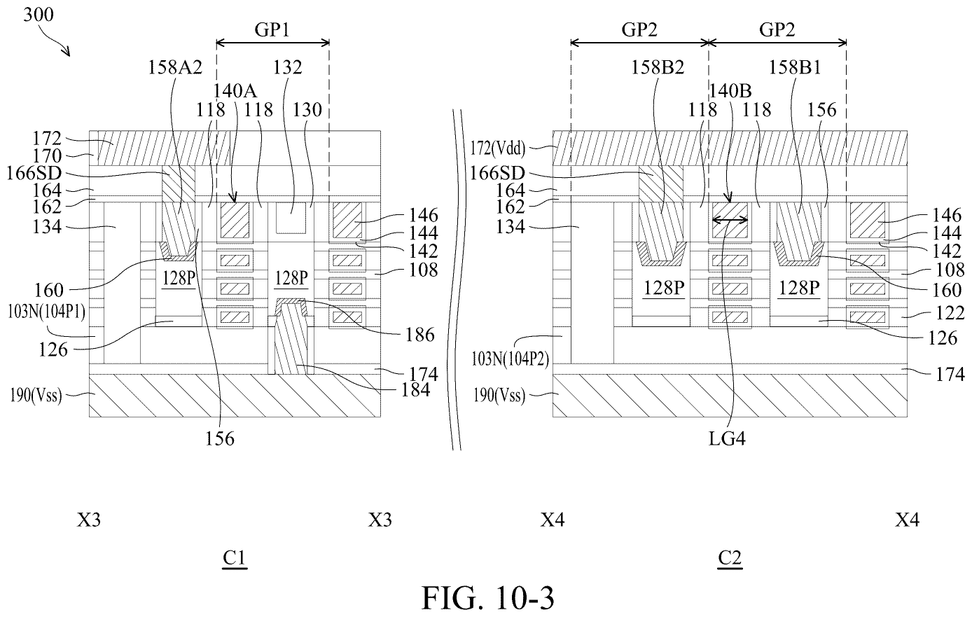

FIGS. 10-1, 10-2 and 10-3 are a modification of the semiconductor structure 300 of FIGS. 9-1, 9-2 and 9-3, in accordance with some embodiments of the disclosure. The embodiments of FIGS. 10-1, 10-2 and 10-3 are similar to the embodiments of FIGS. 9-1, 9-2 and 9-3 where like reference numerals indicate like elements formed by like processes, except that the semiconductor sacrificial layers 124A and 124B are omitted.

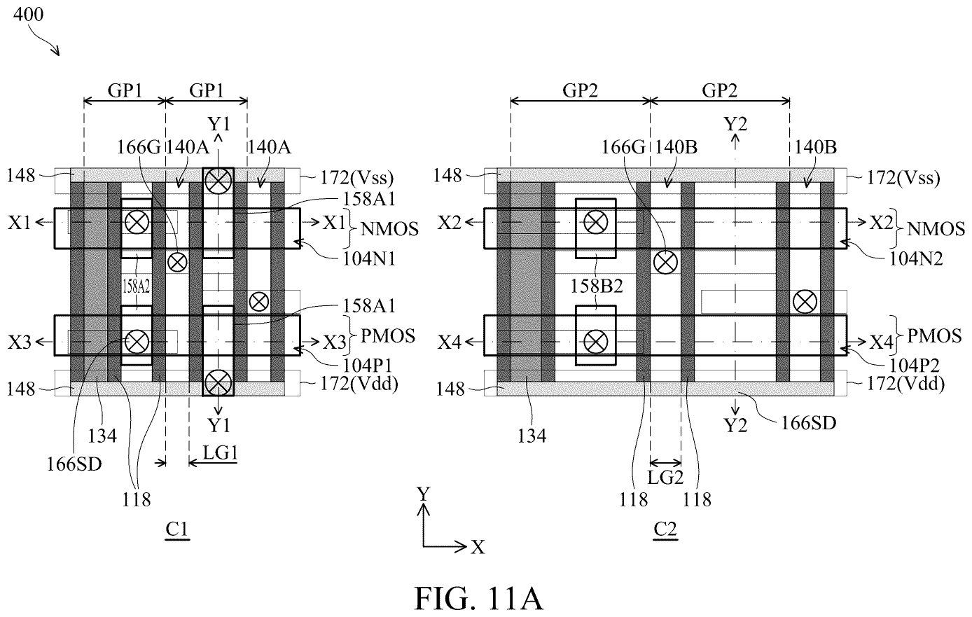

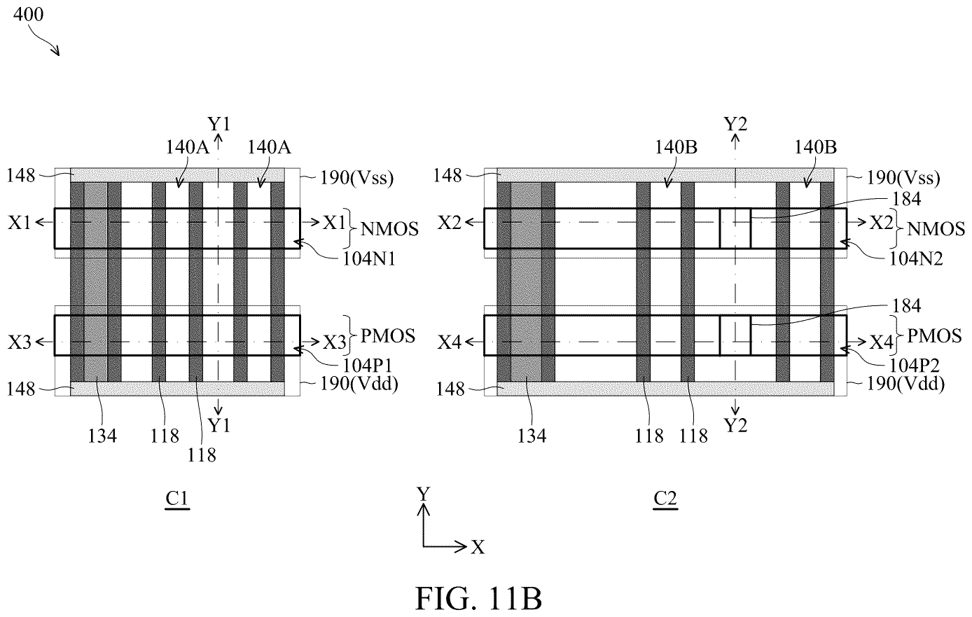

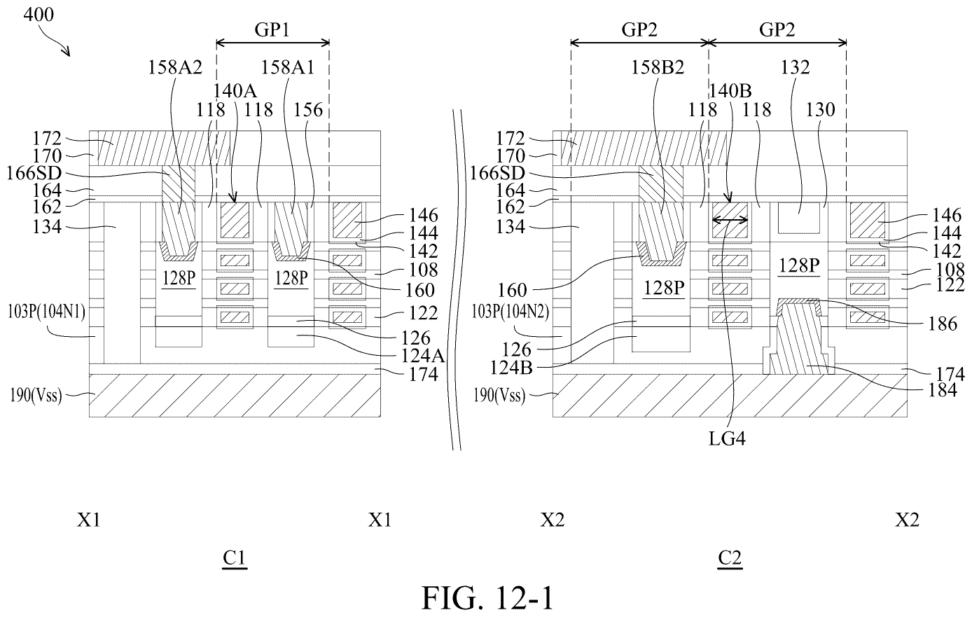

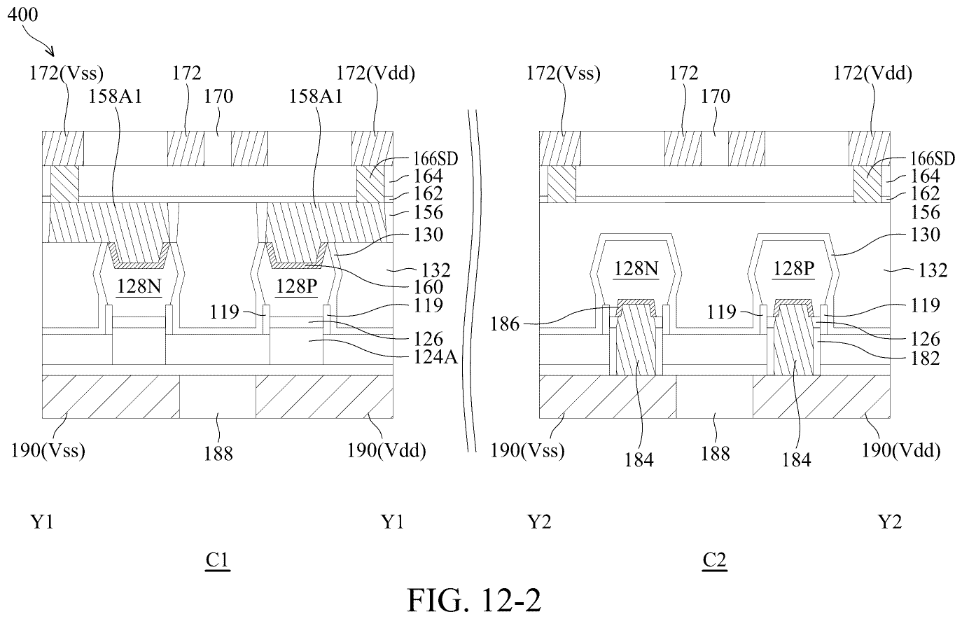

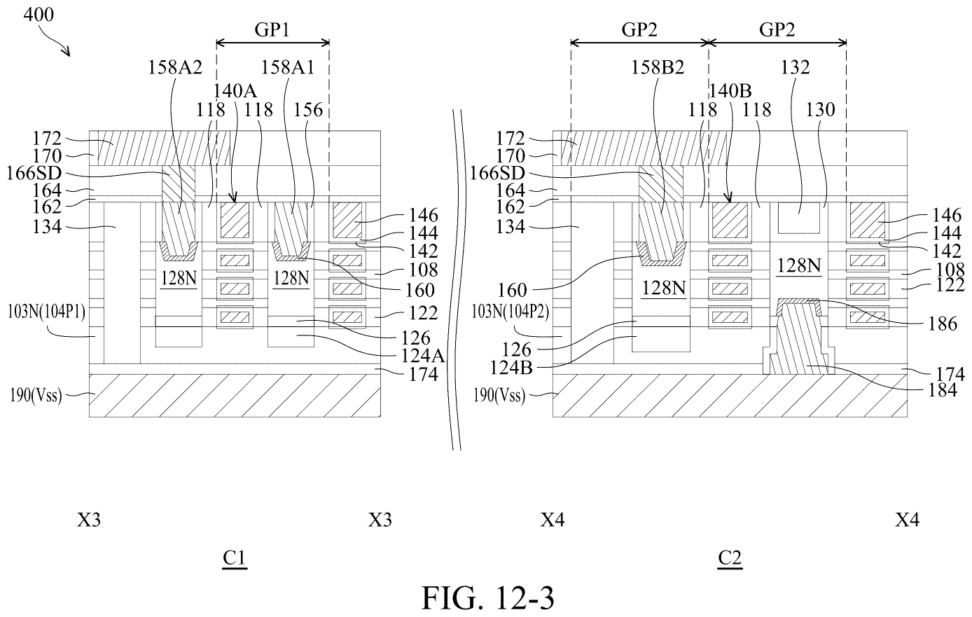

FIGS. 11A and 11B respectively illustrate the frontside layout and the backside layout of a semiconductor structure 400 with a backside power rail architecture, in accordance with some embodiments. The embodiments of FIGS. 11A and 11B are similar to the embodiments of FIGS. 2A and 2B where like reference numerals indicate like elements formed by like processes, except the backside contact structures 184 in the first cell region C1 are omitted, the frontside contact structures 158B1 in the second cell region C2 are omitted, and backside contact structures 184 are formed in the second cell region C2. FIGS. 12-1, 12-2 and 12-3 are cross-sectional views respectively corresponding to lines X1-X1 and X2-X2, lines Y1-Y1 and Y2-Y2 and lines X3-X3 and X4-X4 shown in FIGS. 11A and 11B.

In some embodiments, the circuit in the first cell region C1 may focus more on higher device energy efficiency, and the circuit in the second cell region C2 may focus more on higher performance. In some embodiments where the first cell region C1 includes low-power device, and the second cell region C2 includes high-speed device, the current crowding is less of a concern for the first cell region C1, but more of a concern for the second cell region C2. The circuit in the first cell region C1 is powered only from the frontside of the semiconductor structure 400, while the circuit in the second cell region C2 is powered only from the backside of the semiconductor structure 400, in accordance with some embodiments.

In some embodiments, the circuit in the second cell region C2 includes backside contact structures 184, which serve as Vdd/Vss nodes of the circuit in the second cell region C2, in accordance with some embodiments. In the second cell region C2, the Vss backside power rail 190 is electrically connected to the Vss node (e.g., source terminals) of the n-channel nanostructure transistors NMOS through the backside contact structure 184, and the Vdd backside power rail 190 is electrically connected to the Vdd node (e.g., source terminals) of the p-channel nanostructure transistors PMOS through the backside contact structures 184, in accordance with some embodiments.

In some embodiments, the bottom surfaces of source/drain features 128N and 128P in the first cell region C1 remain covered by the dielectric separation layers 126. In some embodiments, the top surfaces of source/drain features 128N and 128P in the second cell region C2 remain covered by the contact etching stop layer 130.

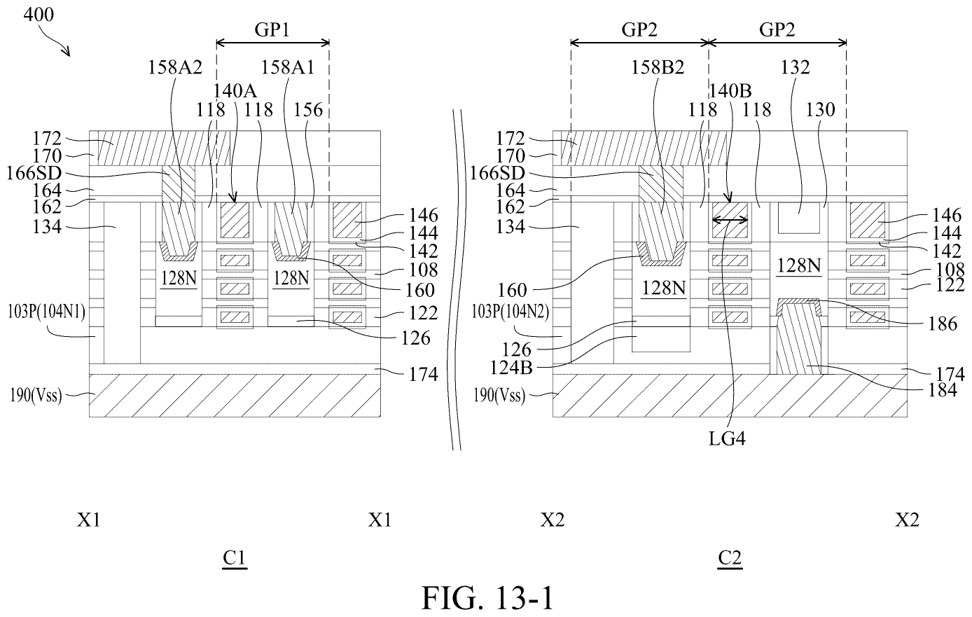

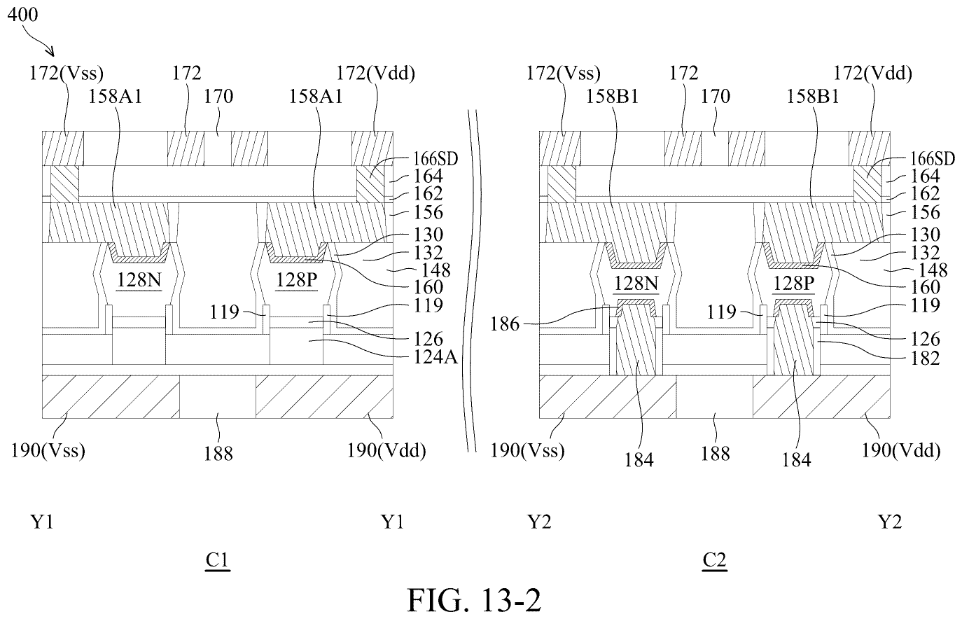

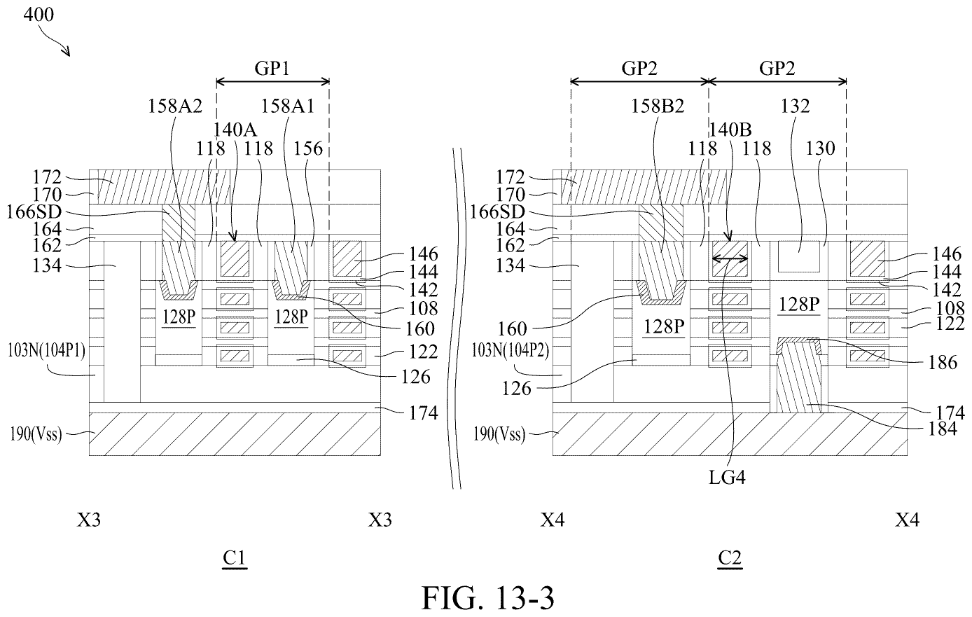

FIGS. 13-1, 13-2 and 10-3 are a modification of the semiconductor structure 400 of FIGS. 12-1, 12-2 and 12-3, in accordance with some embodiments of the disclosure. The embodiments of FIGS. 13-1, 13-2 and 13-3 are similar to the embodiments of FIGS. 12-1, 12-2 and 12-3where like reference numerals indicate like elements formed by like processes, except that the semiconductor sacrificial layers 124A and 124B are omitted.

As described above, the aspect of the present disclosure is directed to a semiconductor structure with a backside power rail architecture. The semiconductor structure includes cell regions C1 and C2 with different gate pitches. One of the cell regions C1 and C2 includes backside contact structures 184, and thus the current crowding may be alleviated. The other one of the cell regions C1 and C2 has no backside contact structures 184, and thus the difficulty of the patterning process for forming the backside contact opening may be reduced. As a result, the performance and manufacturing yield of the resulting semiconductor structure may improve.

Embodiments of a semiconductor structure and the method for forming the same may be provided. The semiconductor structure includes a first cell region and a second cell region having different gate pitches. The circuit of the first cell region includes a first source/drain feature and a contact structure abutting the backside of the first source/drain feature, and the circuit of the second cell region includes a second source/drain feature and a dielectric layer covering the backside of the second source/drain feature. Therefore, the performance and manufacturing yield of the resulting semiconductor structure may improve.

In some embodiments, a method for forming a semiconductor structure is provided. The method includes forming a first circuit and a second circuit over a first region and a second region of a substrate, respectively. The first circuit includes a first fin element extending lengthwise along a first direction, a first source/drain feature on the first fin element, a plurality of first gate stacks extending lengthwise along a second direction across the first fin element and having a first gate pitch, and the second direction is different than the first direction. The second circuit includes a second fin element extending lengthwise along the first direction, a second source/drain feature on the second fin element, a plurality of second gate stacks extending lengthwise along the second direction across the second fin element and having a second gate pitch that is different from the first gate pitch. The method further includes removing the substrate, forming a first opening through the first fin element to expose a backside surface of the first source/drain feature while a backside surface of the second source/drain feature remains covered by the second fin element, and forming a first contact structure in the first opening. An electrical conductivity of the first contact structure is greater than an electrical conductivity of the first source/drain feature.

In some embodiments, a method for forming a semiconductor structure is provided. The method includes forming a first active region and a second active region over a substrate. Each of the first active region and the second active region includes a fin element and alternating first semiconductor layers and second semiconductor layers on the fin element. The method further includes forming an isolation structure to surround the fin elements, recessing the first active region and the second active region to form a first recess and a second recess, respectively, forming a first dielectric separation layer and a second dielectric separation layer respectively in the first recess and the second recess, forming a first source/drain feature and a second source/drain feature respectively on the first dielectric separation layer and the second dielectric separation layer, and removing the first semiconductor layers of the first active region and the second active region. Each of the first source/drain feature and the second source/drain feature includes a portion overhanging the isolation structure. The second semiconductor layers of the first active region form first nanostructures, and the second semiconductor layers of the second active region form second nanostructures. The method further includes forming a first gate stack and second gate stack respectively surrounding the first nanostructures and the second nanostructures. The first gate stack is narrower than the second gate stack. The method further includes flipping the substrate upside down, forming a first opening through the first fin element and the first dielectric separation layer and to a backside surface of the first source/drain feature while a backside surface of the second source/drain feature remains covered by the second dielectric separation layer, and forming a first contact structure in the first opening.

In some embodiments, a semiconductor structure is provided. The semiconductor structure includes a first source/drain feature and a second source/drain feature interposed by a plurality of first nanostructures, a first gate stack wrapping around the first nanostructures, a third source/drain feature and a fourth source/drain feature interposed by a plurality of second nanostructures, and a second gate stack wrapping around the second nanostructures. A first distance between the first and second source/drain features is different than a second distance between the third and fourth source/drain features. The semiconductor structure further includes a first backside contact structure on a backside surface of the second source/drain feature, and a first dielectric layer covering a backside surface of the fourth source/drain feature. The first backside contact structure is electrically coupled to the second source/drain feature by way of a silicide layer, and an electrical conductivity of the silicide layer is between an electrical conductivity of the backside contact structure and an electrical conductivity of the second source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first circuit and a second circuit over a first region and a second region of a substrate, respectively,
wherein the first circuit includes a first fin element extending lengthwise along a first direction, a first source/drain feature on the first fin element, and a plurality of first gate stacks extending lengthwise along a second direction across the first fin element and having a first gate pitch, wherein the second direction is different than the first direction, and
the second circuit includes a second fin element extending lengthwise along the first direction, a second source/drain feature on the second fin element, and a plurality of second gate stacks extending lengthwise along the second direction across the second fin element and having the second gate pitch that is different from the first gate pitch;
removing the substrate;
forming a first opening through the first fin element to expose a backside surface of the first source/drain feature while a backside surface of the second source/drain feature remains covered by the second fin element; and
forming a first contact structure in the first opening, wherein an electrical conductivity of the first contact structure is greater than an electrical conductivity of the first source/drain feature.

2. The method for forming the semiconductor structure as claimed in claim 1, wherein the second gate pitch is greater than the first gate pitch.

3. The method for forming the semiconductor structure as claimed in claim 1, wherein an interlayer dielectric layer is formed over the first source/drain feature and the second source/drain feature, wherein the method further comprises:
forming a second opening through the interlayer dielectric layer to expose a top surface of the first source/drain feature;
forming a third opening through the interlayer dielectric layer to expose a top surface of the second source/drain feature;
forming a second contact structure in the second opening; and
forming a third contact structure in the third opening.

4. The method for forming the semiconductor structure as claimed in claim 1, further comprising:
forming a first active region and a second active region over the first region and the second region of the substrate, respectively, wherein the first active region includes first semiconductor layers and second semiconductor layers alternatingly stacked over the first fin element, and the second active region includes the first semiconductor layers and the second semiconductor layers alternatingly stacked over the second fin element; and
etching the first active region and the second active region to form a first recess and a second recess, respectively, wherein the second recess is deeper than the first recess;
forming the first source/drain feature in the first recess and the second source/drain feature in the second recess.

5. The method for forming the semiconductor structure as claimed in claim 4, further comprising, before forming the first source/drain feature in the first recess and the second source/drain feature in the second recess:
forming a first dielectric separation layer in the first recess and a second dielectric separation layer in the second recess.

6. The method for forming the semiconductor structure as claimed in claim 4, further comprising, before forming the first source/drain feature in the first recess and the second source/drain feature in the second recess:
forming a first semiconductor sacrificial layer in the first recess and a second semiconductor sacrificial layer in the second recess, wherein the second semiconductor sacrificial layer is thicker than the first semiconductor sacrificial layer.

7. The method for forming the semiconductor structure as claimed in claim 4, further comprising:
removing the first semiconductor layers of the first active region and the first semiconductor layers of the second active region; and
forming the plurality of first gate stacks to surround the second semiconductor layers of the first active region; and
forming the plurality of second gate stacks to surround the second semiconductor layers of the second active region.

8. The method for forming the semiconductor structure as claimed in claim 1, further comprising:
forming a patterned mask layer on a backside surface of the first fin element and a backside surface of the second fin element, wherein the patterned mask layer has an opening pattern overlapping the first source/drain feature while the second source/drain feature is covered by the patterned mask layer,
etching the first fin element using the patterned mask layer to form a first portion of the first opening;
forming a contact liner along a sidewall of the first portion of the first opening; and
etching the first source/drain feature to form a second portion of the first opening after forming the contact liner.

9. The method for forming the semiconductor structure as claimed in claim 8, wherein along the first direction, a first portion of the first opening is wider than the first source/drain feature.

10. The method for forming the semiconductor structure as claimed in claim 1, wherein an interlayer dielectric layer is formed over the first source/drain feature and the second source/drain feature, and the method further comprises:
forming a second contact structure through the interlayer dielectric layer and on a top surface of the second source/drain feature while a top surface of the first source/drain feature is covered by the interlayer dielectric layer.

11. A method for forming a semiconductor structure, comprising:
forming a first active region and a second active region over a substrate, wherein each of the first active region and the second active region includes a fin element and alternating first semiconductor layers and second semiconductor layers on the fin element;
forming an isolation structure to surround the fin elements;
recessing the first active region and the second active region to form a first recess and a second recess, respectively;
forming a first dielectric separation layer and a second dielectric separation layer respectively in the first recess and the second recess;
forming a first source/drain feature and a second source/drain feature respectively on the first dielectric separation layer and the second dielectric separation layer, wherein each of the first source/drain feature and the second source/drain feature includes a portion overhanging the isolation structure;
removing the first semiconductor layers of the first active region and the second active region, wherein the second semiconductor layers of the first active region form first nanostructures, and the second semiconductor layers of the second active region form second nanostructures;
forming a first gate stack and second gate stack respectively surrounding the first nanostructures and the second nanostructures, wherein the first gate stack is narrower than the second gate stack;
flipping the substrate upside down;
forming a first opening through the first fin element and the first dielectric separation layer and to a backside surface of the first source/drain feature while a backside surface of the second source/drain feature remains covered by the second dielectric separation layer; and
forming a first contact structure in the first opening.

12. The method for forming the semiconductor structure as claimed in claim 11, wherein the first source/drain feature is narrower than the second source/drain feature.

13. The method for forming the semiconductor structure as claimed in claim 12, further comprising:
forming an interlayer dielectric layer over the first source/drain feature and the second source/drain feature;
forming a second contact structure through the interlayer dielectric layer and on the first source/drain feature; and
forming a third contact structure through the interlayer dielectric layer and on the second source/drain feature, wherein the third contact structure is deeper than the second contact structure.

14. The method for forming the semiconductor structure as claimed in claim 13, further comprising:
forming a first via and a second via respectively on the first contact structure and the second contact structure; and
forming a first metal line and a second metal line respectively on the first via and the second via, wherein the first metal line and the second metal line provide a Vss voltage or a Vdd voltage.

15. The method for forming the semiconductor structure as claimed in claim 11, wherein a ratio of a width of the second gate stack to a width of the first gate stack ranges from about 1.2 to about 5.

16. A semiconductor structure, comprising:
a first source/drain feature and a second source/drain feature interposed by a plurality of first nanostructures;
a first gate stack wrapping around the plurality of first nanostructures;
a third source/drain feature and a fourth source/drain feature interposed by a plurality of second nanostructures, wherein a first distance between the first and second source/drain features is different than a second distance between the third and fourth source/drain features;
a second gate stack wrapping around the plurality of second nanostructures;
a first contact structure on a backside surface of the second source/drain feature, wherein the first contact structure is electrically coupled to the second source/drain feature by way of a silicide layer, and an electrical conductivity of the silicide layer is between an electrical conductivity of the first contact structure and an electrical conductivity of the second source/drain feature; and
a first dielectric layer covering a backside surface of the fourth source/drain feature.

17. The semiconductor structure as claimed in claim 16, further comprising:
a first semiconductor layer under the first source/drain feature; and
a second semiconductor layer under the third source/drain feature, wherein the second semiconductor layer is thicker than the first semiconductor layer.

18. The semiconductor structure as claimed in claim 16, further comprising:
a second contact structure on a frontside surface of the third source/drain feature;
a third contact structure on a frontside surface of the fourth source/drain feature; and
a metal line electrically connected to both the second and third contact structures.

19. The semiconductor structure as claimed in claim 16, further comprising:
a second dielectric layer under and interfaced with a backside surface of the first source/drain feature; and
a third dielectric layer under and interfaced with a backside surface of the third source/drain feature.

20. The semiconductor structure as claimed in claim 16, wherein the first distance is less than the second distance, and the semiconductor structure further comprises:
a contact etching stop layer over the second source/drain feature, wherein in a cross-sectional view, the contact etching stop layer continuously extends along a frontside surface of the second source/drain feature, from a first edge of the first source/drain feature to a second edge of the second source/drain feature;
a second contact structure on the frontside surface of the fourth source/drain feature.
